(19) United States
(12) Patent Application Publication
(10) Pub. No.: US 2025/0234553 A1
(43) Pub. Date: Jul. 17, 2025

(54) METHOD OF SELECTIVE BOTTOM WIDENING OF HIGH ASPECT RATIO OPENINGS THROUGH A MULTI-LAYER STACK

(71) Applicant: SANDISK TECHNOLOGIES LLC, ADDISON, TX (US)

(72) Inventors: Bing ZHOU, San Jose, CA (US); Kartik SONDHI, Milpitas, CA (US); Senaka KANAKAMEDALA, San Jose, CA (US); Kensuke YAMAGUCHI, Yokkaichi (JP); Jo SATO, Yokkaichi (JP); Shigeru NAKATSUKA, Yokkaichi (JP); Fei ZHOU, San Jose, CA (US)

(21) Appl. No.: 18/415,100

(22) Filed: Jan. 17, 2024

(51) Int. Cl. H10B 43/35; G11C 16/04; H01L 23/522; H01L 23/528; H10B 43/10; H10B 43/27

(52) U.S. Cl. CPC H10B 43/35; G11C 16/0483; H01L 23/5226; H01L 23/5283; H10B 43/10; H10B 43/27

(57) ABSTRACT

A device structure includes a layer stack that includes a first alternating stack of first insulating layers and first electrically conductive layers which overlies a base material layer, and an opening fill structure vertically extending through each layer within the layer stack and laterally enclosed by or contacted by the first alternating stack. The opening fill structure includes a first portion having a first variable width that increases linearly with a vertical distance from the base material layer, a second portion that overlies and is adjoined to the first portion and having a second variable width that decreases non-linearly with the vertical distance from the base material layer and laterally bounded by a tapered annular surface segment having a convex vertical profile, and a third portion that overlies the second portion and having a third variable width that increases linearly with the vertical distance from the base material layer.

### FIELD

The present disclosure relates generally to the field of semiconductor devices, and particularly to a method of selectively widening bottom portions of high aspect ratio-openings through a multi-layer stack and structures formed by the same.

### BACKGROUND

A multi-layer stack, such as an alternating stack of insulating layers and spacer material layers, is used to form various semiconductor devices, an example of which is a three-dimensional vertical NAND device. Generally, openings formed through such a multi-layer stack have a high aspect ratio (i.e., the ratio of the height to the top width).

### SUMMARY

According to an aspect of the present disclosure, a device structure is provided, which comprises: a layer stack that comprises a first alternating stack of first insulating layers and first electrically conductive layers which overlies a base material layer; and an opening fill structure vertically extending through each layer within the layer stack and laterally enclosed by or contacted by the first alternating stack. The opening fill structure comprises a contoured sidewall that continuously extends from a bottom surface of the opening fill structure to a top surface of the opening fill structure; a first portion having a first variable width that increases linearly with a vertical distance from the base material layer; a second portion that overlies and is adjoined to the first portion and having a second variable width that decreases non-linearly with the vertical distance from the base material layer and laterally bounded by a tapered annular surface segment having a convex vertical profile; and a third portion that overlies and is adjoined to the second portion and having a third variable width that increases linearly with the vertical distance from the base material layer.

According to another aspect of the present disclosure, a method of forming a device structure is provided. The method comprises: forming a first alternating stack of first insulating layers and first spacer material layer over a base material layer; forming an opening through at least an upper portion of the first alternating stack; forming an etch mask layer only on an upper portion of the sidewall of the opening; performing an isotropic etch process that isotropically etches the first insulating layers and the first spacer material layers selective to the etch mask layer to laterally expand the opening at levels of a lower portion of the first alternating stack; and forming an opening fill structure in a volume that includes an entire volume of the opening.

### BRIEF DESCRIPTION OF THE DRAWINGS

FIG. 1 is a schematic vertical cross-sectional view of an exemplary structure for forming a memory die after formation of a first alternating stack of first insulating layers and first sacrificial material layers, and a first insulating cap layer over a substrate according to a first embodiment of the present disclosure.

FIG. 2 is a schematic vertical cross-sectional view of the exemplary structure after formation of first stepped surfaces and a first stepped dielectric material portion according to an embodiment of the present disclosure.

FIG. 3A is a schematic vertical cross-sectional view of the exemplary structure after forming first-tier memory openings, first-tier support openings, and first-tier lateral isolation trenches according to an embodiment of the present disclosure.

FIG. 3B is a top-down view of the exemplary structure of FIG. 3A. The vertical plane A-A′ is the cut plane of the vertical cross-sectional view of FIG. 3A.

FIGS. 4A-4E are sequential vertical cross-sectional views of a first-tier opening during a first sequence of processing steps for extending and expanding the first-tier opening.

FIGS. 4F and 4G are sequential vertical cross-sectional views of a first-tier opening during a second sequence of processing steps for extending and expanding the first-tier opening.

FIGS. 5A-5E are sequential vertical cross-sectional views of a first-tier opening during a third sequence of processing steps for extending and expanding the first-tier opening.

FIGS. 6A-6D are sequential vertical cross-sectional views of a first-tier opening during a fourth sequence of processing steps for extending and expanding the first-tier opening.

FIGS. 6E and 6F are sequential vertical cross-sectional views of a first-tier opening during a fifth sequence of processing steps for extending and expanding the first-tier opening.

FIGS. 7A-7G are sequential vertical cross-sectional views of a first-tier opening during a sixth sequence of processing steps for extending and expanding the first-tier opening.

FIGS. 8A-8H are sequential vertical cross-sectional views of a first-tier opening during a seventh sequence of processing steps for extending and expanding the first-tier opening.

FIG. 9 is a schematic vertical cross-sectional view of the exemplary structure after extending and expanding the first-tier memory openings, the first-tier support openings, and the first-tier lateral isolation trenches according to an embodiment of the present disclosure.

FIG. 10A illustrates vertical cross-sectional views of various first-tier openings after expansion of lower portions of the first-tier openings.

FIG. 10B illustrates vertical cross-sectional views of various first-tier openings after removal of the etch mask layer.

FIG. 10C is a plot of distance versus critical diameter of a width of a first-tier opening after extending and expanding the first-tier opening according to an embodiment of the present disclosure.

FIG. 11A is a schematic vertical cross-sectional view of the exemplary structure after formation of first-tier sacrificial opening fill material portions according to an embodiment of the present disclosure.

FIG. 11B is a schematic vertical cross-sectional view of an alternative embodiment of a first sacrificial opening fill material portion according to an embodiment of the present disclosure.

FIG. 12 is a schematic vertical cross-sectional view of the exemplary structure after formation of a second alternating stack of second insulating layers and second sacrificial material layers, a second first insulating cap layer, second stepped surfaces, and a second stepped dielectric material portion according to an embodiment of the present disclosure.

FIG. 13 is a schematic vertical cross-sectional view of the exemplary structure after forming second-tier memory openings, second-tier support openings, and second-tier lateral isolation trenches according to an embodiment of the present disclosure.

FIGS. 14A-14E are sequential vertical cross-sectional views of a second-tier opening during a first sequence of processing steps for extending and expanding the second-tier opening.

FIGS. 14F and 14G are sequential vertical cross-sectional views of a second-tier opening during a second sequence of processing steps for extending and expanding the second-tier opening.

FIGS. 15A-15E are sequential vertical cross-sectional views of a second-tier opening during a third sequence of processing steps for extending and expanding the second-tier opening.

FIGS. 16A-16D are sequential vertical cross-sectional views of a second-tier opening during a fourth sequence of processing steps for extending and expanding the second-tier opening.

FIGS. 16E and 16F are sequential vertical cross-sectional views of a second-tier opening during a fifth sequence of processing steps for extending and expanding the second-tier opening.

FIGS. 17A-17G are sequential vertical cross-sectional views of a second-tier opening during a sixth sequence of processing steps for extending and expanding the second-tier opening.

FIGS. 18A-18H are sequential vertical cross-sectional views of a second-tier opening during a seventh sequence of processing steps for extending and expanding the second-tier opening.

FIG. 19 is a schematic vertical cross-sectional view of the exemplary structure after extending and expanding the second-tier memory openings, the second-tier support openings, and the second-tier lateral isolation trenches according to an embodiment of the present disclosure.

FIG. 20A is a schematic vertical cross-sectional view of the exemplary structure after formation of second-tier sacrificial opening fill material portions according to an embodiment of the present disclosure.

FIG. 20B is top-down view of the exemplary structure of FIG. 20A. The hinged vertical plane A-A′ is a cut plane of the vertical cross-sectional view of FIG. 20A.

FIG. 21A is a schematic vertical cross-sectional view of the exemplary structure after formation of a third-tier structure containing third-tier sacrificial opening fill material portions according to an embodiment of the present disclosure.

FIG. 21B is top-down view of the exemplary structure of FIG. 21A. The hinged vertical plane A-A′ is a cut plane of the vertical cross-sectional view of FIG. 21A.

FIG. 22 is a schematic vertical cross-sectional view of the exemplary structure after replacement of sacrificial support opening fill material portions with support pillar structures according to an embodiment of the present disclosure.

FIG. 23 is a schematic vertical cross-sectional view of the exemplary structure after formation of multi-tier memory openings according to an embodiment of the present disclosure.

FIGS. 24A-24D are sequential vertical cross-sectional views of a region around an multi-tier memory opening during formation of a memory opening fill structure according to an embodiment of the present disclosure.

FIG. 25 is a vertical cross-sectional view of the exemplary structure after formation of memory opening fill structures according to an embodiment of the present disclosure.

FIG. 26A is a vertical cross-sectional view of the exemplary structure after formation and patterning of a contact-level dielectric layer according to an embodiment of the present disclosure.

FIG. 26B is a top-down view of the exemplary structure of FIG. 26A. The hinged vertical plane A-A′ is a cut plane of the vertical cross-sectional view of FIG. 26A.

FIG. 27 is a vertical cross-sectional view of the exemplary structure after formation of lateral isolation trenches according to an embodiment of the present disclosure.

FIG. 28 is a vertical cross-sectional view of the exemplary structure after formation of lateral recesses according to an embodiment of the present disclosure.

FIG. 29 is a vertical cross-sectional view of the exemplary structure after formation of electrically conductive layers according to an embodiment of the present disclosure.

FIG. 30 is a vertical cross-sectional view of the exemplary structure after formation of lateral isolation trench fill structures according to an embodiment of the present disclosure.

FIGS. 31A and 31B are vertical cross-sectional views of embodiments of a lateral isolation trench fill structure.

FIGS. 32A and 32B are vertical cross-sectional views of embodiments of a support pillar structure.

FIG. 33A is a vertical cross-sectional view of the exemplary structure after formation of various contact via structures according to an embodiment of the present disclosure.

FIG. 33B is a top-down view of the exemplary structure of FIG. 33A. The hinged vertical plane A-A′ is a cut plane of the vertical cross-sectional view of FIG. 33A.

FIG. 34 is a vertical cross-sectional view of the exemplary structure after formation of memory-side dielectric material layers and memory-side metal interconnect structures according to an embodiment of the present disclosure.

FIG. 35 is a vertical cross-sectional view of the exemplary structure after attaching a logic die to a memory die according to an embodiment of the present disclosure.

FIG. 36 is a vertical cross-sectional view of the exemplary structure after removal of a substrate according to an embodiment of the present disclosure.

FIGS. 37A-37C are sequential vertical cross-sectional views of a region around a memory opening fill structure during formation of a source layer thereupon according to an aspect of the present disclosure.

FIG. 38 is a vertical cross-sectional view of the exemplary structure after formation of a source layer according to an embodiment of the present disclosure.

### DETAILED DESCRIPTION

The present inventors realized that taper angles of high aspect ratio openings cause the bottom lateral dimensions (i.e., the bottom widths of the openings which are typically referred to as bottom critical dimensions or bottom CD's) of such high aspect ratio openings to be significantly smaller than top lateral dimensions (i.e., the top widths of the openings which are typically referred to as top critical dimensions or top CD's). Such reduction of the bottom CD relative to the top CD may have an adverse effect on device performance. As discussed above, the embodiments of the present disclosure are directed to a method of selectively widening bottom portions of high aspect ratio openings through a multi-layer stack and structures formed by the same, of which various aspects are now described in detail. Embodiments of the disclosure can be employed to form semiconductor devices, such as three-dimensional memory devices comprising a plurality of memory strings.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or from each other, the two elements are “disjoined from” each other or “disjoined among” one another. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a first element is “electrically connected to” a second element if there exists a conductive path consisting of at least one conductive material between the first element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the first continuous structure. For example, a layer may be located between any pair of horizontal planes between, or at, a top surface and a bottom surface of the first continuous structure. A layer may extend horizontally, vertically, and/or along a tapered surface. A substrate may be a layer, may include one or more layers therein, or may have one or more layer thereupon, thereabove, and/or therebelow.

As used herein, a first surface and a second surface are “vertically coincident” with each other if the second surface overlies or underlies the first surface and there exists a vertical plane or a substantially vertical plane that includes the first surface and the second surface. A substantially vertical plane is a plane that extends straight along a direction that deviates from a vertical direction by an angle less than 5 degrees. A vertical plane or a substantially vertical plane is straight along a vertical direction or a substantially vertical direction, and may, or may not, include a curvature along a direction that is perpendicular to the vertical direction or the substantially vertical direction.

As used herein, a “memory level” or a “memory array level” refers to the level corresponding to a general region between a first horizontal plane (i.e., a plane parallel to the top surface of the substrate) including topmost surfaces of an array of memory elements and a second horizontal plane including bottommost surfaces of the array of memory elements. As used herein, a “through-stack” element refers to an element that vertically extends through a memory level.

As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

Generally, a semiconductor package (or a “package”) refers to a unit semiconductor device that may be attached to a circuit board through a set of pins or solder balls. A semiconductor package may include a semiconductor chip (or a “chip”) or a plurality of semiconductor chips that are bonded throughout, for example, by flip-chip bonding or another chip-to-chip bonding. A package or a chip may include a single semiconductor die (or a “die”) or a plurality of semiconductor dies. A die is the smallest unit that may independently execute external commands or report status. Typically, a package or a chip with multiple dies is capable of simultaneously executing as many number of external commands as the total number of dies therein. Each die includes one or more planes. Identical concurrent operations may be executed in each plane within a same die, although there may be some restrictions. In case a die is a memory die, i.e., a die including memory elements, concurrent read operations, concurrent write operations, or concurrent erase operations may be performed in each plane within a same memory die. In a memory die, each plane contains a number of memory blocks (or “blocks”), which are the smallest unit that may be erased by in a single erase operation. Each memory block contains a number of pages, which are the smallest units that may be selected for programming. A page is also the smallest unit that may be selected to a read operation.

Embodiments of the present disclosure are directed to a process for forming enlarged bottom critical dimensions (CD) for high aspect ratio (HAR) openings. Such high aspect ratio openings may comprise various types of openings, such as memory openings, support openings, slit trenches, contact via openings, and other types of via openings that may be included in 3D NAND devices. According to an aspect of the present disclosure, an etch mask layer deposition process, and anisotropic etch process, and an isotropic etch process may be used to provide selective bottom widening for via openings. The etch mask layer can cover an upper portion of a high aspect ratio opening without covering a bottom portion of the high aspect ratio opening. An isotropic etch process, such as a wet etch process, can be used to isotropically etch the uncovered bottom portion of the high aspect ratio opening without etching the covered upper portion of the high aspect ratio opening. The etch mask layer may be deposited by an anisotropic deposition process, such as physical vapor deposition, plasma-enhanced chemical vapor deposition, or a depletive atomic layer deposition process. The etch mask layer may be removed after the isotropic etch process or may be incorporated into a final device structure. Various aspects of the present disclosure are now described with reference to accompanying drawings.

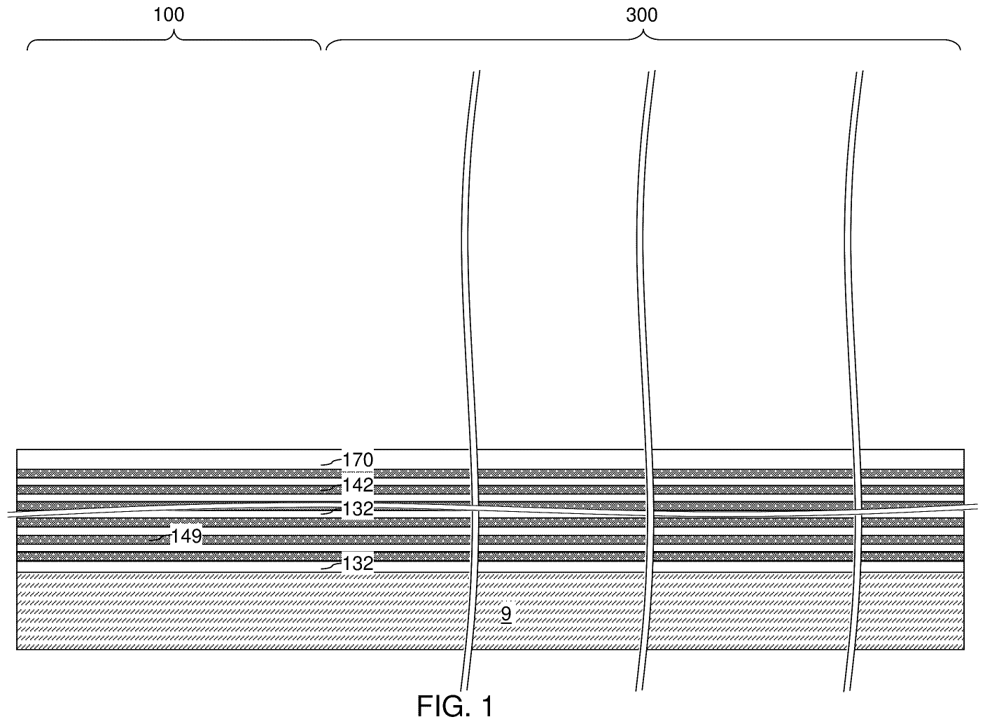

Referring to FIG. 1, an exemplary structure according to an embodiment of the present disclosure is illustrated. The exemplary structure comprises base material layer over which layer stacks are subsequently formed. In one embodiment, the base material layer comprises a substrate 9, which may be a semiconductor substrate. For example, the substrate 9 may comprise a commercially available silicon wafer. Alternatively, the substrate 9 may comprise any material that may be removed selective the materials of overlying materials which are subsequently formed.

A first alternating stack of first insulating layers 132 and first spacer material layers can be formed over the substrate 9. In one embodiment, the first spacer material layers may comprise first sacrificial material layers 142. In this case, a first alternating stack (132, 142) of first insulating layers 132 and first sacrificial material layers 142 can be formed over the substrate 9. The first insulating layers 132 comprise an insulating material, such as undoped silicate glass (i.e., silicon oxide) or a doped silicate glass, and the first sacrificial material layers 142 comprise a sacrificial material, such as silicon nitride or silicon-germanium. In one embodiment, the first insulating layers 132 may comprise silicon oxide layers, and the first sacrificial material layers 142 may comprise silicon nitride layers. The first alternating stack (132, 142) may comprise multiple repetitions of a unit layer stack including a first insulating layer 132 and a first sacrificial material layer 142. The total number of repetitions of the unit layer stack within the first alternating stack (132, 142) may be, for example, in a range from 8 to 1,024, such as from 32 to 256, although lesser and greater number of repetitions may also be employed.

Each of the first insulating layers 132 may have a thickness in a range from 20 nm to 100 nm, such as from 30 nm to 60 nm, although lesser and greater thicknesses may also be employed. Each of the first sacrificial material layers 142 may have a thickness in a range from 20 nm to 100 nm, such as from 30 nm to 60 nm, although lesser and greater thicknesses may also be employed.

A first insulating cap layer 170 can be formed over the first alternating stack (132, 142). In one embodiment, the first insulating cap layer 170 has a homogeneous material composition throughout. In one embodiment, the first insulating cap layer 170 comprises, and/or consists essentially of, a dielectric material selected from undoped silicate glass and a doped silicate glass. In one embodiment, the first insulating cap layer 170 may have a thickness in a range from 60 nm to 400 nm, such as from 100 nm to 300 nm, although lesser and greater thicknesses may also be employed.

The first insulating cap layer 170 may be formed by chemical vapor deposition. In one embodiment, the first insulating cap layer 170 comprises a silicon oxide material formed by decomposition of a precursor material (such as tetraethylorthosilicate (TEOS)) for silicon oxide deposition. In one embodiment, the first insulating cap layer 170 may include residual carbon atoms and/or residual hydrogen atoms. In one embodiment, the carbon concentration in the first insulating cap layer 170 may be in a range from 2 parts per million to 5,000 parts per million, such as from 10 parts per million to 1,000 parts per million. In one embodiment, the hydrogen concentration in the first insulating cap layer 170 may be in a range from 100 parts per million to 10,000 parts per million, such as from 300 parts per million to 5,000 parts per million.

The exemplary structure comprises a memory array region 100 in which a three-dimensional array of memory elements is to be subsequently formed, and a contact region 300 in which layer contact via structures contacting word lines are to be subsequently formed.

While an embodiment is described in which the first spacer material layers are formed as first sacrificial material layers 142, the first spacer material layers may be formed as first electrically conductive layers in an alternative embodiment. Generally, the spacer material layers formed in any alternating stack of insulating layers and spacer material layers of the present disclosure may be formed as, or may be subsequently replaced at least partly with, electrically conductive layers. Such variations of embodiments of the present disclosure are expressly contemplated herein.

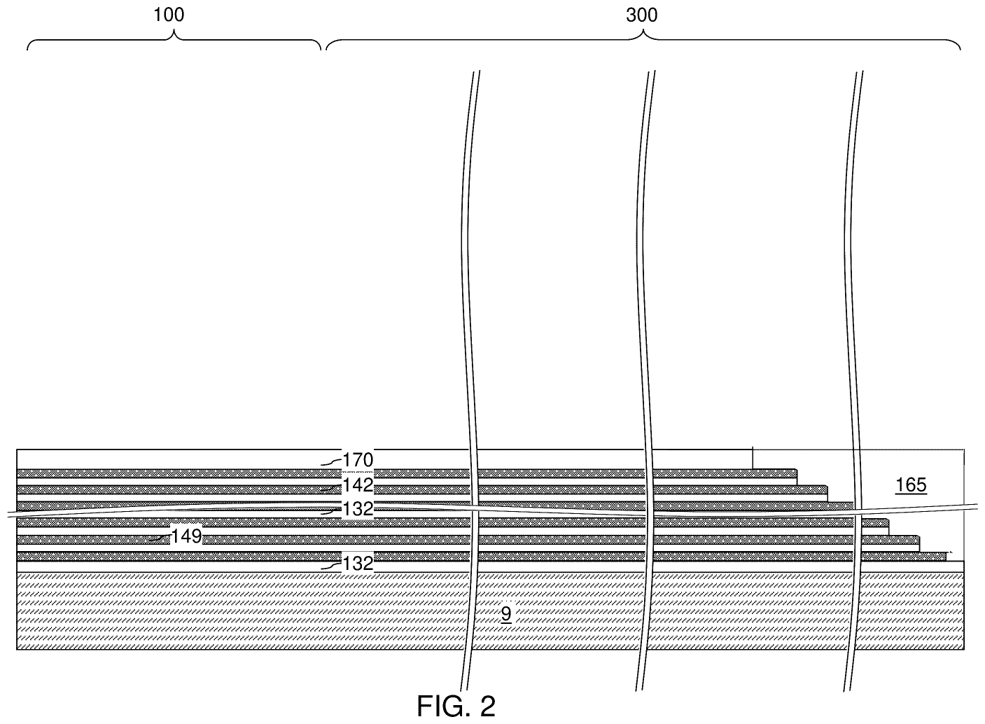

Referring to FIG. 2, first stepped surfaces are formed in the contact region 300. As used herein, “stepped surfaces” refer to a set of surfaces that include at least two horizontal surfaces and at least two vertical surfaces such that each horizontal surface is adjoined to a first vertical surface that extends upward from a first edge of the horizontal surface, and is adjoined to a second vertical surface that extends downward from a second edge of the horizontal surface. A first stepped cavity is formed within the volume from which portions of the first alternating stack (132, 142) and the first insulating cap layer 170 are removed through formation of the first stepped surfaces. A “stepped cavity” refers to a cavity having stepped surfaces.

The first stepped cavity can have various first stepped surfaces such that the horizontal cross-sectional shape of the first stepped cavity changes in steps as a function of the vertical distance from the top surface of the substrate 9. In one embodiment, the first stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type. As used herein, a “level” of a structure including alternating plurality is defined as the relative position of a pair of a first material layer and a second material layer within the structure.

Each first sacrificial material layer 142 other than a topmost first sacrificial material layer 142 within the first alternating stack (132, 142) laterally extends farther than any overlying first sacrificial material layer 142 within the first alternating stack (132, 142) in the terrace region. The first stepped surfaces of the first alternating stack (132, 142) continuously extend from a bottommost layer within the first alternating stack (132, 142) to the first insulating cap layer 170. Generally, the first stepped surfaces continuously extend from a bottommost layer within the first alternating stack (132, 142) at least to a topmost layer within the first alternating stack (132, 142).

A first stepped dielectric material portion 165 (i.e., an insulating fill material portion) can be formed in the first stepped cavity by deposition of a dielectric material therein. For example, a dielectric material such as silicon oxide can be deposited in the first stepped cavity. Excess portions of the deposited dielectric material can be removed from above the top surface of the first insulating cap layer 170, for example, by chemical mechanical planarization (CMP). The remaining portion of the deposited dielectric material filling the first stepped cavity constitutes the first stepped dielectric material portion 165. As used herein, a “stepped” element refers to an element that has first stepped surfaces and a horizontal cross-sectional area that increases monotonically as a function of a vertical distance from a top surface of a substrate on which the element is present. If silicon oxide is employed for the first stepped dielectric material portion 165, the silicon oxide of the first stepped dielectric material portion 165 may, or may not, be doped with dopants such as B, P, and/or F. In one embodiment, the first stepped dielectric material portion 165 overlies and contacts the first stepped surfaces, and has a top surface that is coplanar with the top surface of the first insulating cap layer 170.

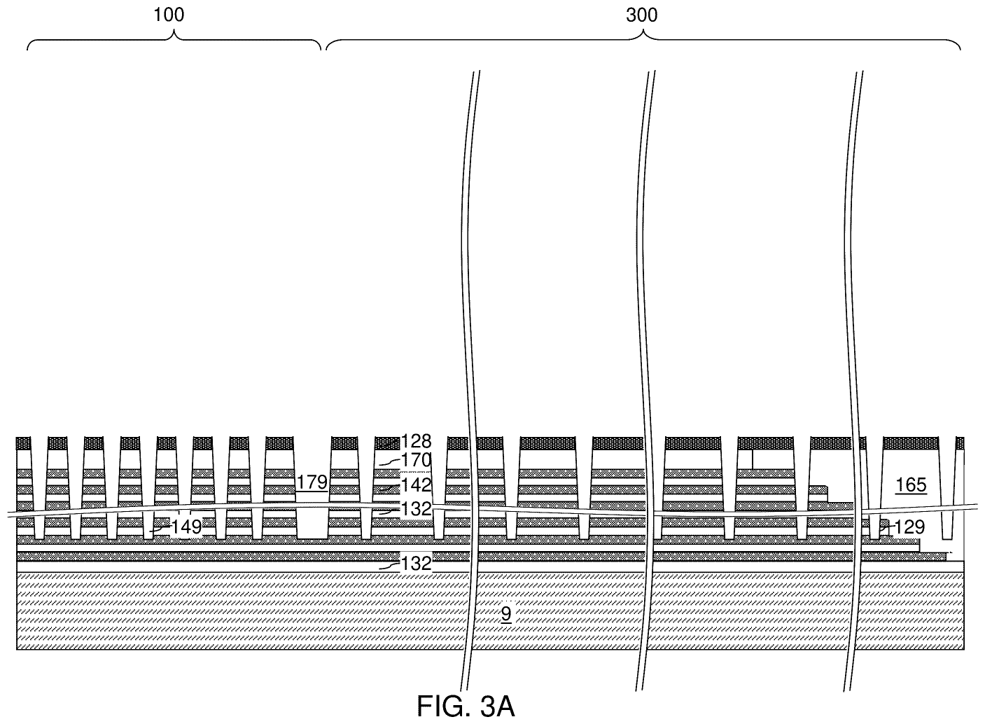

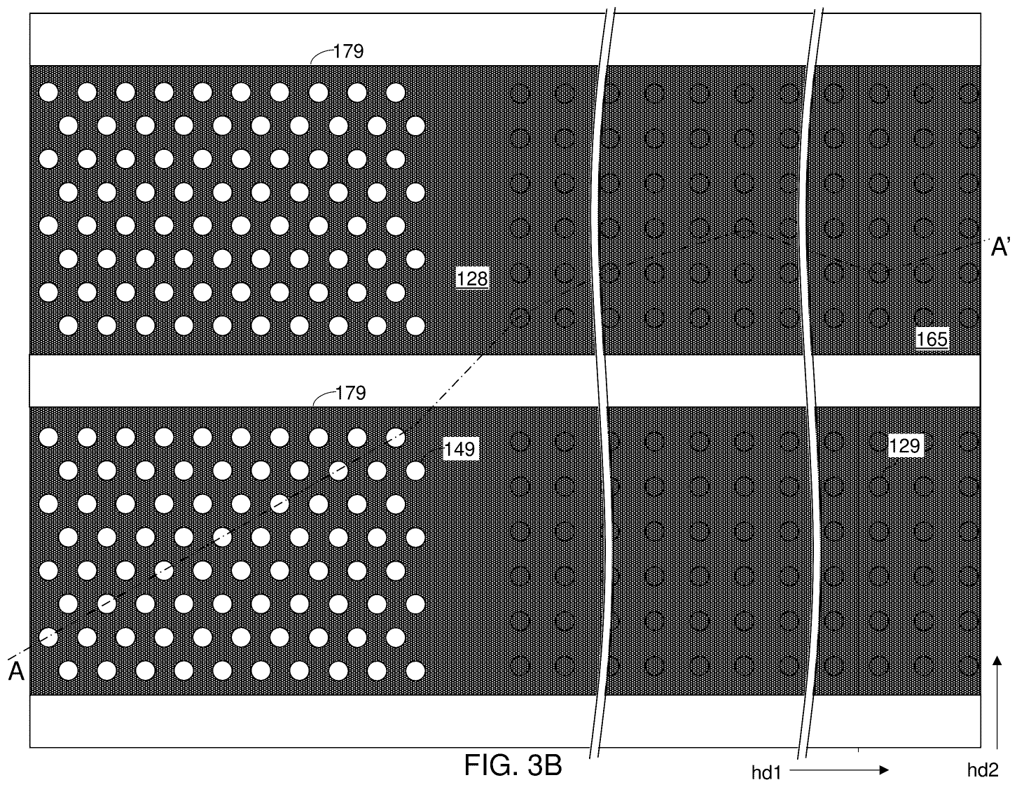

Referring to FIGS. 3A and 3B, a hard mask layer 128 can be formed over the first insulating cap layer 170. The hard mask layer 128 may comprise a carbon-based material, such as a carbon patterning film, which may comprise amorphous carbon or diamond-like carbon. A photoresist layer (not shown) can be formed above the hard mask layer 128, and can be lithographically patterned to form various openings therein. A first anisotropic etch process can be performed to transfer the pattern of the openings in the photoresist layer through the hard mask layer 128, the first insulating cap layer 170, and an upper portion of the combination of the first alternating stack (132, 142) and the first stepped dielectric material portion 165. The various openings may comprise first-tier memory openings 149 that are formed in the memory array region 100, first-tier support openings 129 that are formed in the contact region 300, and optionally first-tier lateral isolation trenches 179 that laterally extend along a first horizontal direction hd1 across the memory array region 100 and the contact region 300. Each of the first-tier memory openings 149, the first-tier support openings 129, and the first-tier lateral isolation trenches 179 can vertically extend through an upper subset of layers within the first alternating stack (132, 142) without extending into a lower subset of the layers within the first alternating stack (132, 142). In one embodiment, the fraction of layers within the first alternating stack (132, 142) through which each of the first-tier memory openings 149, the first-tier support openings 129, and the first-tier lateral isolation trenches 179 vertically extends may be in a range from 40% to 95%, such as from 50% to 90%, of all layers within the first alternating stack (132, 142). In an alternative embodiment, the first-tier memory openings 149 and the first-tier support openings 129 are formed during a separate masking and etching steps than the first-tier lateral isolation trenches 179

The first-tier support openings 129 may have a maximum diameter in a range from 50 nm to 400 nm, such as from 70 nm to 300 nm, although lesser and greater maximum diameters may be employed. The first-tier memory openings 149 may have a maximum diameter in a range from 50 nm to 400 nm, such as from 70 nm to 300 nm, although lesser and greater maximum diameters may be employed. The first-tier lateral isolation trenches 179 may have a width in a range from 150 nm to 1,000 nm, such as from 200 nm to 600 nm, although lesser and greater widths may also be employed.

In one embodiment, the memory array region 100 may be laterally spaced apart from the contact region 300 along a first horizontal direction hd1. The first-tier memory openings 149 may comprise rows of first-tier memory openings 149 that are arranged along the first horizontal direction hd1 and laterally spaced apart along a second horizontal direction hd2 that is perpendicular to the first horizontal direction hd2. Multiple clusters (e.g., memory block areas) of first-tier memory openings 149, each containing a respective two-dimensional periodic array of first-tier memory openings 149, may be formed in the memory array region 100. The clusters of first-tier memory openings 149 may be laterally spaced apart along the second horizontal direction hd2.

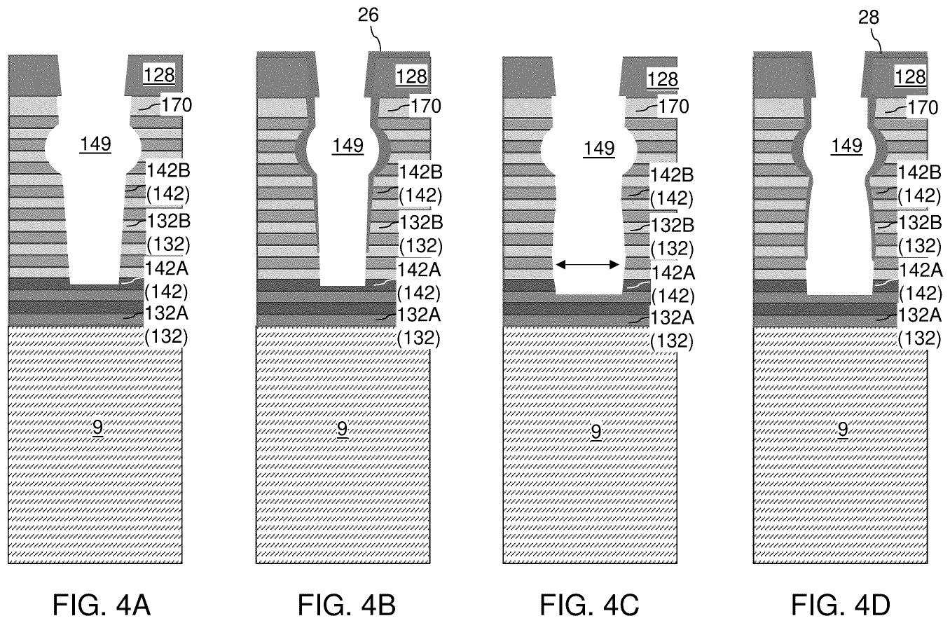

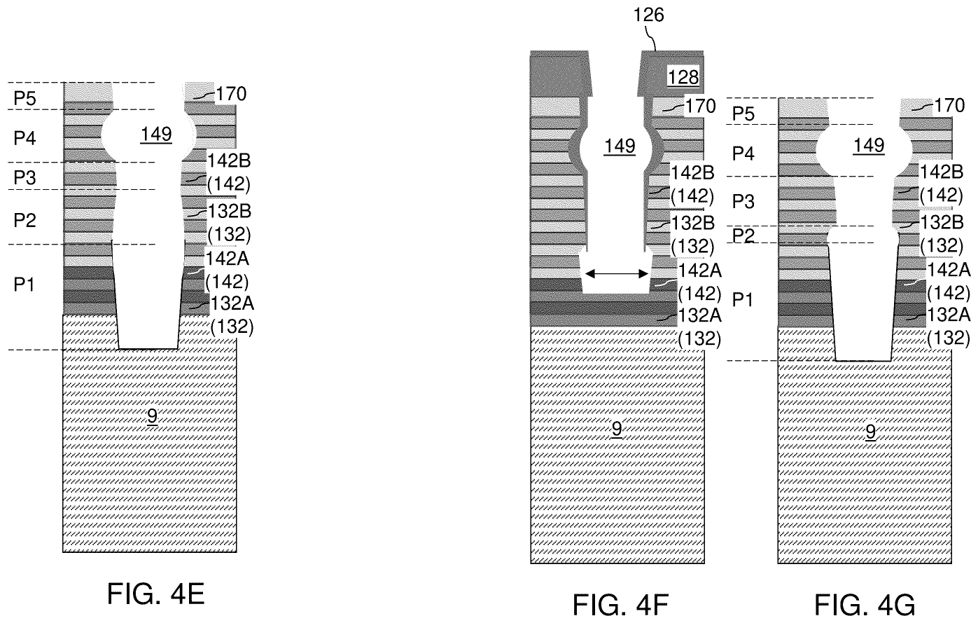

FIGS. 4A-4E are sequential vertical cross-sectional views of a first-tier opening during a first sequence of processing steps for extending and expanding the first-tier opening.

Referring to FIG. 4A, a first-tier opening is illustrated after the processing steps of FIGS. 3A and 3B. The first-tier opening may be a first-tier memory opening 149, a first-tier support opening 129, or a first-tier lateral isolation trench 179. The first-tier opening may have a generally tapered vertical cross-sectional profile with a bulging portion in proximity to the top portion of the first-tier opening. In this case, the first-tier opening may have a first tapered portion that underlies the bulging portion and having a first uniform taper angle relative to the vertical direction, the bulging portion that overlies the first tapered portion, and a second tapered portion that overlies the bulging portion and having a second uniform taper angle. The first uniform taper angle and the second uniform taper angle may be in a range from 0.1 degree to 5 degrees, such as from 0.2 degrees to 1 degree. The first insulating layers 132 may comprise lower insulating layers 132A and upper insulating layers 132B. The first sacrificial material layers 142 may comprise lower sacrificial material layers 142A and upper sacrificial material layers 142B. The first-tier opening will be laterally expanded at the levels of the lower insulating layers 132A and the lower sacrificial material layers 142A in a subsequent step.

Referring to FIG. 4B, a first etch mask layer 26 can be formed on a sidewall of the first-tier opening by performing an anisotropic deposition process. The first etch mask layer 26 comprises a material that can function as an etch mask for the purpose of subsequently isotropically etching the materials of the first insulating layers 132 and the first sacrificial material layers 142. For example, if the first insulating layers 132 comprise undoped silicate glass (i.e., silicon oxide) and if the first sacrificial material layers 142 comprise silicon nitride, the first etch mask layer 26 may comprise a material that has a similar or the same etch as silicon oxide and/or silicon nitride. For example, the first etch mask layer 26 may comprise silicon oxide, silicon nitride or silicon oxynitride.

The first etch mask layer 26 may be non-conformally deposited, for example, by performing a physical vapor deposition (PVD) process, a plasma-enhanced chemical vapor deposition (PECVD) process, or an atomic layer deposition process (ALD). The thickness of the first etch mask layer 26 decreases with a downward distance from the hard mask layer 128. In one embodiment, the first etch mask layer 26 may be isotropically etched to remove the bottommost portion of the first etch mask layer 26 at the bottom of the first-tier opening. The maximum thickness of the first etch mask layer 26 above the hard mask layer 128 may be in a range from 10 nm to 50 nm, although lesser and greater thicknesses may also be employed.

Referring to FIG. 4C, a second isotropic etch process may be performed to vertically extend and laterally expand the first-tier openings. The second isotropic etch process may comprise a wet etch process, such as a wet etch process that uses dilute hydrofluoric acid and/or phosphoric acid which extends both the depth and the width of the bottom of the first-tier opening that is not covered by the first etch mask layer 26. In one embodiment, the first etch mask layer 26 may be collaterally consumed (i.e., etched away) during the second isotropic etch process. Thus, an extended first-tier opening can be formed by vertically and horizontally extending the first-tier opening through the lower portion of the first alternating stack (132, 142) that is not covered by the first etch mask.

Referring to FIG. 4D, a second etch mask layer 28 can be formed on a sidewall of the first-tier opening by performing an anisotropic deposition process. The second etch mask layer 28 may comprise any material that can be employed for the first etch mask layer 26.

Referring to FIG. 4E, a third anisotropic etch process may be performed to vertically extend the first-tier openings. In one embodiment, the second etch mask layer 28 may also be collaterally consumed during the third anisotropic etch process.

In one embodiment, the first-tier opening can be converted into an expanded opening which comprises: a first portion P1 having a first variable width that increases linearly with a vertical distance from the base material layer (such as a substrate 9); a second portion P2 that overlies and is adjoined to the first portion P1 and having a second variable width that decreases non-linearly with the vertical distance from the base material layer (such as a substrate 9); and a third portion P3 that overlies and is adjoined to the second portion P2 and having a third variable width that increases linearly with the vertical distance from the base material layer (such as a substrate 9). Further, the expanded opening may comprise a fourth portion P4 that overlies and is adjoined to the third portion P3 and has a fourth variable width of which a maximum is located between a horizontal plane including a bottom end of the fourth portion P4 and a horizonal plane including a top end of the fourth portion P4; and a fifth portion P5 that overlies and is adjoined to the fourth portion P4 and has a fifth variable width that increases with the vertical distance from the base material layer (such as a substrate 9).

FIGS. 4F and 4G are sequential vertical cross-sectional views of a first-tier opening during a second sequence of processing steps for extending and expanding the first-tier opening.

Referring to FIG. 4F, a first etch mask layer 126 can be formed on a sidewall of the first-tier opening by performing an anisotropic deposition process. The first etch mask layer 126 comprises a material that can function as an etch mask for the purpose of subsequently isotropically etching the materials of the first insulating layers 132 and the first sacrificial material layers 142. For example, if the first insulating layers 132 comprise undoped silicate glass (i.e., silicon oxide) and if the first sacrificial material layers 142 comprise silicon nitride, the first etch mask layer 26 may comprise a material that has a lower etch rate than both silicon oxide and silicon nitride during the subsequent etching steps. For example, the first etch mask layer 26 may comprise amorphous carbon, diamond-like carbon, silicon carbonitride, or a dielectric metal oxide (e.g., aluminum oxide) material.

Subsequently, the second isotropic etch process is performed that isotropically etches the first insulating layers 132 and the first spacer material layers (such as the first sacrificial material layers 142) selective to the first etch mask layer 126. For example, the second isotropic etch process may comprise a wet etch that uses dilute hydrofluoric acid and/or alternating dilute hydrofluoric acid and hot phosphoric acid etches. The first-tier opening is laterally expanded at levels of the lower portion of the first alternating stack (132, 142) to provide an expanded opening. The lateral recess distance may be in a range from 1 nm to 30 nm, such as from 2 nm to 10 nm, although lesser and greater lateral recess distances may also be employed. In one embodiment, an annular convex tapered surface of the first-tier opening 149 that is proximal to a bottom end portion of the first etch mask layer 126 may have a uniform radius of curvature that equals that lateral etch distance. In this embodiment, the first etch mask layer 126 is not consumed during the second isotropic etch process.

Referring to FIG. 4G, the third anisotropic etch process can be performed to vertically extend through first-tier opening 149 through a lower subset of layers within the first alternating stack (132, 142) into the base material layer (such as the substrate 9). The bottom width of the first-tier opening can be increased through the processing steps described with reference to FIGS. 4B, 4F, and 4G. The first etch mask layer 126 may be removed after the third anisotropic etch process by ashing (if the first etch mask layer comprises a carbon material) or by selective etching.

In one embodiment, the first-tier opening can be converted into an expanded opening 149 which comprises: a first portion P1 having a first variable width that increases linearly with a vertical distance from the base material layer (such as a substrate 9); a second portion P2 that overlies and is adjoined to the first portion P1 and having a second variable width that decreases non-linearly with the vertical distance from the base material layer (such as a substrate 9) and laterally bounded by a tapered annular surface segment having a convex vertical profile and formed by the second isotropic etch process; and a third portion P3 that overlies and is adjoined to the second portion P2 and having a third variable width that increases linearly with the vertical distance from the base material layer (such as a substrate 9). Further, the expanded opening may comprise a fourth portion P4 that overlies and is adjoined to the third portion P3 and has a fourth variable width of which a maximum is located between a horizontal plane including a bottom end of the fourth portion P4 and a horizonal plane including a top end of the fourth portion P4; and a fifth portion P5 that overlies and is adjoined to the fourth portion P4 and has a fifth variable width that increases with the vertical distance from the base material layer (such as a substrate 9).

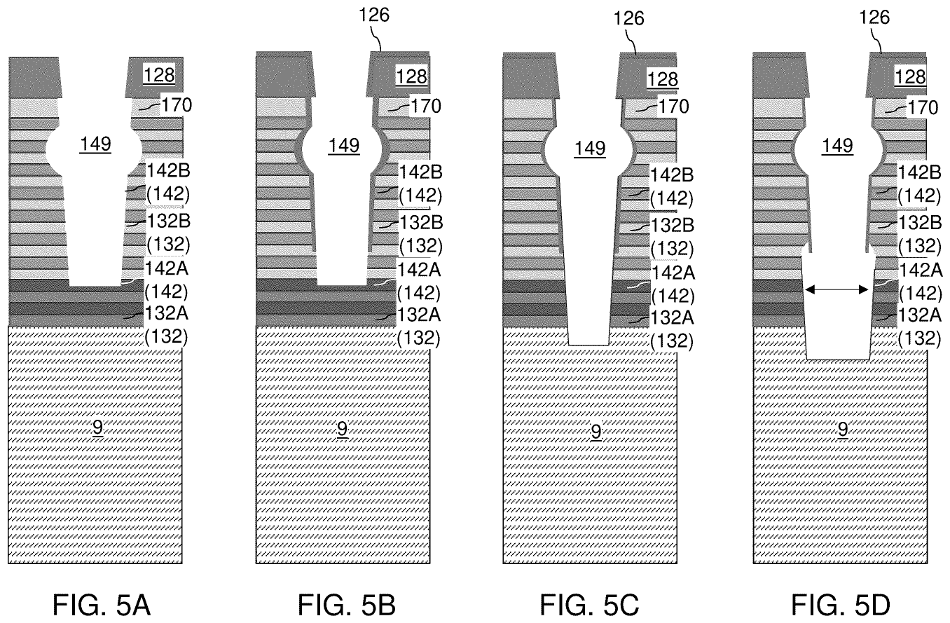

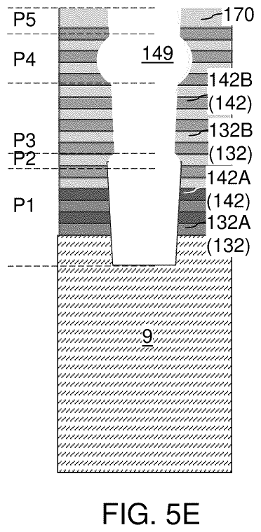

FIGS. 5A-5E are sequential vertical cross-sectional views of a first-tier opening during a third sequence of processing steps for extending and expanding the first-tier opening.

In the third sequence of processing steps, the order of the third anisotropic etch process and the second isotropic etch process within the second sequence of processing steps can be reversed. The first anisotropic etch process is performed as shown in FIG. 5A, followed by forming the first etch mask (e.g., a carbon etch mask) 126, as shown in FIG. 5B. Then, the third anisotropic etch process may be performed at a processing step shown in FIG. 5C while the first etch mask 126 is present in the first-tier opening 49, and the second isotropic etch process may be performed at a subsequent processing step shown in FIG. 5D. The first mask layer 126 is then removed by ashing or selective etching, as shown in FIG. 5E.

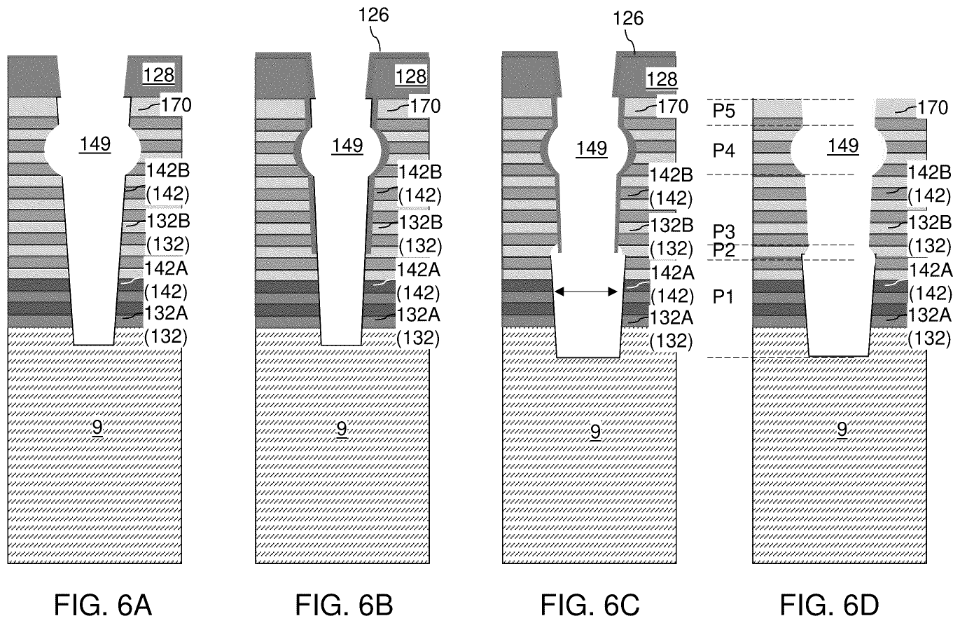

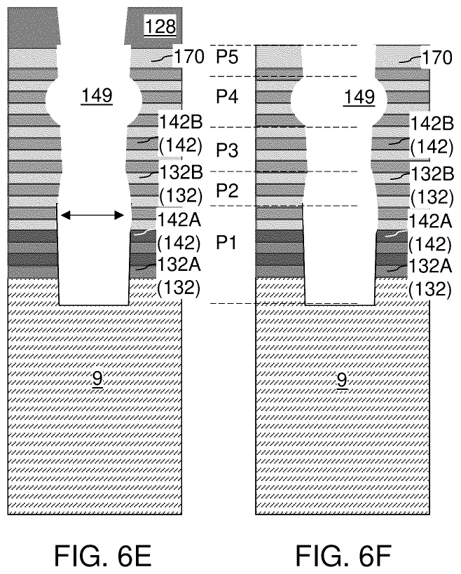

FIGS. 6A-6D are sequential vertical cross-sectional views of a first-tier opening during a fourth sequence of processing steps for extending and expanding the first-tier opening.

The fourth sequence of processing steps can be derived from the second sequence of processing steps described with reference to FIGS. 4A, 4B, 4F, and 4G by combining the first and the third anisotropic etching steps into one step. In this embodiment, the entire first alternating stack (132, 142) is anisotropically etched to expose the base material layer (such as a substrate 9), as shown in FIG. 6A. In this case, the first-tier opening 149 may vertically extend into the base material layer (such as the substrate 9). The first etch mask layer 126 is then formed in the first-tier opening 149, as shown in FIG. 6B. The isotropic etch step described above with respect to FIG. 4F is performed, as shown in FIG. 6C. The first etch mask layer 126 is then removed by ashing or selective etching, as shown in FIG. 6D.

FIGS. 6E and 6F are sequential vertical cross-sectional views of a first-tier opening during a fifth sequence of processing steps for extending and expanding the first-tier opening. The fifth sequence of processing steps can be derived from the fourth sequence of processing steps described with reference to FIGS. 6A-6C by performing the processing steps described with reference to FIG. 4E.

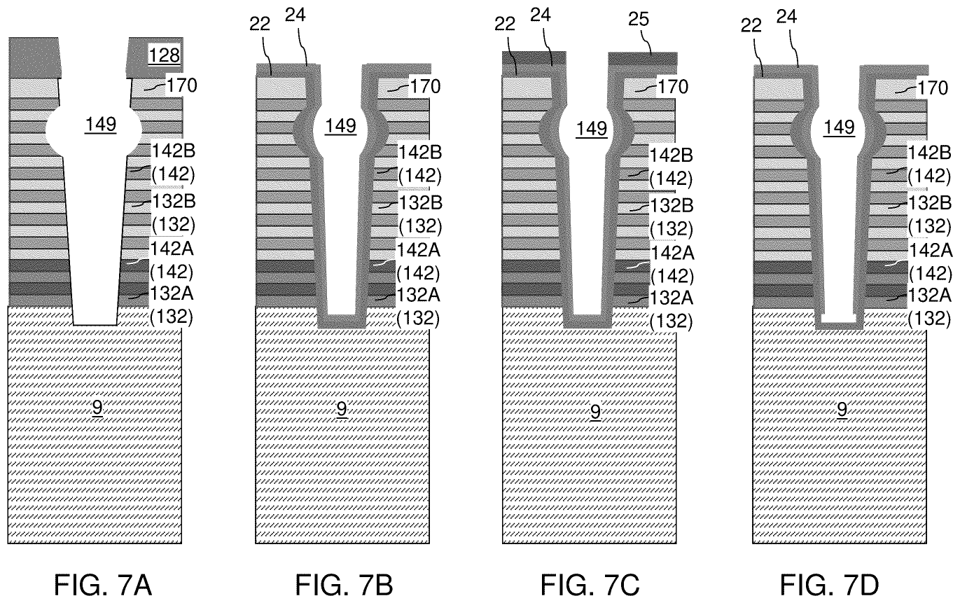

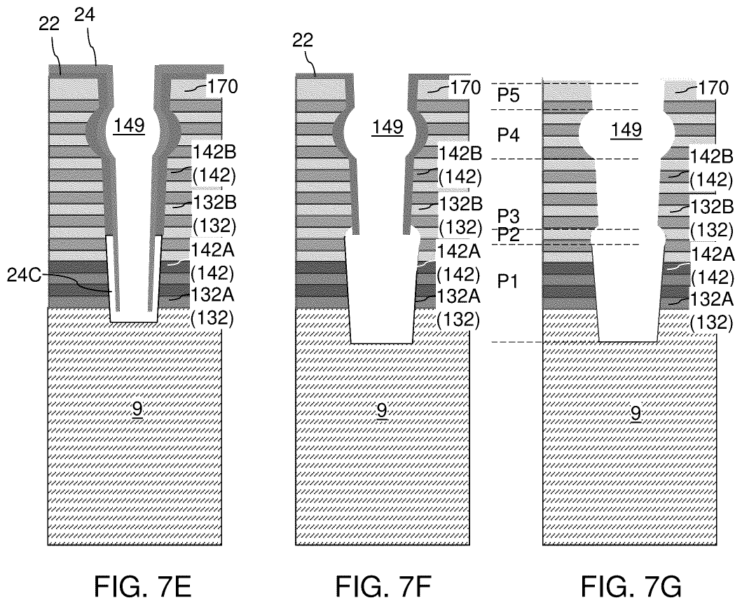

FIGS. 7A-7G are sequential vertical cross-sectional views of a first-tier opening during a sixth sequence of processing steps for extending and expanding the first-tier opening.

Referring to FIG. 7A, a first-tier opening 149 is illustrated, which may be derived from a first-tier opening obtained after the processing steps of FIGS. 3A and 3B by extending the first anisotropic etch process (e.g., by combining the first and the third anisotropic etch processes to expose base material layer (such as the substrate 9), as described above with respect to FIG. 6A. In this case, the first-tier opening may vertically extend into the base material layer (such as the substrate 9).

Referring to FIG. 7B, an etch mask layer 22 may be conformally or non-conformally deposited on the sidewall of the first-tier opening. The etch mask layer 22 may comprise any material that may be employed for the first etch mask layer 126. For example, the etch mask 22 may comprise a carbon material. A cover material layer 24 may be conformally or non-conformally deposited on the etch mask layer 22. The cover material layer 24 may be any material that may be etched selective to the material of the etch mask layer 22. In one embodiment, the cover material layer 24 may comprise silicon oxide, silicon nitride or silicon (e.g., amorphous silicon), and may have a thickness in a range from 3 nm to 20 nm, although lesser and greater thicknesses may also be employed.

Referring to FIG. 7C, a planar mask layer 25 may be formed above the topmost horizontal surface of the cover material layer 24 by anisotropically depositing a mask material, such as amorphous carbon or a carbon patterning film.

Referring to FIG. 7D, an anisotropic etch process can be performed to remove a horizontally-extending bottom portion of the cover material layer 24. The planar mask layer 25 may be collaterally removed during removal of the horizontally-extending bottom portion of the cover material layer 24.

Referring to FIG. 7E, an isotropic etch process can be performed to provide an isotropic etchant that etches the material of the etch mask layer 22 selective to the materials of the first alternating stack (132, 142), the cover material layer 24 and the base material layer (e.g., the substrate 9). A tubular cavity 24C laterally surrounds a tubular bottom portion of the cover material layer 24.

Referring to FIG. 7F, at least one isotropic etch process can be performed to isotropically etch the materials of the first alternating stack (132, 142), and optionally to isotropically etch the material of the cover material layer 24 and the base material layer (e.g., the substrate 9). The lateral recess distance of the at least one isotropic etch process may be in a range from 1 nm to 30 nm, such as from 2 nm to 10 nm, although lesser and greater lateral recess distances may also be employed. In one embodiment, an annular convex tapered surface of the first-tier opening 149 that is proximal to a bottom end portion of the etch mask layer 22 may have a uniform radius of curvature that equals that lateral etch distance. In one embodiment, the cover material layer 24 may comprise a same material as a first insulating layer 132 or a first sacrificial material layer 142, and may be collaterally removed during the at least one anisotropic etch process.

Referring to FIG. 7G, the etch mask layer 22 may be subsequently removed selective to the materials of the first alternating stack (132, 142) and the base material layer by ashing or selective etching.

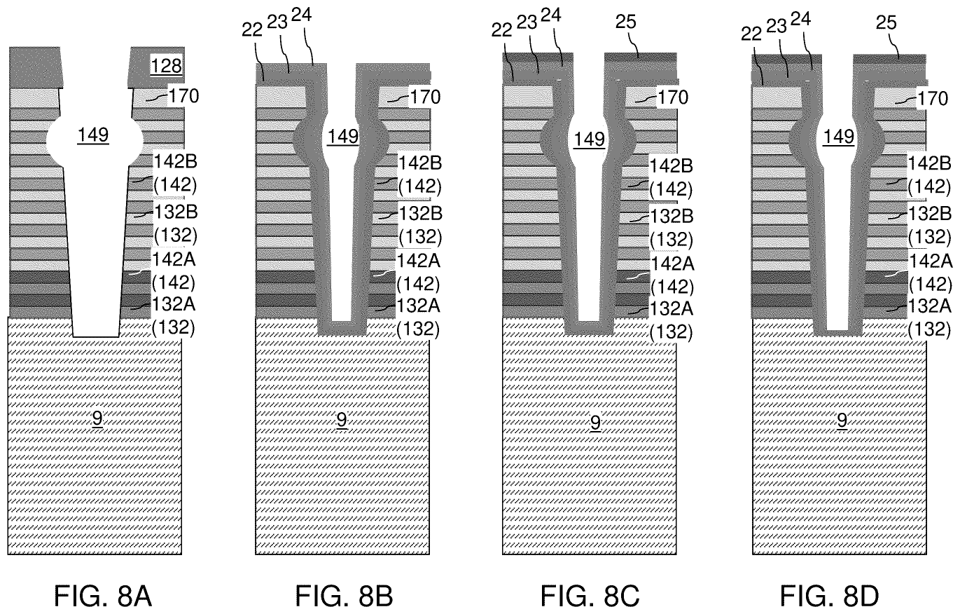

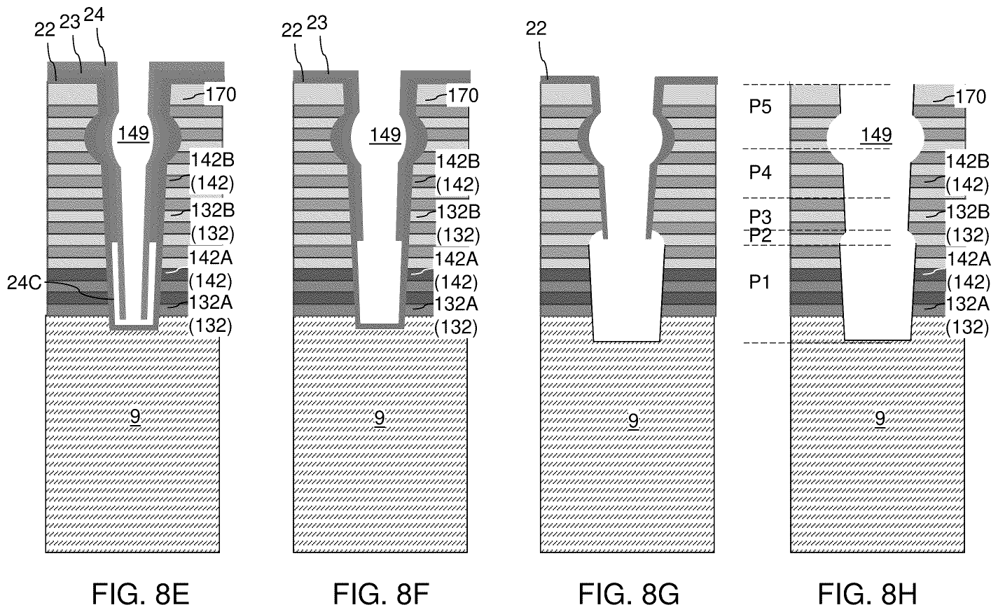

FIGS. 8A-8H are sequential vertical cross-sectional views of a first-tier opening during a seventh sequence of processing steps for extending and expanding the first-tier opening.

Referring to FIG. 8A, a first-tier opening 149 is illustrated, which may be the same as the first-tier opening shown in FIG. 7A.

Referring to FIG. 8B, an etch mask layer 22 may be conformally or non-conformally deposited on the sidewall of the first-tier opening. The etch mask layer 22 may comprise any material that may be employed for the first etch mask layer 126, such as carbon material. An intermediate material layer 23 may be formed over the etch mask layer 22. In one embodiment, the intermediate material layer 23 may comprise amorphous silicon. A cover material layer 24 may be conformally or non-conformally deposited on the intermediate material layer 23. The cover material layer 24 may be any material that may be etched selective to the material of the etch mask layer 22 and/or the intermediate material layer 23.

Referring to FIG. 8C, a planar mask layer 25 may be formed above the topmost horizontal surface of the cover material layer 24 by anisotropically depositing a mask material, such as amorphous carbon or a carbon patterning film.

Referring to FIG. 8D, an anisotropic etch process can be performed to remove horizontally-extending bottom portions of the cover material layer 24 and the intermediate material layer 23. The planar mask layer 25 may be collaterally removed during removal of the horizontally-extending bottom portions of the cover material layer 24 and the intermediate material layer 23.

Referring to FIG. 8E, an isotropic etch process can be performed to provide an isotropic etchant that etches the material of the intermediate material layer 23 selective to the materials of the etch mask layer 22 and the cover material layer 24. For example, a trimethyl-2 hydroxyethyl ammonium hydroxide (“TMY”) selective etch may be used to etch an amorphous silicon intermediate material layer 23. A tubular cavity 24C laterally surrounds a tubular bottom portion of the cover material layer 24.

Referring to FIG. 8F, an isotropic etch process may be performed to remove the cover material later 24. For example, if the cover material layer comprise silicon oxide, a wet etch process employing dilute hydrofluoric acid may be performed to remove the cover material layer 24.

Referring to FIG. 8G, another isotropic etch process may be performed to remove portions of the etch mask layer 22 that are not covered by the intermediate material layer 23. At least one isotropic etch process can be performed to isotropically etch the materials of the first alternating stack (132, 142), and optionally to isotropically etch the material of the base material layer. The lateral recess distance of the at least one isotropic etch process may be in a range from 1 nm to 30 nm, such as from 2 nm to 10 nm, although lesser and greater lateral recess distances may also be employed. In one embodiment, an annular convex tapered surface of the first-tier opening that is proximal to a bottom end portion of the etch mask layer 22 may have a uniform radius of curvature that equals that lateral etch distance. In one embodiment, the intermediate material layer 23 may be collaterally removed during the at least one isotropic etch process.

Referring to FIG. 8G, the etch mask layer 22 may be subsequently removed selective to the materials of the first alternating stack (132, 142) and the base material layer (e.g., the substrate 9) by ashing or selective etching.

Referring collectively to FIGS. 4E, 4G, 5E, 6D, 6F, 7G and 8H, the first-tier opening can be converted into an expanded opening which comprises: a first portion P1 having a first variable width that increases linearly with a vertical distance from the base material layer (such as a substrate 9); a second portion P2 that overlies and is adjoined to the first portion P1 and having a second variable width that decreases non-linearly with the vertical distance from the base material layer (such as a substrate 9) and optionally laterally bounded by a tapered annular surface segment having a convex vertical profile and formed by the at least one isotropic etch process; and a third portion P3 that overlies and is adjoined to the second portion P2 and having a third variable width that increases linearly with the vertical distance from the base material layer (such as a substrate 9). Further, the expanded opening may comprise a fourth portion P4 that overlies and is adjoined to the third portion P3 and has a fourth variable width of which a maximum is located between a horizontal plane including a bottom end of the fourth portion P4 and a horizonal plane including a top end of the fourth portion P4; and a fifth portion P5 that overlies and is adjoined to the fourth portion P4 and has a fifth variable width that increases with the vertical distance from the base material layer (such as a substrate 9). As discussed above, the first-tier opening may be any of a first-tier memory opening 149, a first-tier support opening 129, or a first-tier lateral isolation trench 179.

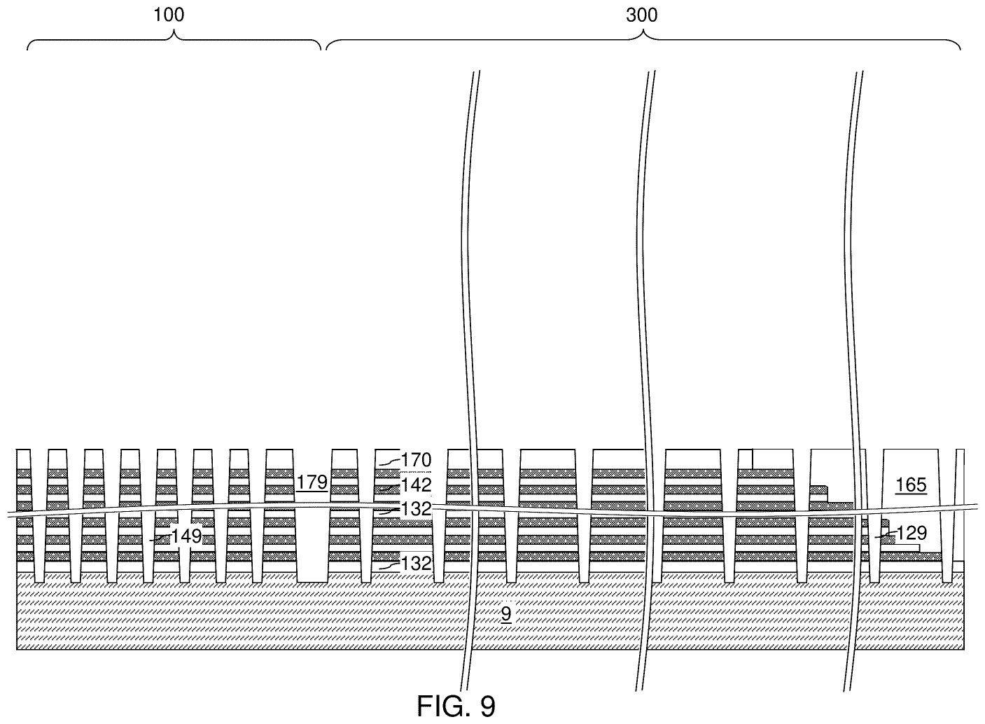

Referring to FIG. 9, the exemplary structure is illustrated after extending and expanding the first-tier memory openings 149, the first-tier support openings 129, and the first-tier lateral isolation trenches 179. The structures of the first-tier memory openings 149, the first-tier support openings 129, and the first-tier lateral isolation trenches 179 may have any configuration among the configurations of FIGS. 4E, 4G, 5E, 6D, 6F, 7G, and 8H.

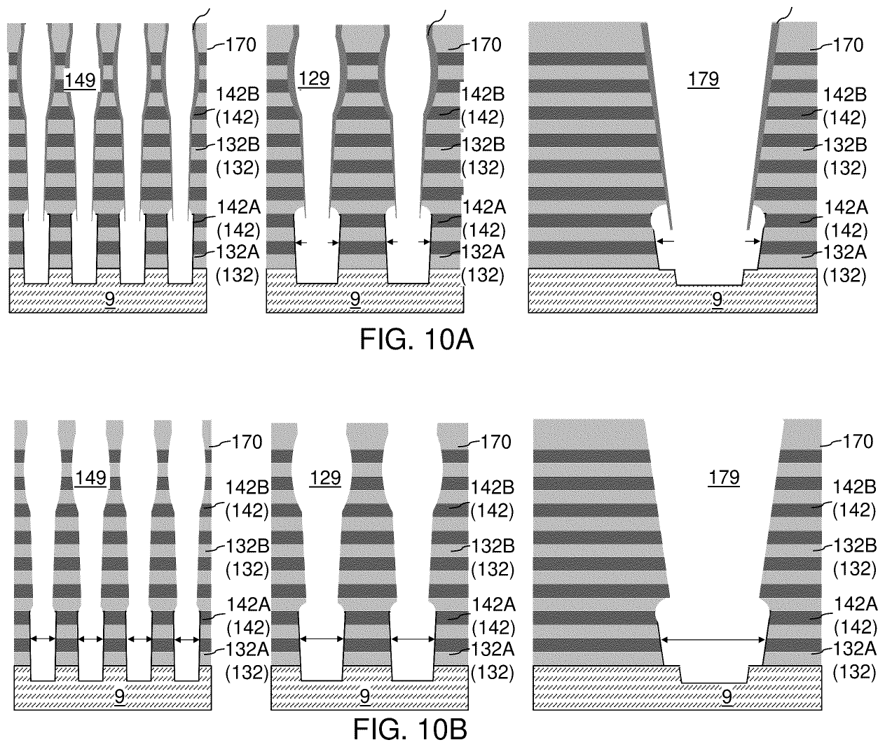

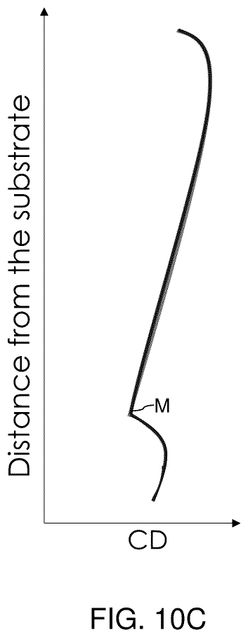

FIG. 10A illustrates vertical cross-sectional views of various first-tier openings (129, 149, 179) after expansion of lower portions of the first-tier openings. A tapered concave surface segment of each first-tier opening may have a radius of curvature that is the same as the etch distance of the isotropic etch process.

FIG. 10B illustrates vertical cross-sectional views of various first-tier openings after removal of the etch mask layer (22, 26, 28, 126).

FIG. 10C is a vertical profile of a width (e.g., CD) of a first-tier opening as a function of height (e.g., distance from the substrate 9) after extending and expanding the first-tier opening according to an embodiment of the present disclosure. A local minimum “M” in the width of a first-tier opening may occur at a top edge of the tapered concave surface segment of a first-tier opening. If the first-tier opening comprises a first-tier memory opening 149 or a first-tier support opening 129, the tapered concave surface segment may be an annular tapered concave surface segment. If the first-tier opening comprises a first-tier lateral isolation trench 179, the tapered concave surface segment may comprise a pair of tapered concave surface segment that laterally extend along the first horizontal direction hd1.

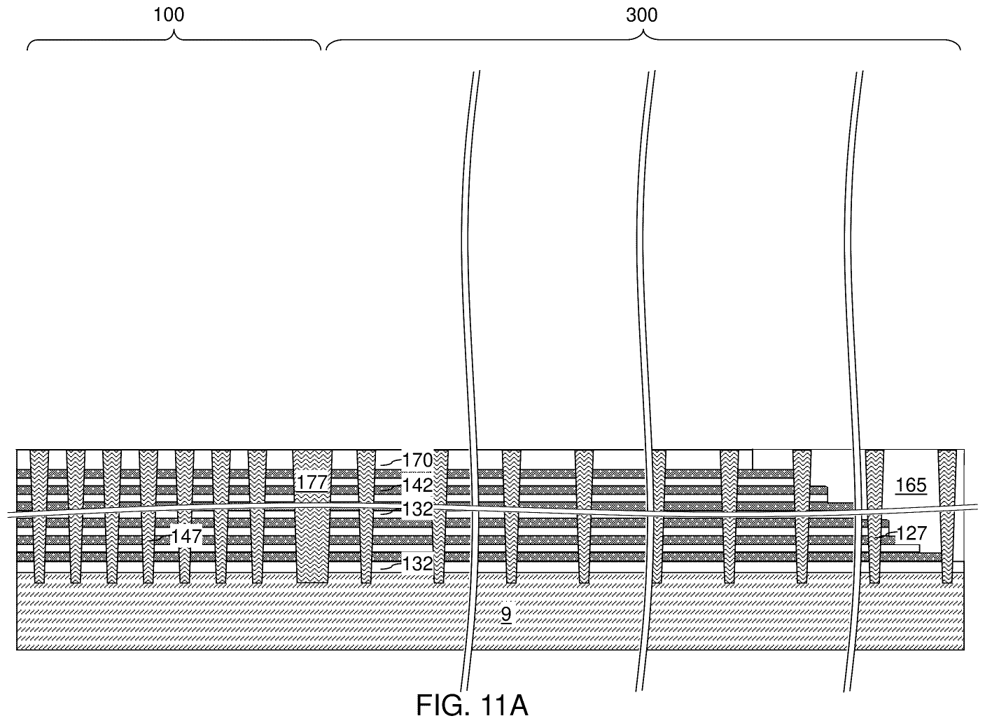

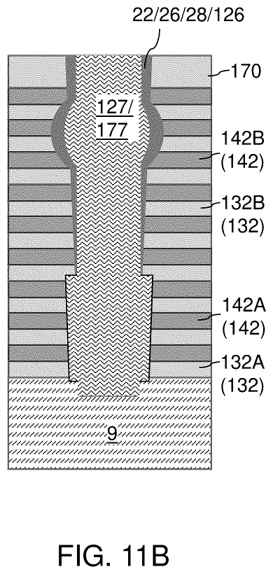

Referring to FIG. 11A, an optional etch stop liner (not shown) and a first sacrificial fill material can be deposited in the first-tier memory openings 149, the first-tier support openings 129, and the first-tier lateral isolation trenches 179. The optional etch stop liner (if present) comprises a thin silicon oxide layer having a thickness in a range from 1 nm to 6 nm. The first sacrificial fill material may comprise a carbon-based material, such as amorphous carbon or diamond-like carbon.

The hard mask layer 128 can be removed selective to the material of the first insulating cap layer 170 either during or after the etching steps described above. A planarization process can be performed to remove portions of the first sacrificial fill material from above the horizontal plane including the top surface of the first insulating cap layer 170. Remaining portions of the first sacrificial fill material that fill the first-tier memory openings 149, the first-tier support openings 129, and the first-tier lateral isolation trenches 179 constitute respective first sacrificial opening fill material portions (147, 127, 177). The first sacrificial opening fill material portions (147, 127, 177) comprise first sacrificial memory opening fill material portions 147 that are formed in the first-tier memory openings 149, first sacrificial support opening fill material portions 127 that are formed in the first-tier support openings 129, and optional first sacrificial lateral isolation trench fill material portions 177 that are formed in the first-tier lateral isolation trenches 179.

Referring to FIG. 11B, an alternative embodiment of a first sacrificial opening fill material portion (127, 177) is illustrated. In this case, the etch mask layer (22, 26, 28, 126) comprises an inorganic dielectric material, such as silicon oxide or a dielectric metal oxide, and is not removed prior to deposition of the first sacrificial fill material. In this case, an etch mask layer (22, 26, 28, 126) may be present within a first-tier support openings 129 or a first-tier lateral isolation trenches 179 as a tubular dielectric liner.

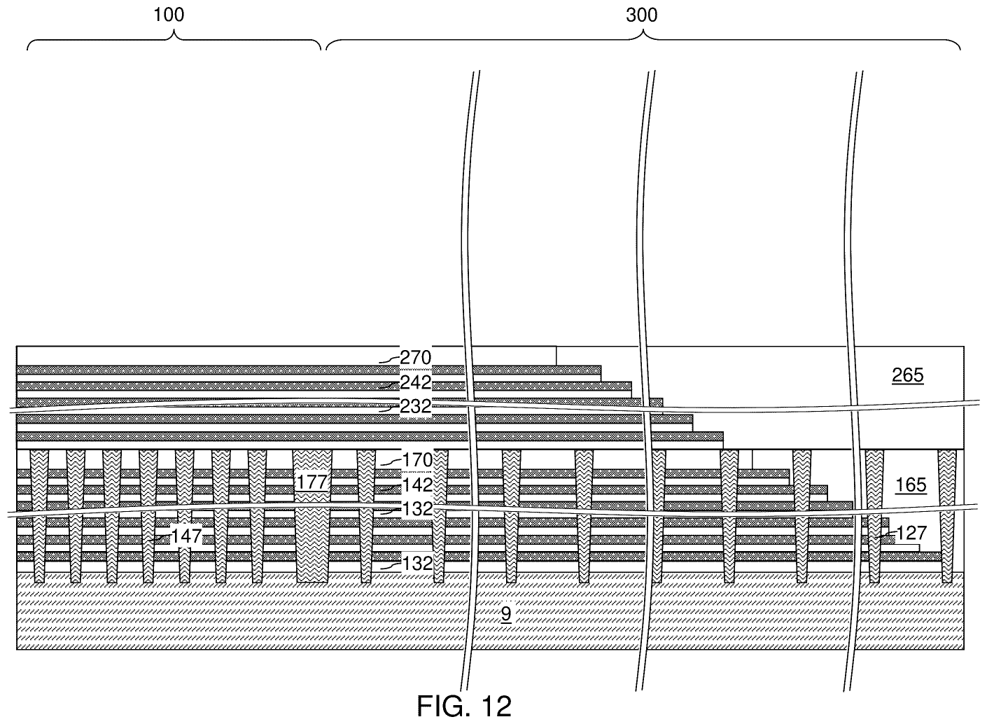

Referring to FIG. 12, a second alternating stack of second insulating layers 232 and second spacer material layers can be formed over the first insulating cap layer 170. In one embodiment, the second spacer material layers may comprise second sacrificial material layers 242. In this case, a second alternating stack (232, 242) of second insulating layers 232 and second sacrificial material layers 242 can be formed over the first insulating cap layer 170. In one embodiment, the second insulating layers 232 may comprise silicon oxide layers, and the second sacrificial material layers 242 may comprise silicon nitride layers. The second alternating stack (232, 242) may comprise multiple repetitions of a unit layer stack including a second insulating layer 232 and a second sacrificial material layer 242. The total number of repetitions of the unit layer stack within the second alternating stack (232, 242) may be, for example, in a range from 8 to 2,024, such as from 32 to 256, although lesser and greater number of repetitions may also be employed.

A second insulating cap layer 270 can be formed over the second alternating stack (232, 242). In one embodiment, the second insulating cap layer 270 has a homogeneous material composition throughout. In one embodiment, the second insulating cap layer 270 comprises, and/or consists essentially of silicon oxide. The second insulating cap layer 270 may have the same thickness and composition as the first insulating cap layer 270. Second stepped surfaces are formed in the contact region 300. A second stepped cavity is formed within the volume from which portions of the second alternating stack (232, 242) and the second insulating cap layer 270 are removed through formation of the second stepped surfaces.

A second stepped dielectric material portion 265 (i.e., an insulating fill material portion) can be formed in the second stepped cavity by deposition of a dielectric material followed by planarization. The second stepped dielectric material portion 265 may have the same composition and configuration as the first stepped dielectric material portion 165.

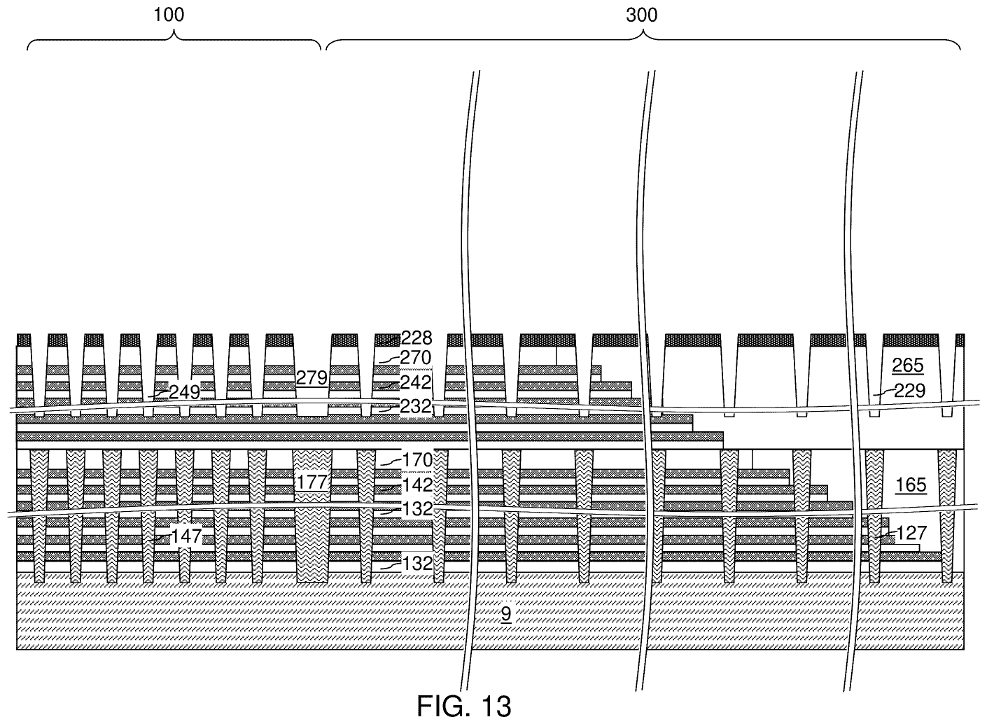

Referring to FIG. 13, a hard mask layer 228 can be formed over the second insulating cap layer 270. The hard mask layer 228 may comprise a carbon-based material, such as a patterning film, amorphous carbon, or diamond-like carbon. A photoresist layer (not shown) can be formed above the hard mask layer 228, and can be lithographically patterned to form various openings therein. The pattern of the opening in the photoresist layer at the processing steps of FIG. 13 may be the same as the pattern of the openings in the hard mask layer 128 at the processing steps of FIGS. 3A and 3B.

An anisotropic etch process can be performed to transfer the pattern of the openings in the photoresist layer through the hard mask layer 228. The photoresist layer may be removed after patterning the hard mask layer 228. Another anisotropic etch process can be performed to transfer the pattern of the openings in the hard mask layer 228 through the second insulating cap layer 270, and an upper portion of the combination of the second alternating stack (232, 242) and the second stepped dielectric material portion 265. The various openings may comprise second-tier memory openings 249 that are formed in the memory array region 100, second-tier support openings 229 that are formed in the contact region 300, and second-tier lateral isolation trenches 279 that laterally extend along a second horizontal direction hd2 across the memory array region 100 and the contact region 300. Each of the second-tier memory openings 249, the second-tier support openings 229, and the second-tier lateral isolation trenches 279 can vertically extend through an upper subset of layers within the second alternating stack (232, 242) without extending into a lower subset of the layers within the second alternating stack (232, 242). In one embodiment, the fraction of layers within the second alternating stack (232, 242) through which each of the second-tier memory openings 249, the second-tier support openings 229, and the second-tier lateral isolation trenches 279 vertically extends may be in a range from 40% to 95%, such as from 50% to 90%, of all layers within the second alternating stack (232, 242).

The second-tier support openings 229 may have a maximum diameter in a range from 50 nm to 400 nm, such as from 70 nm to 300 nm, although lesser and greater maximum diameters may be employed. The second-tier memory openings 249 may have a maximum diameter in a range from 50 nm to 400 nm, such as from 70 nm to 300 nm, although lesser and greater maximum diameters may be employed. The second-tier lateral isolation trenches 279 may have a width in a range from 150 nm to 2,000 nm, such as from 200 nm to 600 nm, although lesser and greater widths may also be employed. Alternatively, the second-tier lateral isolation trenches 279 may be formed during separate masking and etching steps from the second-tier support and memory openings (229, 249).

In one embodiment, the memory array region 100 may be laterally spaced apart from the contact region 300 along a second horizontal direction hd2. The second-tier memory openings 249 may comprise rows of second-tier memory openings 249 that are arranged along the second horizontal direction hd2 and laterally spaced apart along a second horizontal direction hd2 that is perpendicular to the first horizontal direction hd1. Multiple clusters of second-tier memory openings 249, each containing a respective two-dimensional periodic array of second-tier memory openings 249, may be formed in the memory array region 100. The clusters of second-tier memory openings 249 may be laterally spaced apart along the second horizontal direction hd2.

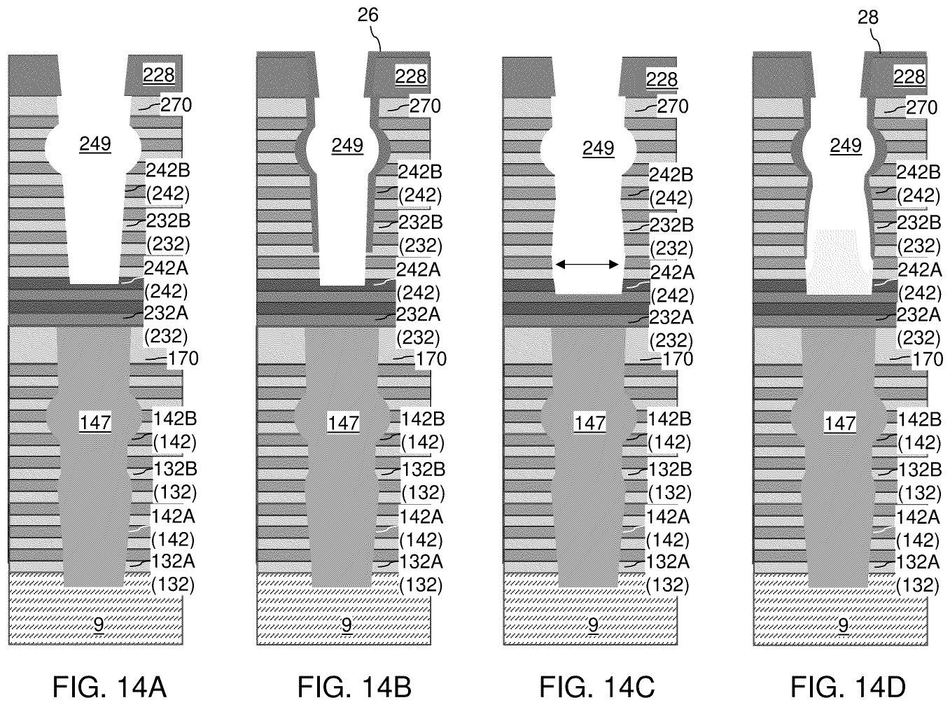

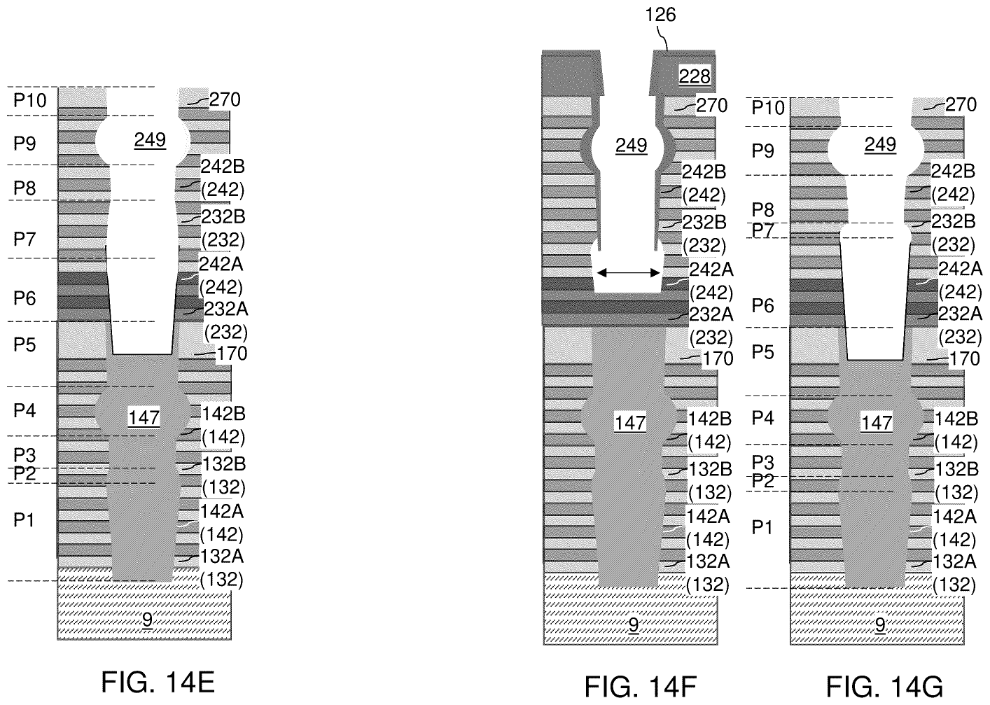

FIGS. 14A-14E are sequential vertical cross-sectional views of a second-tier opening during a first sequence of processing steps for extending and expanding the second-tier opening.

Referring to FIG. 14A, a second-tier opening is illustrated after the processing steps of FIG. 13. The second-tier opening may be formed above a first-tier opening that is filled within a respective first sacrificial opening fill material portion (147, 127, 177). The second-tier opening may be a second-tier memory opening 249, a second-tier support opening 229, or a second-tier lateral isolation trench 179. The second-tier opening may have a generally tapered vertical cross-sectional profile with a bulging portion in proximity to the top portion of the second-tier opening. In this case, the second-tier opening may have a first tapered portion that underlies the bulging portion and having a first uniform taper angle relative to the vertical direction, the bulging portion that overlies the first tapered portion, and a second tapered portion that overlies the bulging portion and having a second uniform taper angle. The first uniform taper angle and the second uniform taper angle may be in a range from 0.1 degree to 5 degrees, such as from 0.2 degrees to 2 degree. The second insulating layers 232 may comprise lower insulating layers 232A and upper insulating layers 232B. The second sacrificial material layers 242 may comprise lower sacrificial material layers 242A and upper sacrificial material layers 242B. The second-tier opening will be laterally expanded at the levels of the lower insulating layers 232A and the lower sacrificial material layers 242A in a subsequent step.

Referring to FIG. 14B, a first etch mask layer 26 can be formed on a sidewall of the second-tier opening by performing an anisotropic deposition process. The first etch mask layer 26 comprises a material that can function as an etch mask for the purpose of subsequently isotropically etching the materials of the second insulating layers 232 and the second sacrificial material layers 242. For example, if the second insulating layers 232 comprise undoped silicate glass and if the second sacrificial material layers 242 comprise silicon nitride, the first etch mask layer 26 may comprise a material that has a similar or the same etch as silicon oxide and/or silicon nitride. For example, the first etch mask layer 26 may comprise silicon oxide, silicon nitride or silicon oxynitride.

The first etch mask layer 26 may be non-conformally deposited, for example, by performing a physical vapor deposition (PVD) process, a plasma-enhanced chemical vapor deposition (PECVD) process or an ALD process. The thickness of the first etch mask layer 26 decreases with a downward distance from the hard mask layer 228. In one embodiment, the first etch mask layer 26 may be isotropically etched to remove the bottommost portion of the first etch mask layer 26 at the bottom of the second-tier opening. The maximum thickness of the first etch mask layer 26 above the hard mask layer 228 may be in a range from 20 nm to 50 nm, although lesser and greater thicknesses may also be employed.

Referring to FIG. 14C, a second isotropic etch process may be performed to vertically extend and laterally expand the first-tier openings. The second isotropic etch process may comprise a wet etch process, such as a wet etch process that uses dilute hydrofluoric acid and/or phosphoric acid which extends both the depth and the width of the bottom of the first-tier opening that is not covered by the first etch mask layer 26. In one embodiment, the first etch mask layer 26 may be collaterally consumed (i.e., etched away) during the second isotropic etch process. Thus, an extended first-tier opening can be formed by vertically and horizontally extending the first-tier opening through the lower portion of the second alternating stack (232, 242) that is not covered by the first etch mask.

Referring to FIG. 14D, a second etch mask layer 28 can be formed on a sidewall of the second-tier opening by performing an anisotropic deposition process. The second etch mask layer 28 may comprise any material that can be employed for the first etch mask layer 26.

Referring to FIG. 14E, a third anisotropic etch process may be performed to vertically extend the second-tier openings into the respective first sacrificial opening fill material portions (147, 127, 177). In one embodiment, the second etch mask layer 28 may also be collaterally consumed during the third anisotropic etch process.

In one embodiment, the second-tier opening can be converted into an expanded opening, and is adjoined to a first-tier opening which is filled with a first sacrificial opening fill material portion (147, 127, 177). The first-tier opening comprises a first portion P1 having a first variable width that increases linearly with a vertical distance from the base material layer (such as a substrate 9); a second portion P2 that overlies and is adjoined to the first portion P1 and having a second variable width that decreases non-linearly with the vertical distance from the base material layer (such as a substrate 9); and a third portion P3 that overlies and is adjoined to the second portion P2 and having a third variable width that increases linearly with the vertical distance from the base material layer (such as a substrate 9). Further, the expanded opening may comprise a fourth portion P4 that overlies and is adjoined to the third portion P3 and has a fourth variable width of which a maximum is located between a horizontal plane including a bottom end of the fourth portion P4 and a horizonal plane including a top end of the fourth portion P4; and a fifth portion P5 that overlies and is adjoined to the fourth portion P4 and has a fifth variable width that increases with the vertical distance from the base material layer (such as a substrate 9).

The second-tier opening comprises: a sixth portion P6 having a sixth variable width that increases linearly with a vertical distance from the base material layer (such as a substrate 9); a seventh portion P7 that overlies and is adjoined to the sixth portion P6 and having a seventh variable width that decreases non-linearly with the vertical distance from the base material layer (such as a substrate 9); and an eighth portion P8 that overlies and is adjoined to the seventh portion P7 and having an eighth variable width that increases linearly with the vertical distance from the base material layer (such as a substrate 9). Further, the expanded opening may comprise a ninth portion P9 that overlies and is adjoined to the eighth portion P8 and has a ninth variable width of which a maximum is located between a horizontal plane including a bottom end of the ninth portion P9 and a horizonal plane including a top end of the ninth portion P9; and a tenth portion P10 that overlies and is adjoined to the ninth portion P9 and has a tenth variable width that increases with the vertical distance from the base material layer (such as a substrate 9).

FIGS. 14F and 14G are sequential vertical cross-sectional views of a second-tier opening during a second sequence of processing steps for extending and expanding the second-tier opening.

Referring to FIG. 14F, a first etch mask layer 126 can be formed on a sidewall of the second-tier opening by performing an anisotropic deposition process. The first etch mask layer 126 comprises a material that can function as an etch mask for the purpose of subsequently isotropically etching the materials of the second insulating layers 232 and the second sacrificial material layers 242. For example, if the second insulating layers 232 comprise undoped silicate glass (i.e., silicon oxide) and if the second sacrificial material layers 242 comprise silicon nitride, the first etch mask layer 126 may comprise a material that has a lower etch rate than both silicon oxide and silicon nitride during the subsequent etching steps. For example, the first etch mask layer 126 may comprise amorphous carbon, diamond-like carbon, silicon carbonitride, or a dielectric metal oxide (e.g., aluminum oxide) material.

Subsequently, the second isotropic etch process is performed that isotropically etches the second insulating layers 232 and the second spacer material layers (such as the second sacrificial material layers 242) selective to the first etch mask layer 126. For example, the second isotropic etch process may comprise a wet etch that uses dilute hydrofluoric acid and/or alternating dilute hydrofluoric acid and hot phosphoric acid etches. The second-tier opening is laterally expanded at levels of the lower portion of the second alternating stack (232, 242) to provide an expanded opening. The lateral recess distance may be in a range from 1 nm to 30 nm, such as from 2 nm to 10 nm, although lesser and greater lateral recess distances may also be employed. In one embodiment, an annular convex tapered surface of the second-tier opening 249 that is proximal to a bottom end portion of the first etch mask layer 126 may have a uniform radius of curvature that equals that lateral etch distance. In this embodiment, the first etch mask layer 126 is not consumed during the second isotropic etch process.

Referring to FIG. 14G, the third anisotropic etch process can be performed to vertically extend through second-tier opening 249 through a lower subset of layers within the first alternating stack (132, 142) into the first sacrificial opening fill material portion (147, 127, 177). The bottom width of the first-tier opening can be increased through the processing steps described with reference to FIGS. 4B, 4F, and 4G. The first etch mask layer 126 may be removed after the third anisotropic etch process by ashing (if the first etch mask layer comprises a carbon material) or by selective etching.

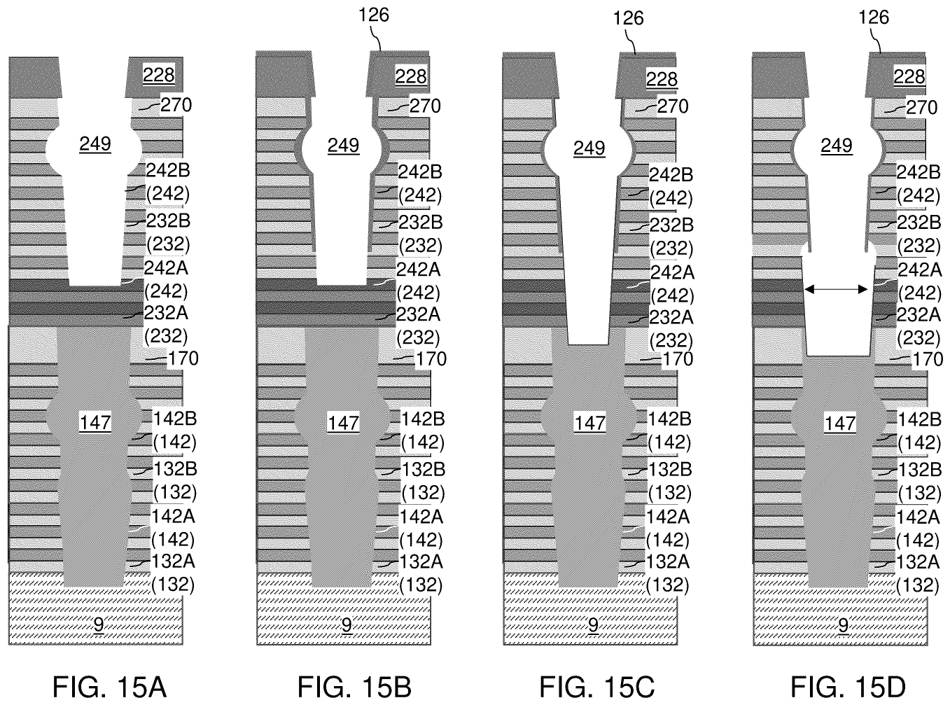

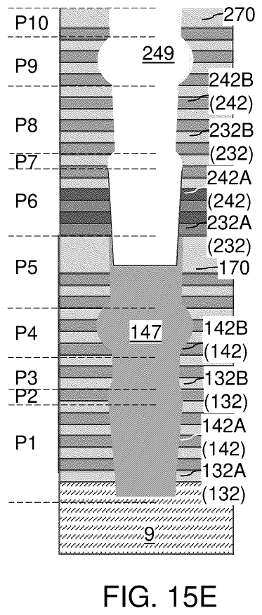

FIGS. 15A-15E are sequential vertical cross-sectional views of a second-tier opening during a third sequence of processing steps for extending and expanding the second-tier opening. FIGS. 15A-15E comprise the same steps as those illustrated and described above with respect to FIGS. 5A-5E, but that are performed on the second alternating stack (232, 242).

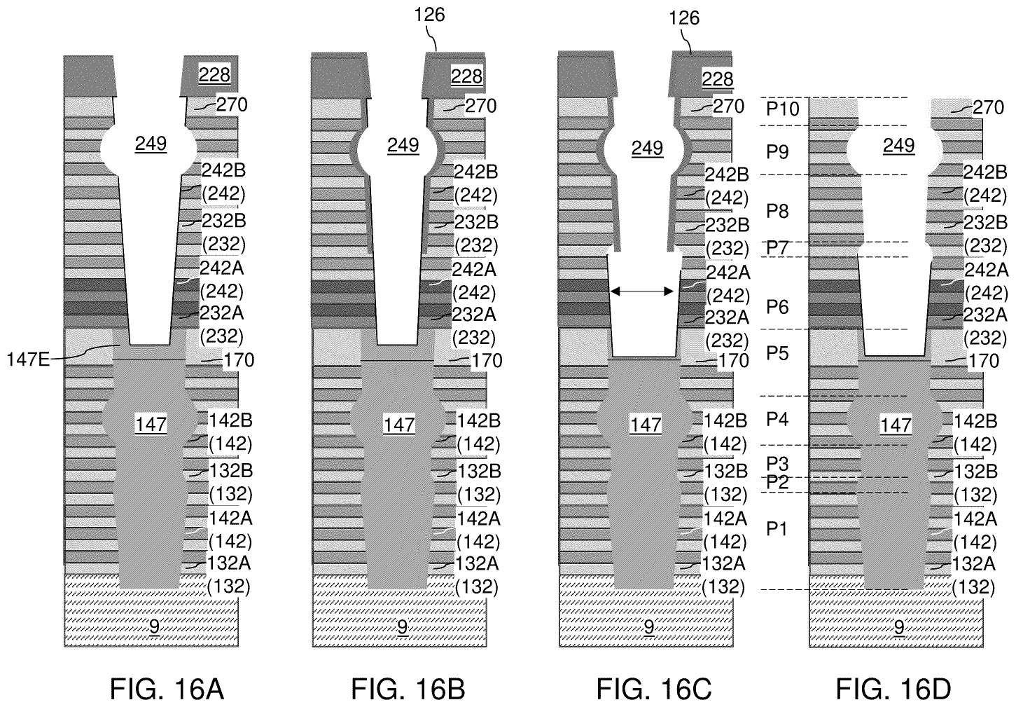

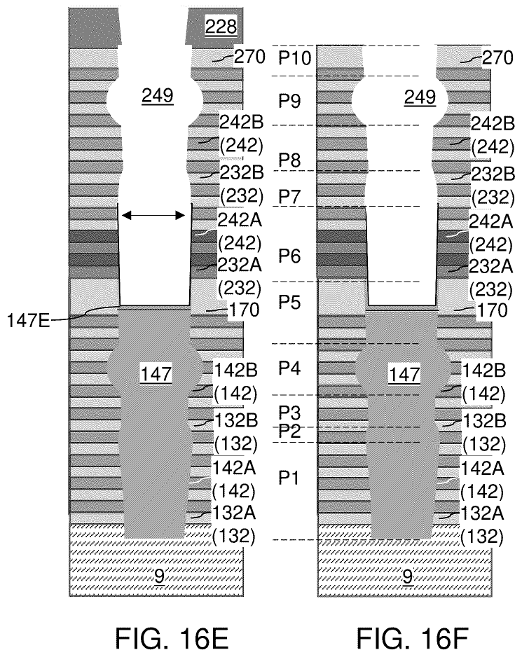

FIGS. 16A-16D are sequential vertical cross-sectional views of a second-tier opening during a fourth sequence of processing steps for extending and expanding the second-tier opening. FIGS. 16A-16D comprise the same steps as those illustrated and described above with respect to FIGS. 6A-6D, but that are performed on the second alternating stack (232, 242). In this embodiment, an optional etch stop layer 147E may be formed at the top of the first sacrificial opening fill material portion 147. The etch stop layer 147E may comprise a high density carbon layer or a metal oxide layer.

FIGS. 16E and 16F are sequential vertical cross-sectional views of a second-tier opening during a fifth sequence of processing steps for extending and expanding the second-tier opening. The fifth sequence of processing steps can be derived from the fourth sequence of processing steps described with reference to FIGS. 16A-16C by performing the processing steps described with reference to FIG. 14E. In this embodiment, an optional etch stop layer 147E may be formed at the top of the first sacrificial opening fill material portion 147. The etch stop layer 147E may comprise a high density carbon layer or a metal oxide layer.

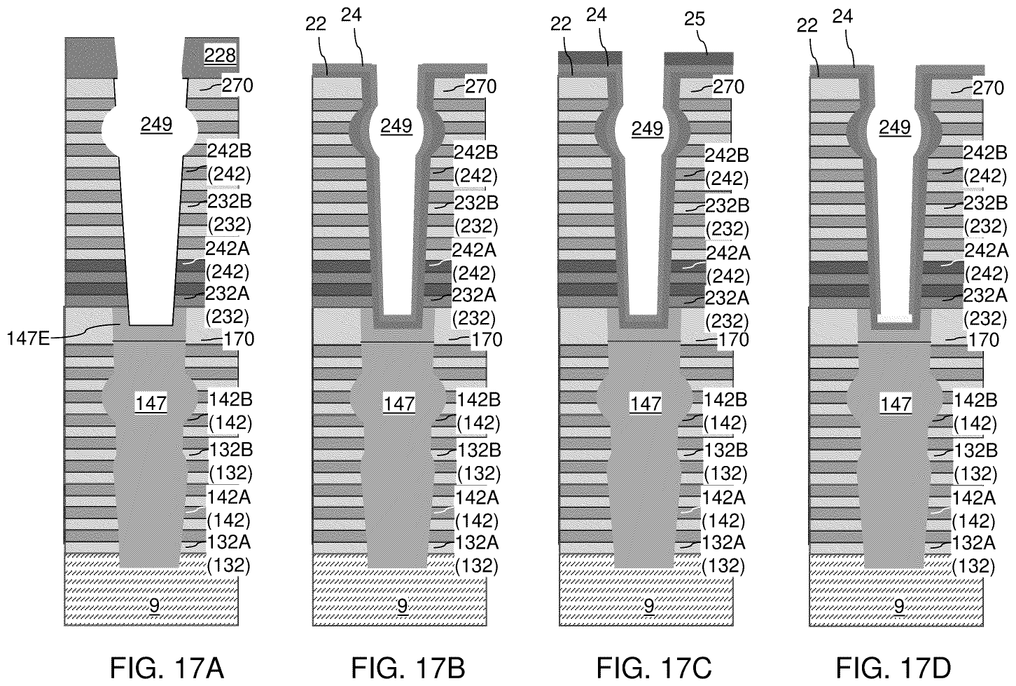

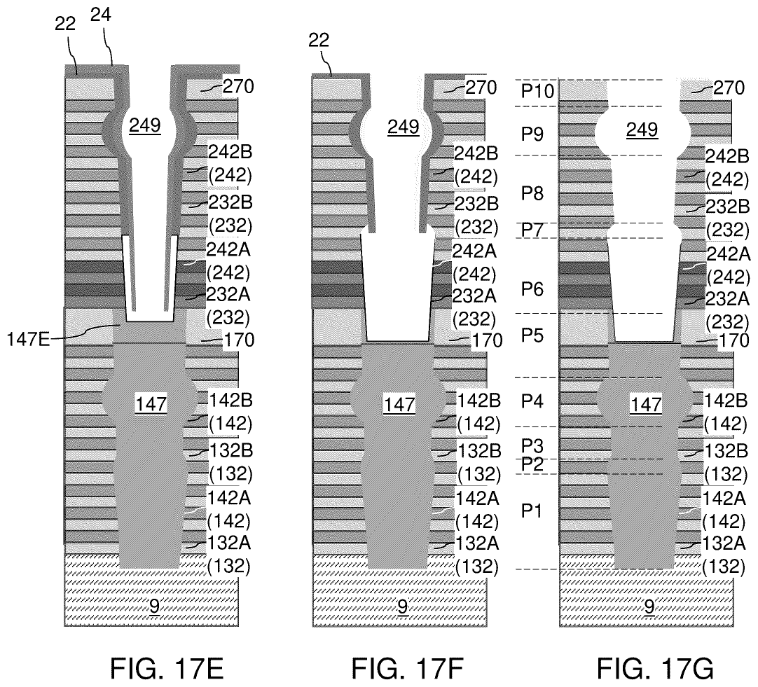

FIGS. 17A-17G are sequential vertical cross-sectional views of a second-tier opening during a sixth sequence of processing steps for extending and expanding the second-tier opening. FIGS. 17A-17G comprise the same steps as those illustrated and described above with respect to FIGS. 7A-7G, but that are performed on the second alternating stack (232, 242). In this embodiment, an optional etch stop layer 147E may be formed at the top of the first sacrificial opening fill material portion 147. The etch stop layer 147E may comprise a high density carbon layer or a metal oxide layer.

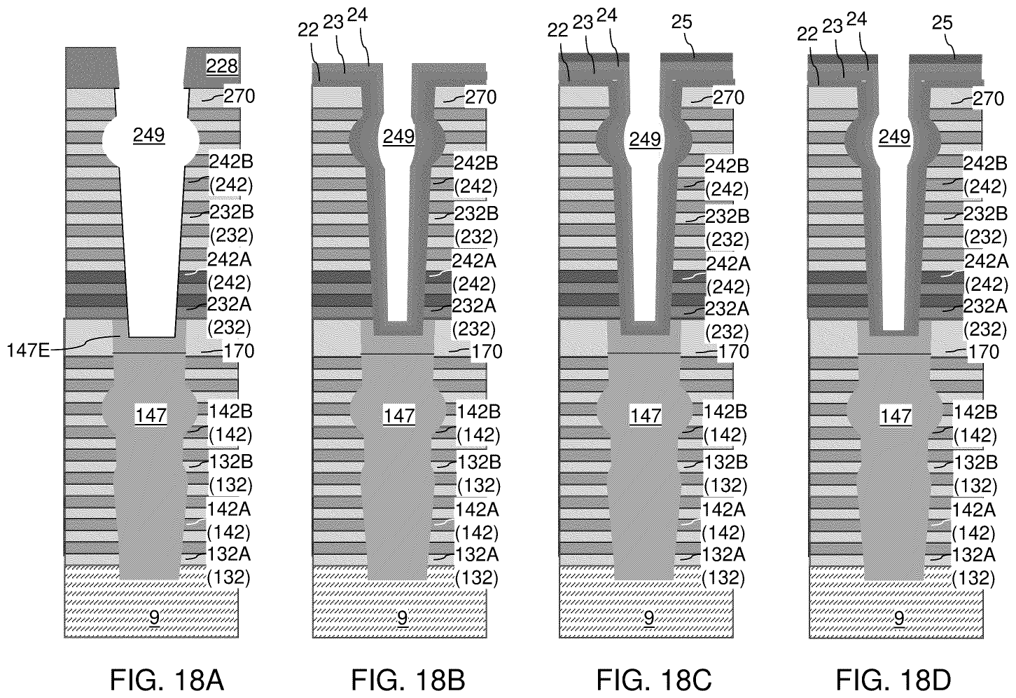

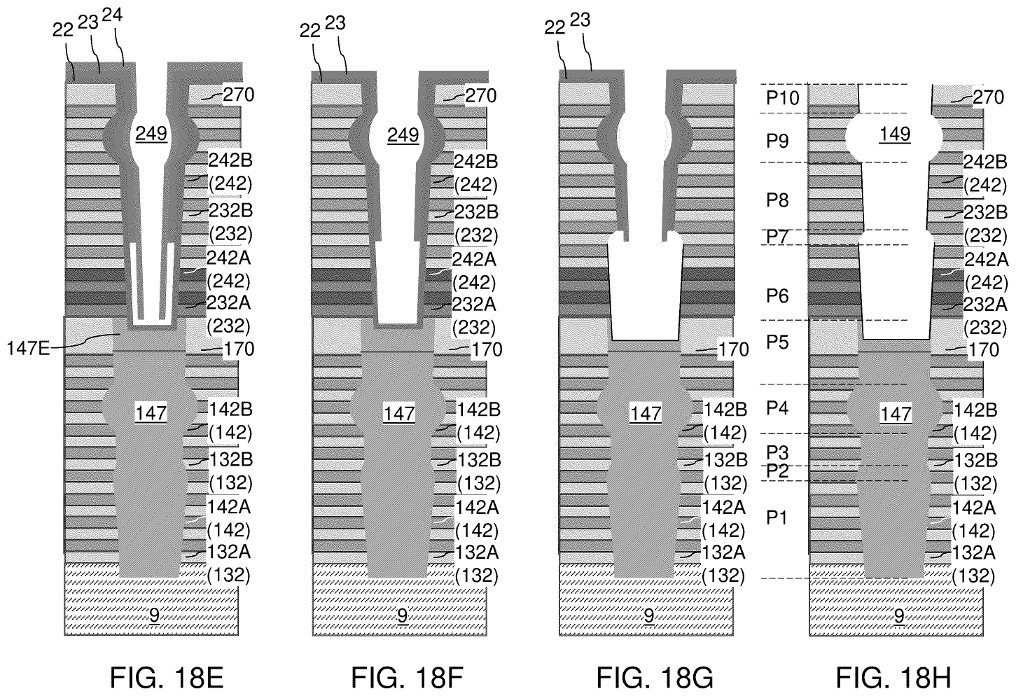

FIGS. 18A-18H are sequential vertical cross-sectional views of a second-tier opening during a seventh sequence of processing steps for extending and expanding the second-tier opening. FIGS. 18A-18H comprise the same steps as those illustrated and described above with respect to FIGS. 8A-8H, but that are performed on the second alternating stack (232, 242). In this embodiment, an optional etch stop layer 147E may be formed at the top of the first sacrificial opening fill material portion 147. The etch stop layer 147E may comprise a high density carbon layer or a metal oxide layer.

Referring collectively to FIGS. 14E, 14G, 15E, 16D, 16F, 17G, and 18H, the second-tier opening can be converted into an expanded opening, and is adjoined to a first-tier opening which is filled with a first sacrificial opening fill material portion (147, 127, 177). The first-tier opening comprises a first portion P1 having a first variable width that increases linearly with a vertical distance from the base material layer (such as a substrate 9); a second portion P2 that overlies and is adjoined to the first portion P1 and having a second variable width that decreases non-linearly with the vertical distance from the base material layer (such as a substrate 9) and optionally laterally bounded by a tapered annular surface segment having a convex vertical profile and formed by the at least one isotropic etch process; and a third portion P3 that overlies and is adjoined to the second portion P2 and having a third variable width that increases linearly with the vertical distance from the base material layer (such as a substrate 9). Further, the expanded opening may comprise a fourth portion P4 that overlies and is adjoined to the third portion P3 and has a fourth variable width of which a maximum is located between a horizontal plane including a bottom end of the fourth portion P4 and a horizonal plane including a top end of the fourth portion P4; and a fifth portion P5 that overlies and is adjoined to the fourth portion P4 and has a fifth variable width that increases with the vertical distance from the base material layer (such as a substrate 9).

The second-tier opening comprises: a sixth portion P6 having a sixth variable width that increases linearly with a vertical distance from the base material layer (such as a substrate 9); a seventh portion P7 that overlies and is adjoined to the sixth portion P6 and having a seventh variable width that decreases non-linearly with the vertical distance from the base material layer (such as a substrate 9) and optionally laterally bounded by a tapered annular surface segment having a convex vertical profile and formed by the at least one isotropic etch process; and an eighth portion P8 that overlies and is adjoined to the seventh portion P7 and having an eighth variable width that increases linearly with the vertical distance from the base material layer (such as a substrate 9). Further, the expanded opening may comprise a ninth portion P9 that overlies and is adjoined to the eighth portion P8 and has a ninth variable width of which a maximum is located between a horizontal plane including a bottom end of the ninth portion P9 and a horizonal plane including a top end of the ninth portion P9; and a tenth portion P10 that overlies and is adjoined to the ninth portion P9 and has a tenth variable width that increases with the vertical distance from the base material layer (such as a substrate 9). As discussed above, the second-tier opening may be any of a second-tier memory opening 249, a second-tier support opening 229, or a second-tier lateral isolation trench 279. The underlying first-tier opening may be of the same type as the first-tier opening. In other words, if the second-tier opening comprises a second-tier memory opening 249, the underlying first-tier opening comprises a first-tier memory opening 149; if the second-tier opening comprises a second-tier support opening 229, the underlying first-tier opening comprises a first-tier support opening 129; and if the second-tier opening comprises a second-tier lateral isolation trench 279, the underlying first-tier opening comprises a first-tier lateral isolation trench 179.

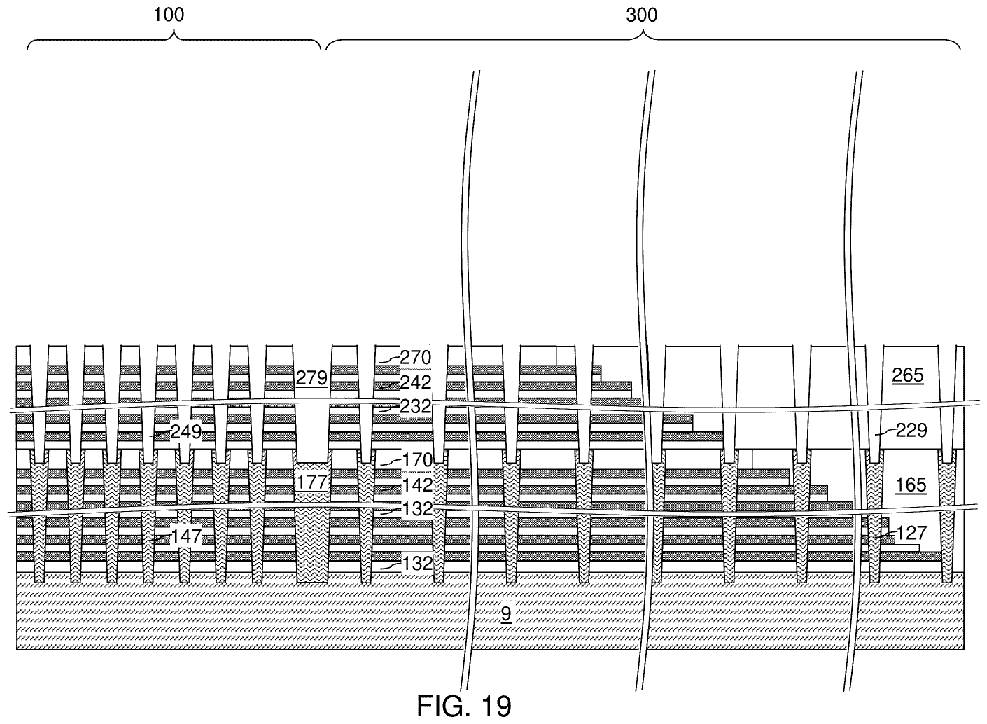

Referring to FIG. 19, the exemplary structure is illustrated after extending and expanding the second-tier memory openings 249, the second-tier support openings 229, and the second-tier lateral isolation trenches 279. The structures of the second-tier memory openings 249, the second-tier support openings 229, and the second-tier lateral isolation trenches 279 may have any configuration among the configurations of FIGS. 14E, 14G, 15E, 16D, 16F, 17G, and 18H.

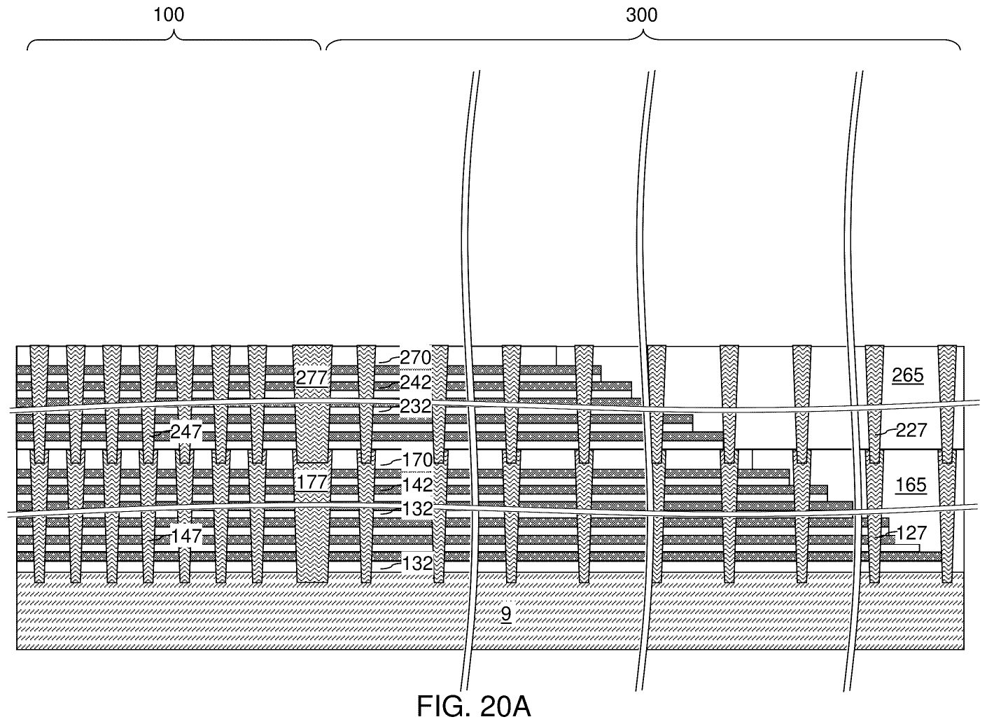

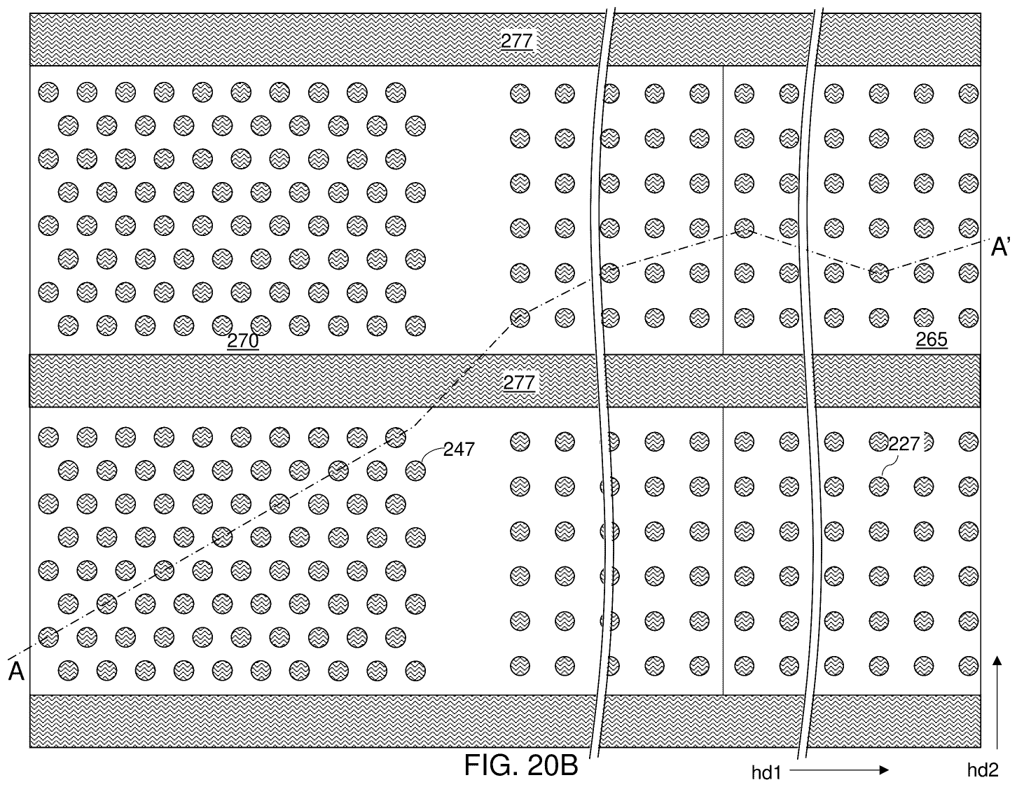

Referring to FIGS. 20A and 20B, an optional etch stop liner (not shown) and a second sacrificial fill material can be deposited in the second-tier memory openings 249, the second-tier support openings 229, and the second-tier lateral isolation trenches 279. The optional etch stop liner (if present) comprises a thin silicon oxide layer having a thickness in a range from 2 nm to 6 nm. The second sacrificial fill material may comprise a carbon-based material, such as amorphous carbon or diamond-like carbon.

The hard mask layer 228 can be removed selective to the material of the second insulating cap layer 270 either during or after the etching steps described above. A planarization process can be performed to remove portions of the second sacrificial fill material from above the horizontal plane including the top surface of the second insulating cap layer 270. Remaining portions of the second sacrificial fill material that fill the second-tier memory openings 249, the second-tier support openings 229, and the second-tier lateral isolation trenches 279 constitute respective second sacrificial opening fill material portions (247, 227, 277). The second sacrificial opening fill material portions (247, 227, 277) comprise second sacrificial memory opening fill material portions 247 that are formed in the second-tier memory openings 249, second sacrificial support opening fill material portions 227 that are formed in the second-tier support openings 229, and optional second sacrificial lateral isolation trench fill material portions 277 that are formed in the second-tier lateral isolation trenches 279.

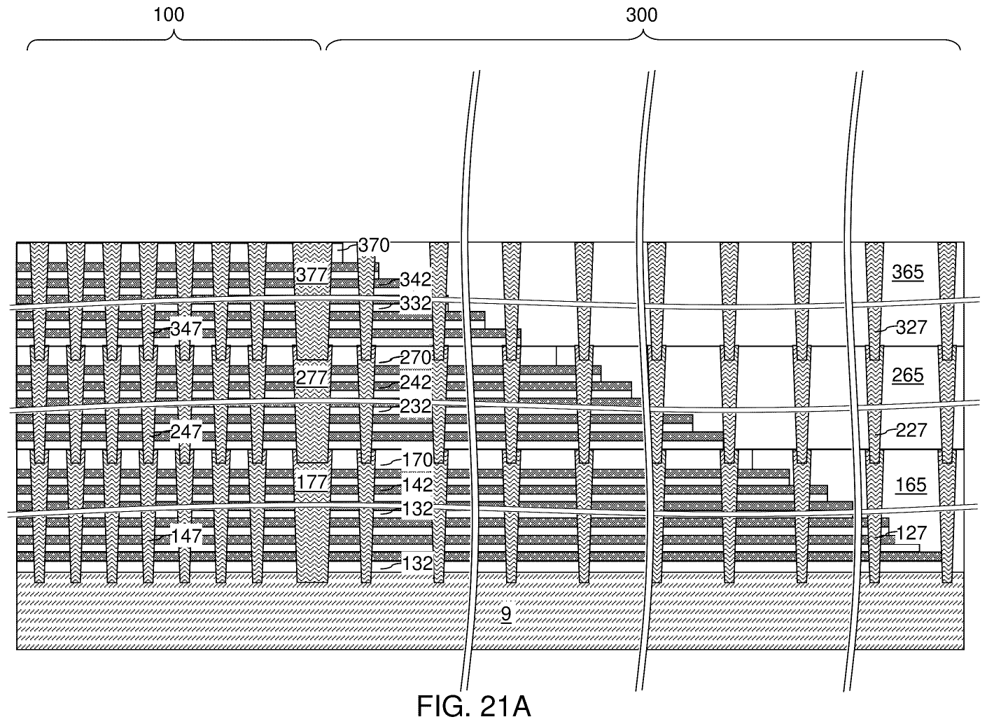

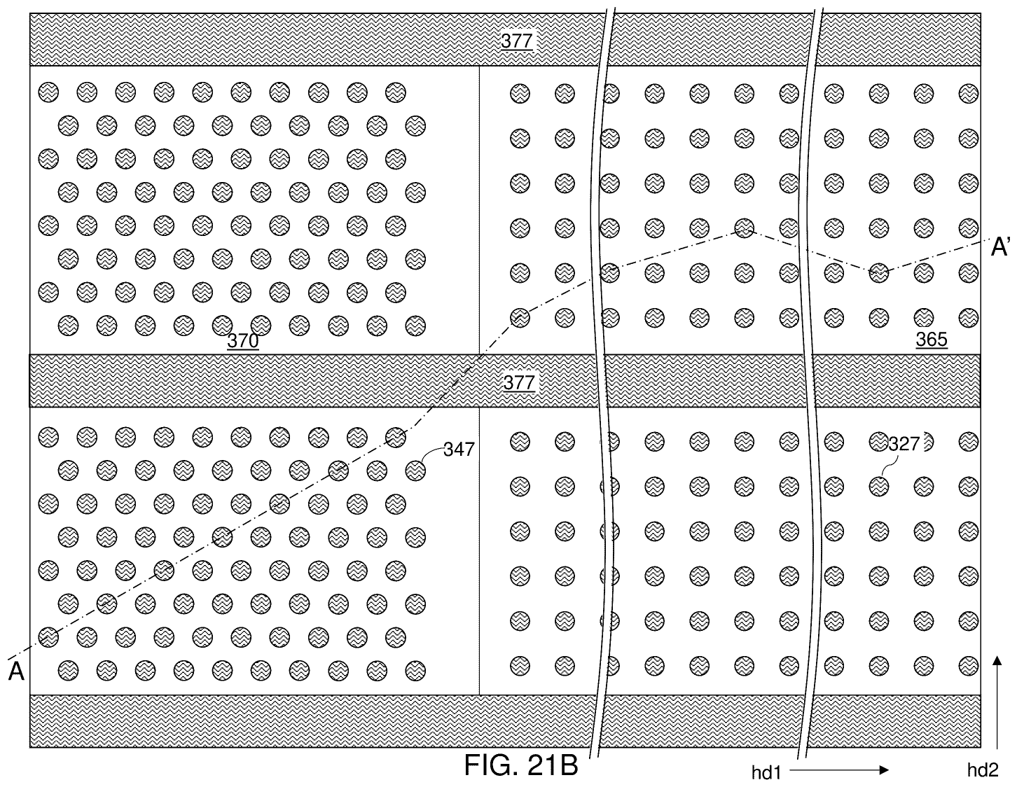

Referring to FIGS. 21A and 21B, the processing steps described with reference to FIGS. 12-20B can be performed with a suitable modification in the pattern of third stepped surfaces to form a third alternating stack (332, 342) of third insulating layers 332 and third sacrificial material layers 342, a third insulating cap layer 370, a third stepped dielectric material portion 365, various third-tier openings, and various third sacrificial opening fill material portions (347, 327, 377). Generally, the third-tier openings may have a same vertical cross-sectional profile as a respective underlying second-tier opening. Alternatively, the third sacrificial opening fill material portions (347, 327, 377) may be omitted if the memory openings and support openings are filled with the same set of materials and the isolation trenches are formed during a separate step from the memory openings and support openings.

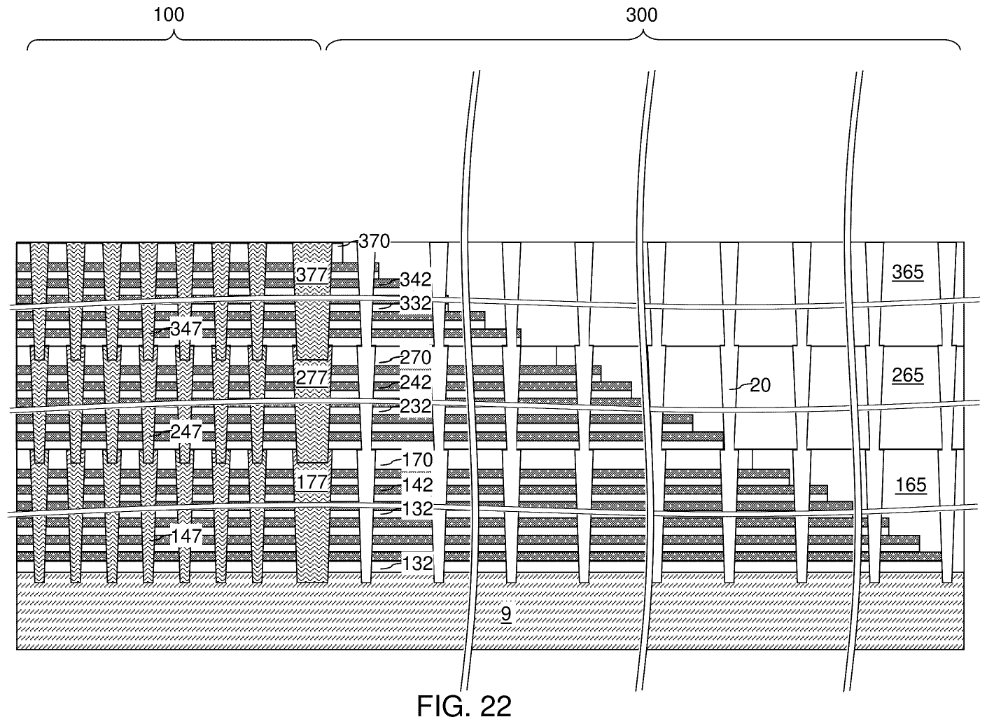

Referring to FIG. 22, a photoresist layer (not shown) can be applied over the third insulating cap layer 370 and the third stepped dielectric material portion 365, and can be lithographically patterned to cover the sacrificial memory opening fill material portions (147, 247, 347) and the sacrificial lateral isolation trench fill material portions (177, 277, 377) without covering the sacrificial support opening fill material portions (127, 227, 327). The sacrificial support opening fill material portions (127, 227, 327) in the contact region 300 can be removed selective to the materials of the alternating stacks {(132, 142), (232, 242), (332, 342)}, the insulating cap layers (170, 270, 370), and the stepped dielectric material portions (165, 265, 365). For example, an etch process or an ashing process may be employed to remove the sacrificial support opening fill material portions (127, 227, 327) in the contact region 300. The photoresist layer can be subsequently removed.

A dielectric fill material, such as silicon oxide, can be deposited in the cavities formed by removal of the sacrificial support opening fill material portions (127, 227, 327) by a conformal deposition process. Excess portions of the dielectric fill material can be removed from above the top surface of the insulating cap layer 370, for example, by a recess etch process. Each portion of the dielectric fill material that fills a respective cavity constitutes a support pillar structure 20, which can be employed to provide structural support to the insulating layers (132, 232, 332) and the stepped dielectric material portions (165, 265, 365) during subsequent replacement of the sacrificial material layers (142, 242, 342) with electrically conductive layers.

Each support pillar structure 20 vertically extends at least from a horizontal plane including the bottom surface of the first alternating stack (132, 142), and at least to a horizontal plane including the top surface of the third alternating stack (332, 342). In one embodiment, each support pillar structure 20 consists essentially of at least one dielectric fill material. In one embodiment, each support pillar structure 20 comprises a first dielectric sidewall that vertically extends through the first alternating stack (132, 142); a second dielectric sidewall that vertically extends through the second alternating stack (232, 242); and a third dielectric sidewall that vertically extends through the third alternating stack (332, 342). Alternatively, the steps described above with respect to FIG. 22 may be omitted and the support pillar structures 20 may have the same structure as the memory opening fill structures described below.

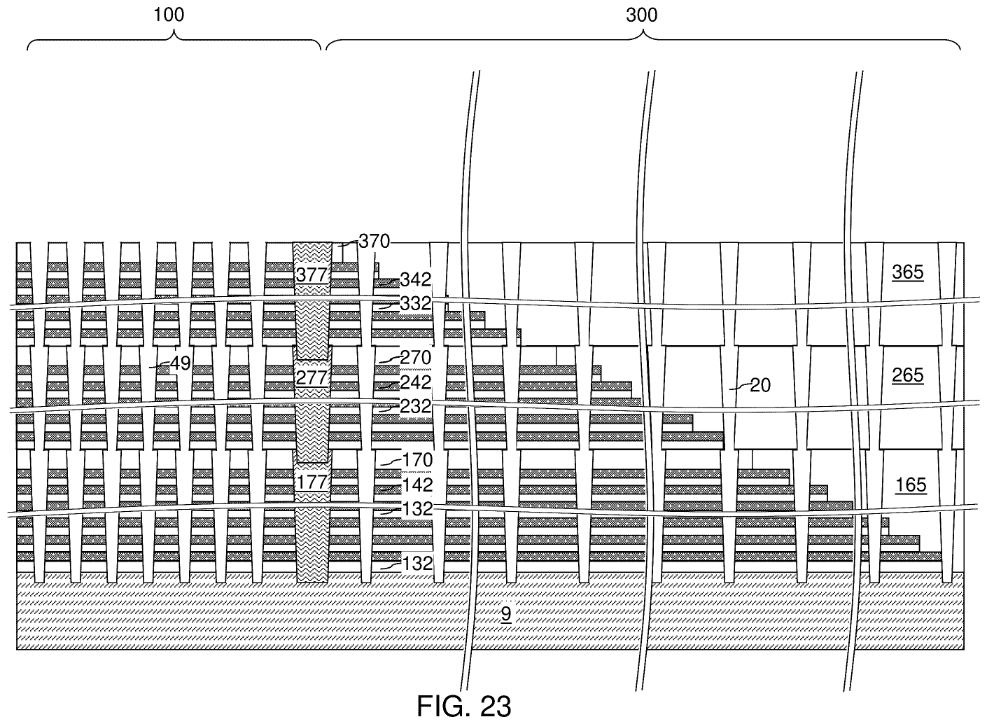

Referring to FIG. 23, a photoresist layer (not shown) can be applied over the third insulating cap layer 370 and the third stepped dielectric material portion 365, and can be lithographically patterned to cover the sacrificial lateral isolation trench fill material portions (177, 277, 377) without covering the sacrificial memory opening fill material portions (147, 247, 347). The sacrificial memory opening fill material portions (147, 247, 347) in the memory array region 100 can be removed selective to the materials of the alternating stacks {(132, 142), (232, 242), (332, 342)}, the insulating cap layers (170, 270, 370), and the stepped dielectric material portions (165, 265, 365) to form multi-tier memory openings 49, which are also referred to as memory openings 49. For example, an etch process or an ashing process may be employed to remove the sacrificial memory opening fill material portions (147, 247, 347) in the memory array region 100. The photoresist layer can be subsequently removed.

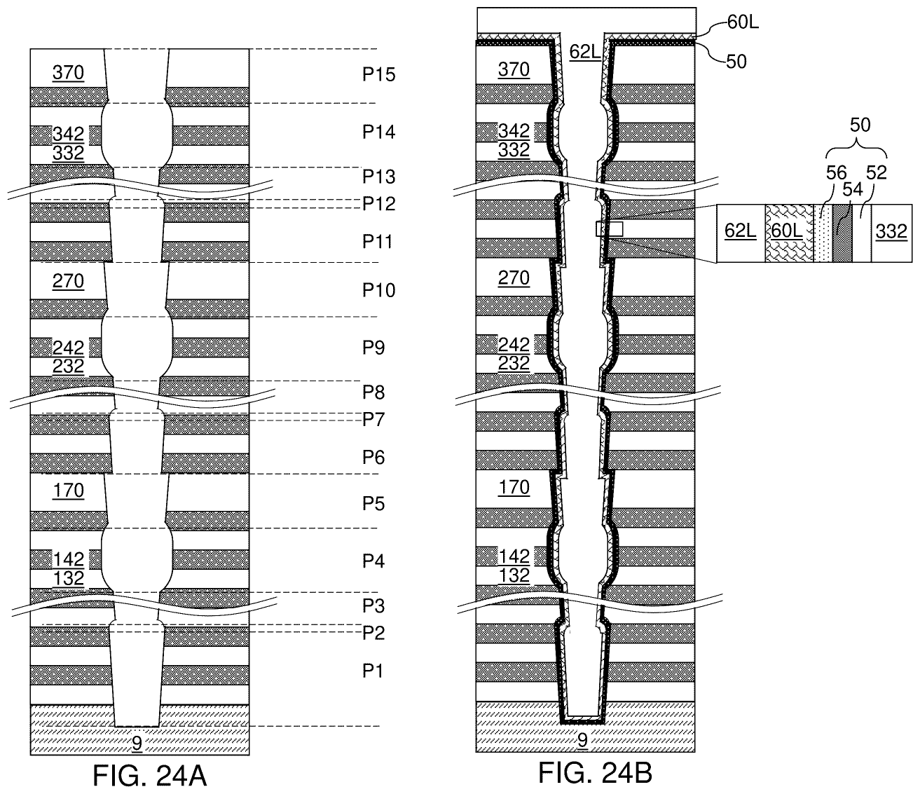

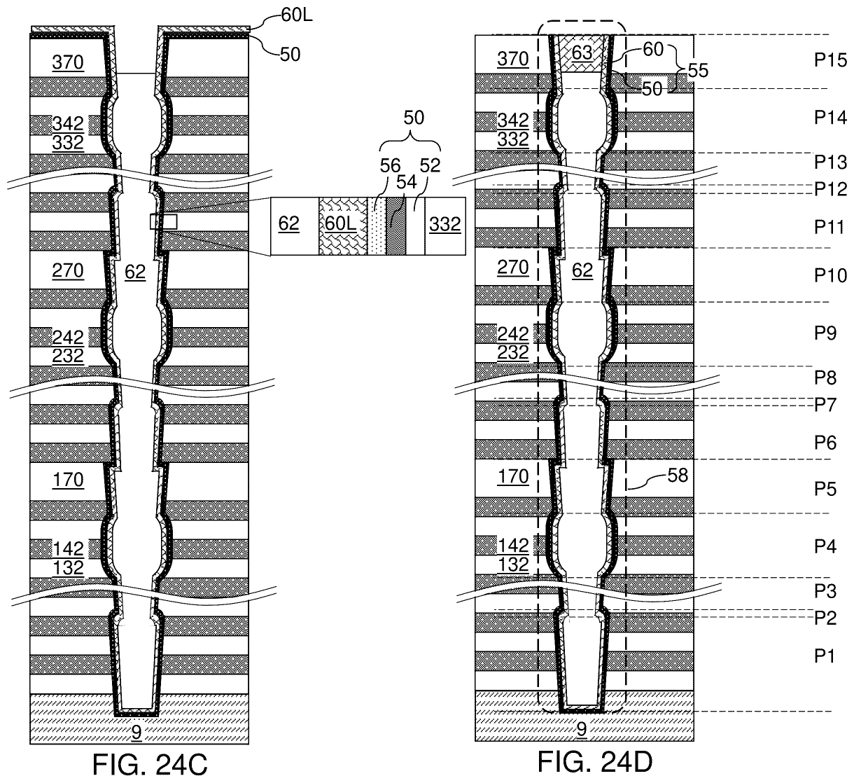

FIGS. 24A-24D are sequential vertical cross-sectional views of a multi-tier memory opening 49 (i.e., a memory opening 49) during formation of a memory opening fill structure 58 according to an embodiments of the present disclosure.

Referring to FIG. 24A, a memory opening 49 is illustrated after the processing steps of FIG. 23. The memory opening 49 has a contoured vertical cross-sectional profile. For example, the portion of the memory opening 49 that underlies the second alternating stack (232, 242) may comprise a first portion P1 having a first variable width that increases linearly with a vertical distance from the base material layer (such as a substrate 9); a second portion P2 that overlies and is adjoined to the first portion P1 and having a second variable width that decreases non-linearly with the vertical distance from the base material layer (such as a substrate 9) and laterally bounded by a tapered annular surface segment having a convex vertical profile and formed by the at least one isotropic etch process; and a third portion P3 that overlies and is adjoined to the second portion P2 and having a third variable width that increases linearly with the vertical distance from the base material layer (such as a substrate 9). Further, the expanded opening may comprise a fourth portion P4 that overlies and is adjoined to the third portion P3 and has a fourth variable width of which a maximum is located between a horizontal plane including a bottom end of the fourth portion P4 and a horizonal plane including a top end of the fourth portion P4; and a fifth portion P5 that overlies and is adjoined to the fourth portion P4 and has a fifth variable width that increases with the vertical distance from the base material layer (such as a substrate 9).

The portion of the memory opening that extends through the second alternating stack (232, 242) may comprise: a sixth portion P6 having a sixth variable width that increases linearly with a vertical distance from the base material layer (such as a substrate 9); a twelfth portion P7 that overlies and is adjoined to the sixth portion P6 and having a twelfth variable width that decreases non-linearly with the vertical distance from the base material layer (such as a substrate 9) and laterally bounded by a tapered annular surface segment having a convex vertical profile and formed by the at least one isotropic etch process; and an eighth portion P8 that overlies and is adjoined to the twelfth portion P7 and having an eighth variable width that increases linearly with the vertical distance from the base material layer (such as a substrate 9). Further, the expanded opening may comprise a ninth portion P9 that overlies and is adjoined to the eighth portion P8 and has a ninth variable width of which a maximum is located between a horizontal plane including a bottom end of the ninth portion P9 and a horizonal plane including a top end of the ninth portion P9; and a tenth portion P10 that overlies and is adjoined to the ninth portion P9 and has a tenth variable width that increases with the vertical distance from the base material layer (such as a substrate 9).

The portion of the memory opening that extends through the third alternating stack (332, 342) may comprise: an eleventh portion P11 having a eleventh variable width that increases linearly with a vertical distance from the base material layer (such as a substrate 9); a twelfth portion P12 that overlies and is adjoined to the eleventh portion P11 and having a twelfth variable width that decreases non-linearly with the vertical distance from the base material layer (such as a substrate 9) and laterally bounded by a tapered annular surface segment having a convex vertical profile and formed by the at least one isotropic etch process; and a thirteenth portion P13 that overlies and is adjoined to the twelfth portion P12 and having an thirteenth variable width that increases linearly with the vertical distance from the base material layer (such as a substrate 9). Further, the expanded opening may comprise a fourteenth portion P14 that overlies and is adjoined to the thirteenth portion P13 and has a fourteenth variable width of which a maximum is located between a horizontal plane including a bottom end of the fourteenth portion P14 and a horizonal plane including a top end of the fourteenth portion P14; and a fifteenth portion P15 that overlies and is adjoined to the fourteenth portion P14 and has a fifteenth variable width that increases with the vertical distance from the base material layer (such as a substrate 9).

Referring to FIG. 24B, a layer stack including a memory material layer 54 can be conformally deposited. In an illustrative example, the layer stack may comprise an optional blocking dielectric layer 52, the memory material layer 54, and an optional dielectric liner 56. The memory material layer 54 includes a memory material, i.e., a material that can store data bits therein. The memory material layer 54 may comprise a charge storage material (such as silicon nitride), a ferroelectric material, a phase change memory material, or any other memory material that can store data bits by inducing a change in the electrical resistivity, ferroelectric polarization, or any other measurable physical property. In case the memory material layer 54 comprise a charge storage material, the optional dielectric liner 56 may comprise a tunneling dielectric layer.

A semiconductor channel material layer 60L can be deposited over the layer stack (52, 54, 56) by performing a conformal deposition process. If the semiconductor channel material layer 60L is doped, the semiconductor channel material layer 60L may have a doping of a first conductivity type, which may be p-type or n-type. In one embodiment, the first semiconductor material comprises a first doped silicon material having a doping of the first conductivity type. In an illustrative example, the atomic concentration of dopants of the first conductivity type in the semiconductor channel material layer 60L may be in a range from 1.0×10¹³/cm³ to 3.0×10¹⁷/cm³, such as 1.0×10¹⁴/cm³ to 3.0×10¹⁶/cm³, although lesser and greater atomic concentrations may also be employed. A dielectric core layer 62L comprising a dielectric fill material (e.g., silicon oxide) can be deposited in remaining volumes of the memory openings 49 and over the alternating stack (32, 42).

Referring to FIG. 24C, the dielectric core layer 62L can be vertically recessed such that each remaining portion of the dielectric core layer 62L has a top surface at, or about, the horizontal plane including the bottom surface of the insulating cap layer 370. Each remaining portion of the dielectric core layer 62L constitutes a dielectric core 62.

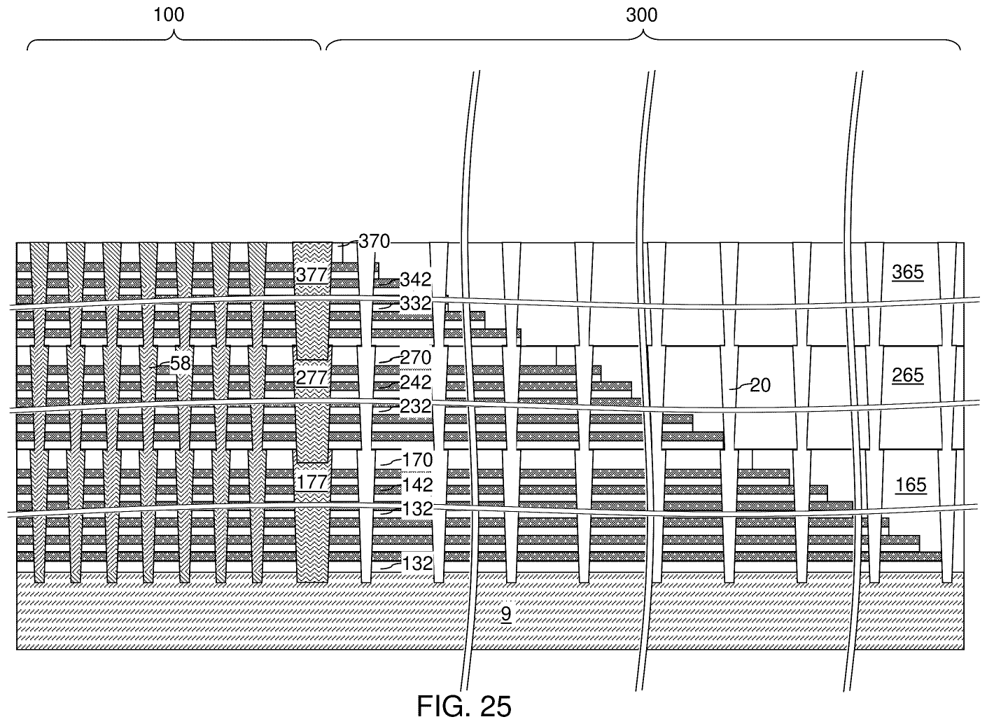

Referring to FIGS. 24D and 25, a doped semiconductor material having a doping of a second conductivity type can be deposited within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5.0×10¹⁸/cm³ to 2.0×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel layer 60L can be removed from above the horizontal plane including the top surface of the insulating cap layer 370, for example, by chemical mechanical planarization (CMP) or a recess etch process. Each remaining portion of the doped semiconductor material having a doping of the second conductivity type constitutes a drain region 63. Each remaining portion of the semiconductor channel layer 60L (which has a doping of the first conductivity type) constitutes a vertical semiconductor channel 60.

Each portion of the layer stack including the memory material layer 54 that remains in a respective memory opening 49 constitutes a memory film 50. In one embodiment, a memory film 50 may comprise an optional blocking dielectric layer 52, a memory material layer 54, and an optional dielectric liner 56. Each contiguous combination of a memory film 50 and a vertical semiconductor channel 60 constitutes a memory stack structure 55. Each combination of a memory stack structure 55, a dielectric core 62, and a drain region 63 within a memory opening 49 constitutes a memory opening fill structure 58. Each memory opening fill structure 58 comprises a respective vertical stack of memory elements, which may comprise portions of the memory material layer 54 located at levels of the sacrificial material layers 42.

In an alternative embodiment, the support pillar structures 20 may have the same composition and structure as the memory opening fill structures 58. In this embodiment, the memory openings and the support openings filled with the respective layers (52, 54, 56, 60, 62 and 63) during the same deposition steps.

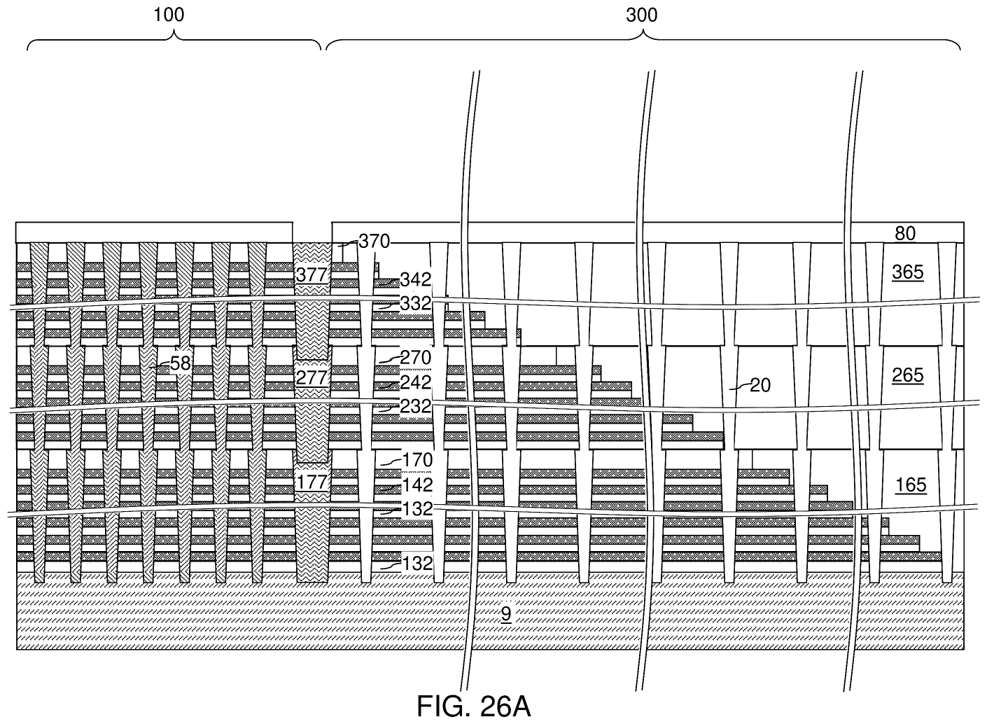

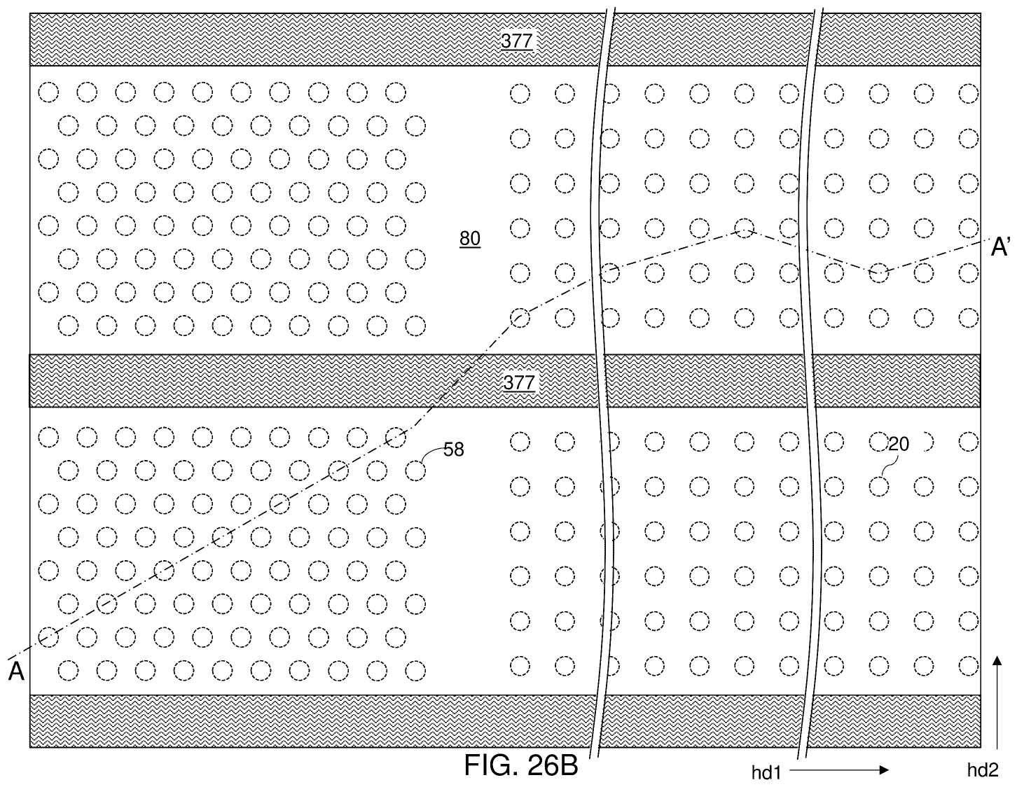

Referring to FIGS. 26A and 26B, a contact-level dielectric layer 80 can be deposited over the third insulating cap layer 370. The contact-level dielectric layer 80 comprises a dielectric material such as silicon oxide, and may have a thickness in a range from 100 nm to 800 nm, although lesser and greater thicknesses may also be employed.

A photoresist layer can be applied over the contact-level dielectric layer 80, and can be lithographically patterned to form strip-shaped openings that overlie the sacrificial lateral isolation trench fill material portions (177, 277, 377) (if present). An anisotropic etch process can be performed to form slit-shaped openings through the contact-level dielectric layer 80 over the areas of the sacrificial lateral isolation trench fill material portions (177, 277, 377).

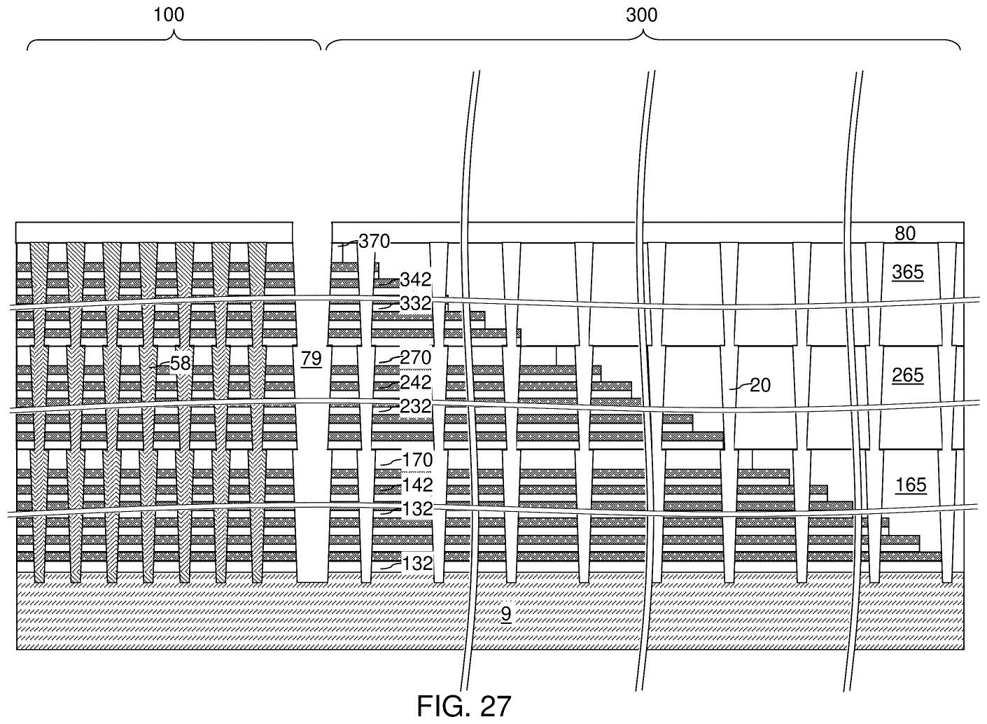

Referring to FIG. 27, the sacrificial lateral isolation trench fill material portions (177, 277, 377) can be removed selective to the materials of the alternating stacks {(132, 142), (232, 242), (332, 342)}, the insulating cap layers (170, 270, 370), and the stepped dielectric material portions (165, 265, 365) to form lateral isolation trenches 79. For example, an etch process or an ashing process may be employed to remove the sacrificial lateral isolation trench fill material portions (177, 277, 377). Alternatively, the lateral isolation trenches 79 may be formed during a separate masking and etching step from the support openings and the memory openings. In this case, the sacrificial lateral isolation trench fill material portions (177, 277, 377) are omitted.

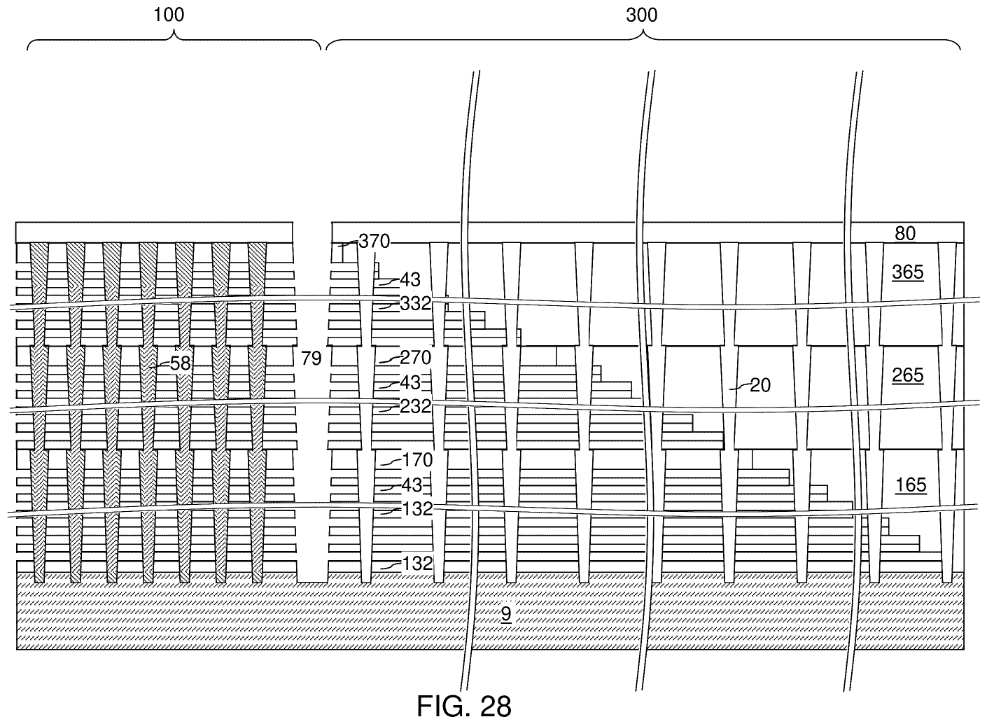

Referring to FIG. 28, an isotropic etch process can be performed to remove the sacrificial material layers (142, 242, 342) selective to the insulating layers (132, 232, 332), the insulating cap layers (170, 270, 370), the contact-level dielectric layer 80, the memory opening fill structures 58, the support pillar structures 20, and the substrate 9. In an illustrative example, the insulating layers (132, 232, 332) may comprise silicon oxide, the sacrificial material layers (142, 242, 342) may comprise silicon nitride. In this case, the isotropic etch process that removes the sacrificial material layers (142, 242, 342) may comprise a wet etch process employing hot phosphoric acid. Laterally-extending cavities 43 can be formed in volumes from which the sacrificial material layers (142, 242, 342) are removed. Sidewall surface segments of the memory opening fill structures 58 can be physically exposed to the laterally-extending cavities 43.

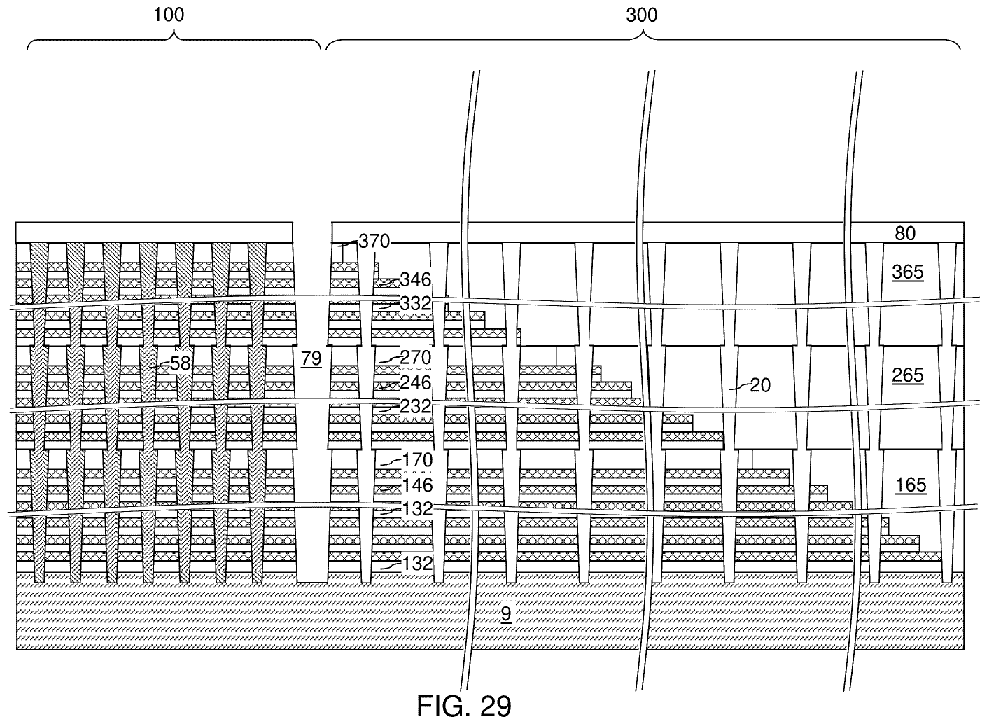

Referring to FIG. 29, an outer blocking dielectric layer (not shown), such as an aluminum oxide layer, can be optionally formed in the laterally-extending cavities 43 by a conformal deposition process. At least one conductive material, such as at least one metallic material, can be conformally deposited in the laterally-extending cavities 43. The at least one conductive material may comprise, for example, a combination of a metallic barrier material and a metallic fill material. The metallic barrier material may comprise, for example, TiN, TaN, WN, MoN, TiC, TaC, WC, or a combination thereof. The metallic fill material may comprise, for example, Ti, Ta, Mo, Co, Ru, W, Cu, other transition metals, and/or alloys or layer stacks thereof. Excess portions of the at least one conductive material that are deposited in the lateral isolation trenches 79 or above the contact-level dielectric layer 80 can be removed by performing an etch-back process, which may comprise an isotropic etch process and/or an anisotropic etch process. Each remaining portion of the at least one conductive material filling a respective one of the laterally-extending cavities 43 constitutes an electrically conductive layer (146, 246, 346). The electrically conductive layers (146, 246, 346) comprise first electrically conductive layers 146 that are interlaced with the first insulating layers 132, second electrically conductive layers 246 that are interlaced with the second insulating layers 232, and third electrically conductive layers 346 that are interlaced with the third insulating layers 332. An alternating stack of insulating layers (132, 232, 332) and electrically conductive layers (146, 246, 346) can be formed between each neighboring pair of lateral isolation trenches 79 over the carrier substate 9. A plurality of alternating stacks of insulating layers (132, 232, 332) and electrically conductive layers (146, 246, 346) can be laterally spaced apart among one another by the lateral isolation trenches 79.

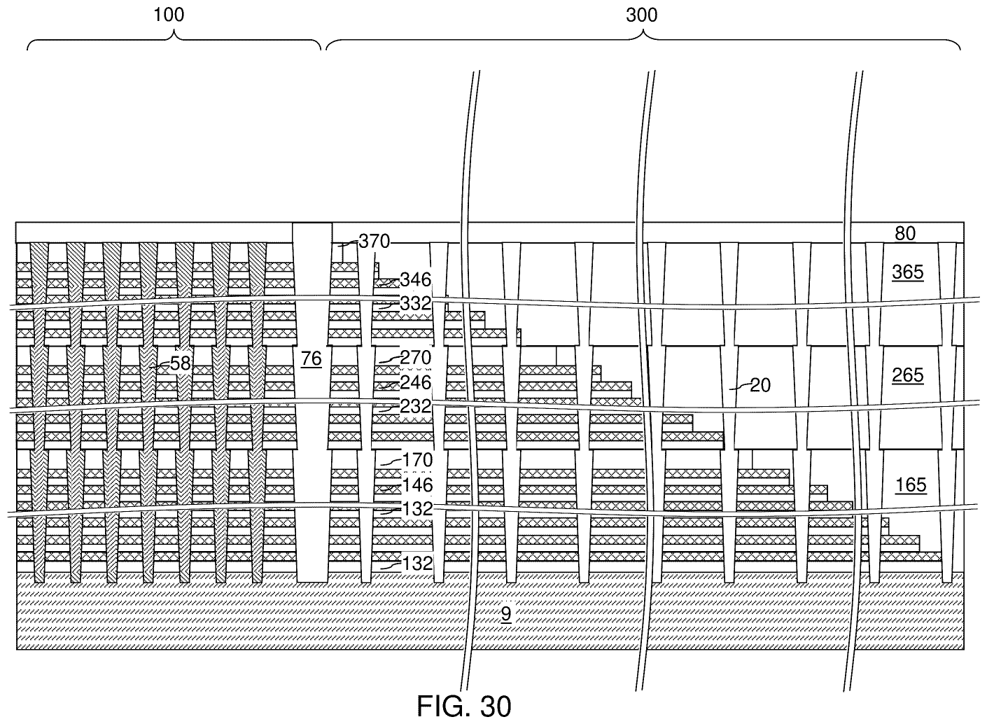

Referring to FIG. 30, an insulating fill material may be conformally deposited in the lateral isolation trenches 79. Excess portions of the insulating fill material may be removed from above the contact-level dielectric layer 80, for example, by a recess etch process. Each remaining portion of the insulating fill material that fills a respective lateral isolation trench 79 constitutes an lateral isolation trench fill structure 76. Alternatively, each lateral isolation trench fill structure 76 may comprise a combination of a tubular insulating spacer (not expressly shown) and a conductive connection via structure (not expressly shown) that is laterally surrounded by the tubular insulating spacer.

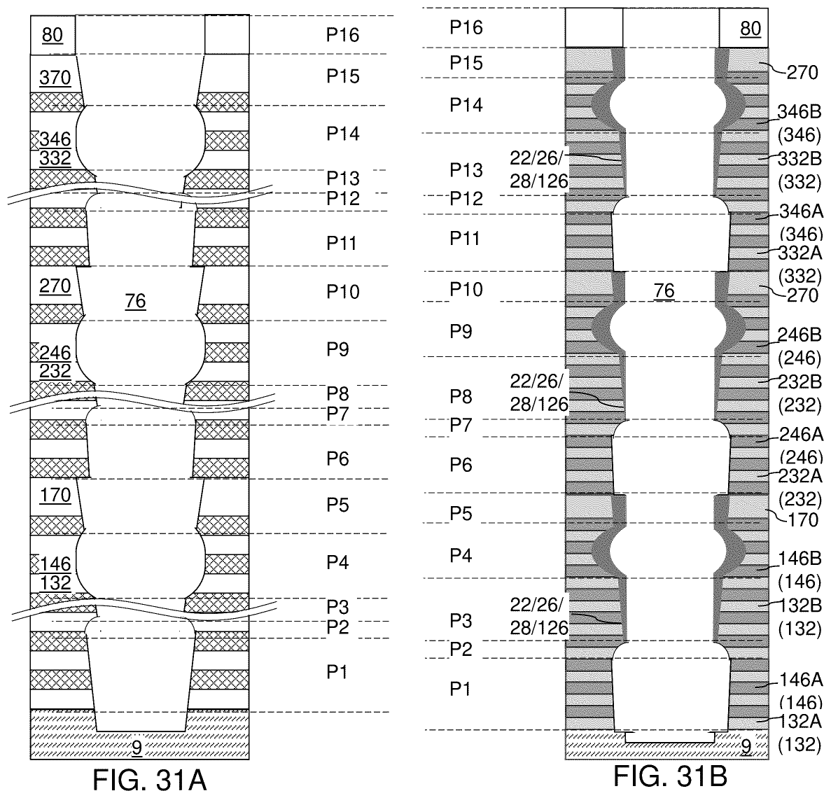

FIGS. 31A and 31B are vertical cross-sectional views of embodiments of a lateral isolation trench fill structure 76 of an alternative embodiment. Each lateral isolation trench may have a contoured vertical cross-sectional profile. For example, the portion of a lateral isolation trench that underlies the second alternating stack (232, 242) may comprise a first portion P1 having a first variable width that increases linearly with a vertical distance from the base material layer (such as a substrate 9); a second portion P2 that overlies and is adjoined to the first portion P1 and having a second variable width that decreases non-linearly with the vertical distance from the base material layer (such as a substrate 9) and laterally bounded by a tapered annular surface segment having a convex vertical profile and formed by the at least one isotropic etch process; and a third portion P3 that overlies and is adjoined to the second portion P2 and having a third variable width that increases linearly with the vertical distance from the base material layer (such as a substrate 9). Further, the expanded opening may comprise a fourth portion P4 that overlies and is adjoined to the third portion P3 and has a fourth variable width of which a maximum is located between a horizontal plane including a bottom end of the fourth portion P4 and a horizonal plane including a top end of the fourth portion P4; and a fifth portion P5 that overlies and is adjoined to the fourth portion P4 and has a fifth variable width that increases with the vertical distance from the base material layer (such as a substrate 9).

The portion of the lateral isolation trench that extends through the second alternating stack (232, 242) may comprise: a sixth portion P6 having a sixth variable width that increases linearly with a vertical distance from the base material layer (such as a substrate 9); a twelfth portion P7 that overlies and is adjoined to the sixth portion P6 and having a twelfth variable width that decreases non-linearly with the vertical distance from the base material layer (such as a substrate 9) and laterally bounded by a tapered annular surface segment having a convex vertical profile and formed by the at least one isotropic etch process; and an eighth portion P8 that overlies and is adjoined to the twelfth portion P7 and having an eighth variable width that increases linearly with the vertical distance from the base material layer (such as a substrate 9). Further, the expanded opening may comprise a ninth portion P9 that overlies and is adjoined to the eighth portion P8 and has a ninth variable width of which a maximum is located between a horizontal plane including a bottom end of the ninth portion P9 and a horizonal plane including a top end of the ninth portion P9; and a tenth portion P10 that overlies and is adjoined to the ninth portion P9 and has a tenth variable width that increases with the vertical distance from the base material layer (such as a substrate 9).

The portion of the lateral isolation trench that extends through the third alternating stack (332, 342) may comprise: an eleventh portion P11 having a eleventh variable width that increases linearly with a vertical distance from the base material layer (such as a substrate 9); a twelfth portion P12 that overlies and is adjoined to the eleventh portion P11 and having a twelfth variable width that decreases non-linearly with the vertical distance from the base material layer (such as a substrate 9) and laterally bounded by a tapered annular surface segment having a convex vertical profile and formed by the at least one isotropic etch process; and a thirteenth portion P13 that overlies and is adjoined to the twelfth portion P12 and having an thirteenth variable width that increases linearly with the vertical distance from the base material layer (such as a substrate 9). Further, the expanded opening may comprise a fourteenth portion P14 that overlies and is adjoined to the thirteenth portion P13 and has a fourteenth variable width of which a maximum is located between a horizontal plane including a bottom end of the fourteenth portion P14 and a horizonal plane including a top end of the fourteenth portion P14; and a fifteenth portion P15 that overlies and is adjoined to the fourteenth portion P14 and has a fifteenth variable width that increases with the vertical distance from the base material layer (such as a substrate 9).

The entirety of the lateral isolation trench may be filled with a lateral isolation trench fill structure 76 as illustrated in FIG. 31A. Alternatively, portions of etch mask layers (22, 26, 28, 126) may remain in peripheral regions of the lateral isolation trench, and the lateral isolation trench may be filled with a combination of a lateral isolation trench fill structure 76 and at least one etch mask layer (22, 26, 28, 126) as illustrated in FIG. 31B.

The third insulating layers 332 may comprise lower insulating layers 332A and upper insulating layers 332B. The electrically conductive layers (146, 246, 346) comprise respective lower electrically conductive layers (146A, 246A, 346A) and respective upper electrically conductive layers (146B, 246B, 346B). The respective first, second and third tier openings are laterally expanded at the levels of the lower insulating layers (132A, 232A, 332A) and the lower electrically conductive layers (146A, 246A, 346A). The first-tier lower electrically conductive layers 146 may comprise dummy source side select gate electrodes and/or active source side select gate electrodes.

An opening fill structure that fills a lateral isolation trench 79 may comprise a trench fill structure which includes a lateral isolation trench fill structure 76 and optionally at least one etch mask layer (22, 26, 28, 126) having a configuration of a laterally-elongated tube. The trench fill structure may have a pair of contoured sidewalls, each of which comprises a lengthwise sidewall that laterally extends straight along a first horizontal direction hd1 and having a contoured profile within a vertical plane that is perpendicular to the first horizontal direction hd1. The trench fill structure comprises a dielectric fill material that vertically extends continuously from a bottommost surface of the opening fill structure that contacts the base material layer to a planar top surface of the opening fill structure.

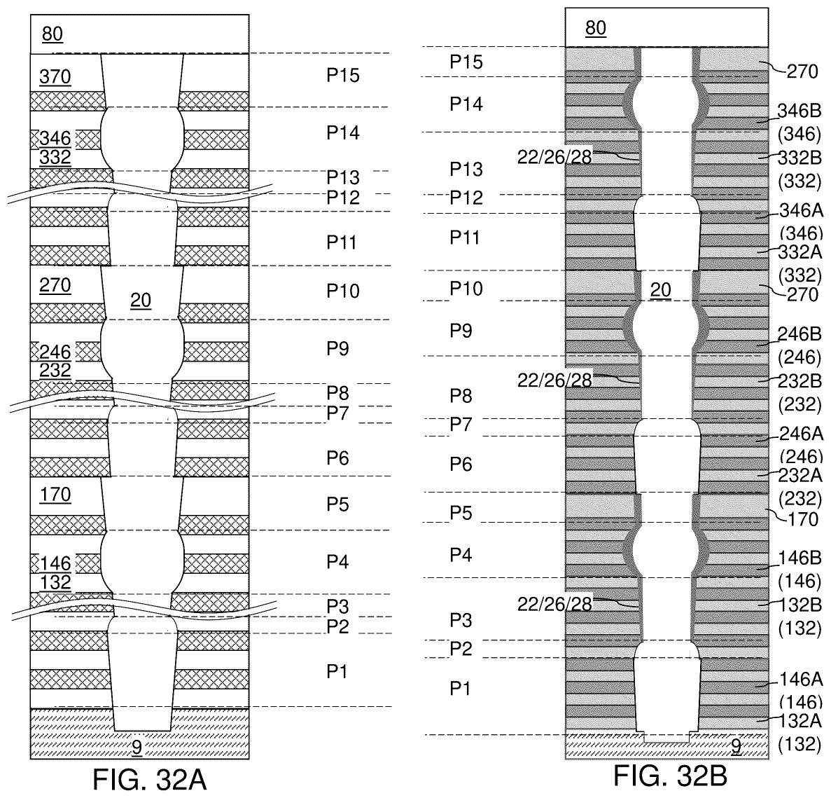

FIGS. 32A and 32B are vertical cross-sectional views of embodiments of a support pillar structure 20. Each support pillar structure 20 may have a contoured vertical cross-sectional profile. For example, the portion of a support pillar structure 20 that underlies the second alternating stack (232, 242) may comprise a first portion P1 having a first variable width that increases linearly with a vertical distance from the base material layer (such as a substrate 9); a second portion P2 that overlies and is adjoined to the first portion P1 and having a second variable width that decreases non-linearly with the vertical distance from the base material layer (such as a substrate 9) and laterally bounded by a tapered annular surface segment having a convex vertical profile and formed by the at least one isotropic etch process; and a third portion P3 that overlies and is adjoined to the second portion P2 and having a third variable width that increases linearly with the vertical distance from the base material layer (such as a substrate 9). Further, the expanded opening may comprise a fourth portion P4 that overlies and is adjoined to the third portion P3 and has a fourth variable width of which a maximum is located between a horizontal plane including a bottom end of the fourth portion P4 and a horizonal plane including a top end of the fourth portion P4; and a fifth portion P5 that overlies and is adjoined to the fourth portion P4 and has a fifth variable width that increases with the vertical distance from the base material layer (such as a substrate 9).

The portion of the support pillar structure 20 that extends through the second alternating stack (232, 242) may comprise: a sixth portion P6 having a sixth variable width that increases linearly with a vertical distance from the base material layer (such as a substrate 9); a twelfth portion P7 that overlies and is adjoined to the sixth portion P6 and having a twelfth variable width that decreases non-linearly with the vertical distance from the base material layer (such as a substrate 9) and laterally bounded by a tapered annular surface segment having a convex vertical profile and formed by the at least one isotropic etch process; and an eighth portion P8 that overlies and is adjoined to the twelfth portion P7 and having an eighth variable width that increases linearly with the vertical distance from the base material layer (such as a substrate 9). Further, the expanded opening may comprise a ninth portion P9 that overlies and is adjoined to the eighth portion P8 and has a ninth variable width of which a maximum is located between a horizontal plane including a bottom end of the ninth portion P9 and a horizonal plane including a top end of the ninth portion P9; and a tenth portion P10 that overlies and is adjoined to the ninth portion P9 and has a tenth variable width that increases with the vertical distance from the base material layer (such as a substrate 9).

The portion of the support pillar structure 20 that extends through the third alternating stack (332, 342) may comprise: an eleventh portion P11 having a eleventh variable width that increases linearly with a vertical distance from the base material layer (such as a substrate 9); a twelfth portion P12 that overlies and is adjoined to the eleventh portion P11 and having a twelfth variable width that decreases non-linearly with the vertical distance from the base material layer (such as a substrate 9) and laterally bounded by a tapered annular surface segment having a convex vertical profile and formed by the at least one isotropic etch process; and a thirteenth portion P13 that overlies and is adjoined to the twelfth portion P12 and having an thirteenth variable width that increases linearly with the vertical distance from the base material layer (such as a substrate 9). Further, the expanded opening may comprise a fourteenth portion P14 that overlies and is adjoined to the thirteenth portion P13 and has a fourteenth variable width of which a maximum is located between a horizontal plane including a bottom end of the fourteenth portion P14 and a horizonal plane including a top end of the fourteenth portion P14; and a fifteenth portion P15 that overlies and is adjoined to the fourteenth portion P14 and has a fifteenth variable width that increases with the vertical distance from the base material layer (such as a substrate 9).

A support pillar structure 20 may not be surrounded by any etch mask layer (22, 26, 28, 126), and may contact each layer within the alternating stacks {(132, 146), (232, 246), (332, 346) as illustrated in FIG. 32A. Alternatively, a support pillar structure 20 may be laterally surrounded by remaining portions of etch mask layers (22, 26, 28, 126) may remain within volumes of a first-tier support opening 129, a second-tier support opening 229, and/or a third-tier support opening 329. In this case, a support pillar structure 20 may contact only a subset of layers within the alternating stacks {(132, 146), (232, 246), (332, 346) as illustrated in FIG. 32B.

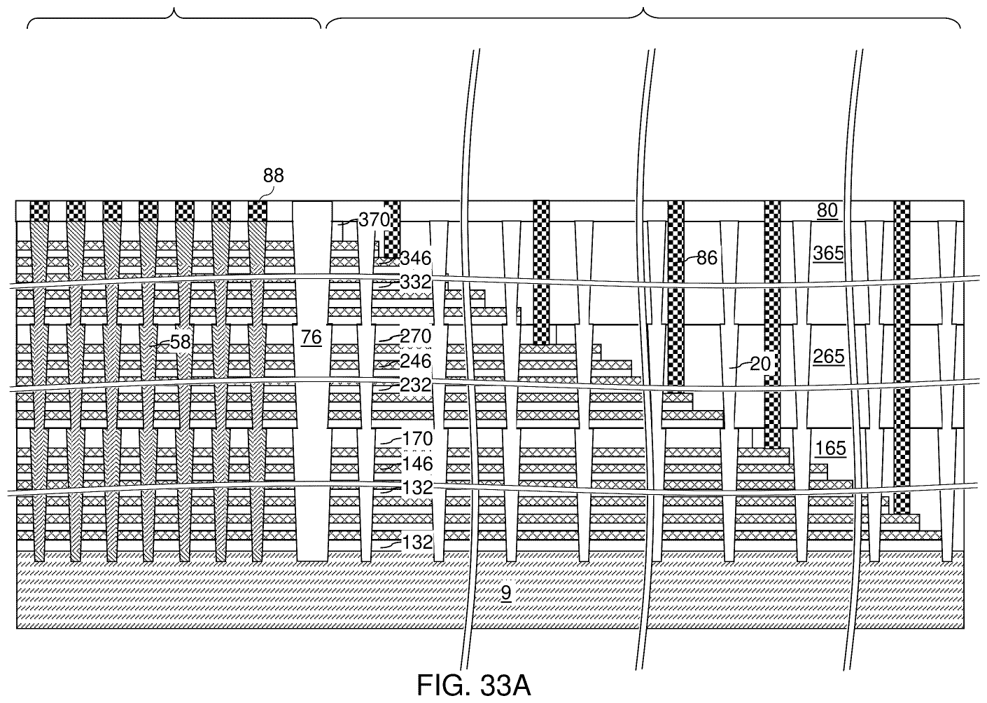

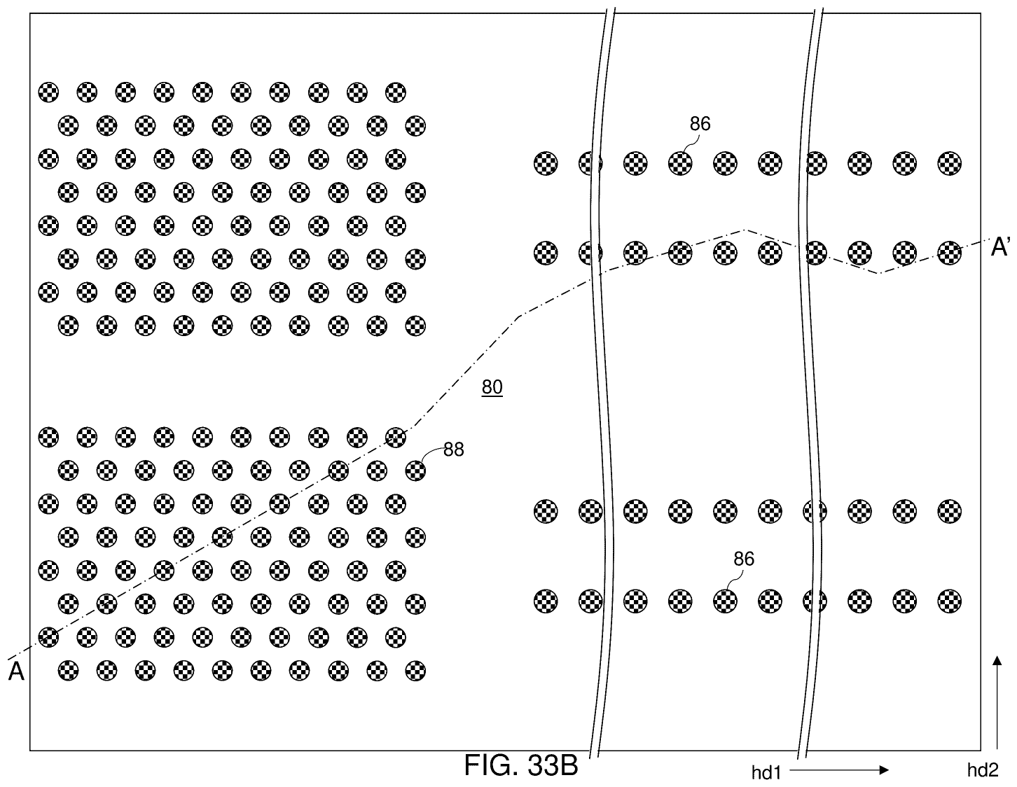

Referring to FIGS. 33A and 33B, via cavities can be formed through the contact-level dielectric layer 80 and through the stepped dielectric material portions (365, 265, 165). Drain contact via cavities can be formed over the drain regions 63 of the memory opening fill structures 58. Layer contact via structures can be formed over the electrically conductive layers (146, 246, 346) that underlie the stepped surfaces.

At least one conductive material, such as a combination of an electrically conductive barrier material and an electrically conductive fill material, can be deposited in the drain contact via cavities and the layer contact via cavities. Excess portions of the at least one conductive material can be removed from above the horizontal plane including the top surface of the contact-level dielectric layer 80 by a planarization process, which may employ a recess etch process and/or a chemical mechanical polishing process. Remaining portions of the at least one conductive material that fill the drain contact via cavities constitute drain contact via structures 88, which contact top surfaces of the drain regions 63. Remaining portions of the at least one conductive material that fill the layer contact via cavities constitute layer contact via structures 86, which contact top surfaces of the electrically conductive layers (146, 246, 346). The electrically conductive layers (146, 246, 346) comprise first electrically conductive layers 146 that replace the first sacrificial material layers 142, second electrically conductive layers 246 that replace the second sacrificial material layers 242, and third electrically conductive layers 346 that replace the third sacrificial material layers 342.

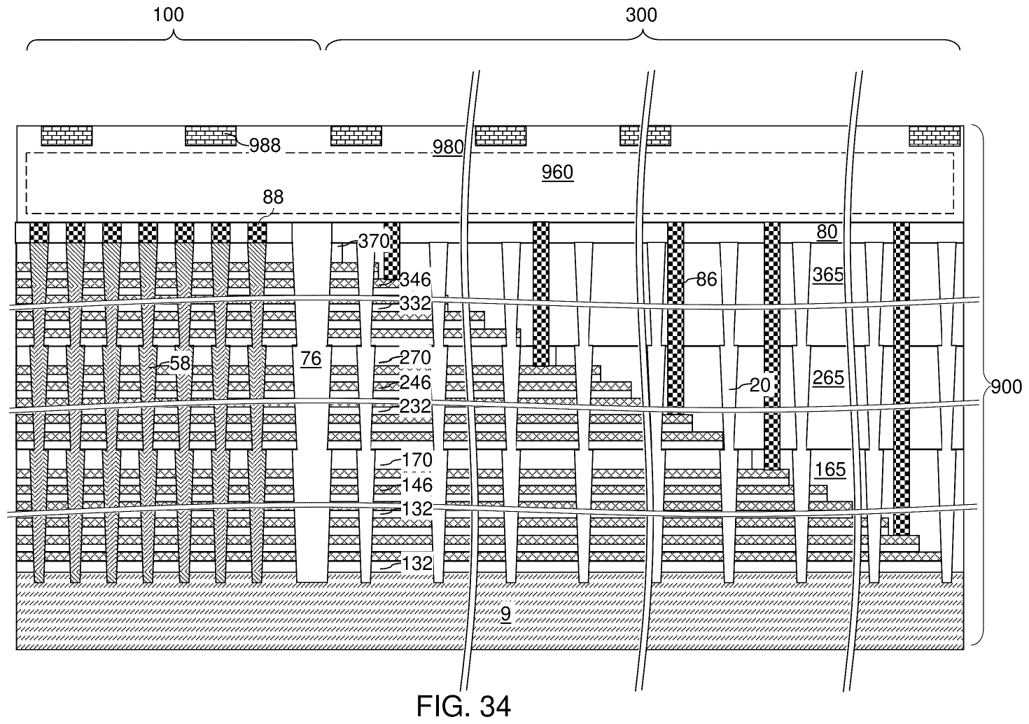

Referring to FIG. 34, additional dielectric material layers and additional metal interconnect structures can be formed over the contact-level dielectric layer 80. The additional dielectric material layers may include at least one via-level dielectric layer, at least one additional line-level dielectric layer, and/or at least one additional line-and-via-level dielectric layer. The additional metal interconnect structures may comprise metal via structures, metal line structures, and/or integrated metal line-and-via structures. The additional dielectric material layers that are formed above the contact-level dielectric layer 80 are herein referred to as memory-side dielectric material layers 960. The additional metal interconnect structures are collectively referred to as memory-side dielectric material layers 960. The memory-side dielectric material layers 960 comprise a bit-line-level dielectric material layer embedding bit lines, which are a subset of the memory-side metal interconnect structures 980.

Metal bonding pads, which are herein referred to as memory-side bonding pads 988, may be formed at the topmost level of the memory-side dielectric material layers 960. The memory-side bonding pads 988 may be electrically connected to the memory-side metal interconnect structures 980 and various nodes of the three-dimensional memory array including the alternating stacks of insulating layers (132, 232, 332) and electrically conductive layers (146, 246, 346) and the memory opening fill structures 58. A memory die 900 is formed by the above steps.

In one embodiment, the memory die 900 may comprise: a three-dimensional memory array comprising an alternating stack of insulating layers (132, 232, 332) and electrically conductive layers (146, 246, 346), a two-dimensional array of memory openings 49 vertically extending through the alternating stack, and a two-dimensional array of memory opening fill structures 58 located in the two-dimensional array of memory openings 49 and comprising a respective vertical stack of memory elements and a respective vertical semiconductor channel 60, a two-dimensional array of drain contact via structures 88 electrically connected to a respective one of the vertical semiconductor channels 60 via respective drain regions 63; and a two-dimensional array of layer contact via structures 86 electrically connected to a respective one of the electrically conductive layers (146, 246, 346), a subset of which functions as word lines for the three-dimensional memory array.

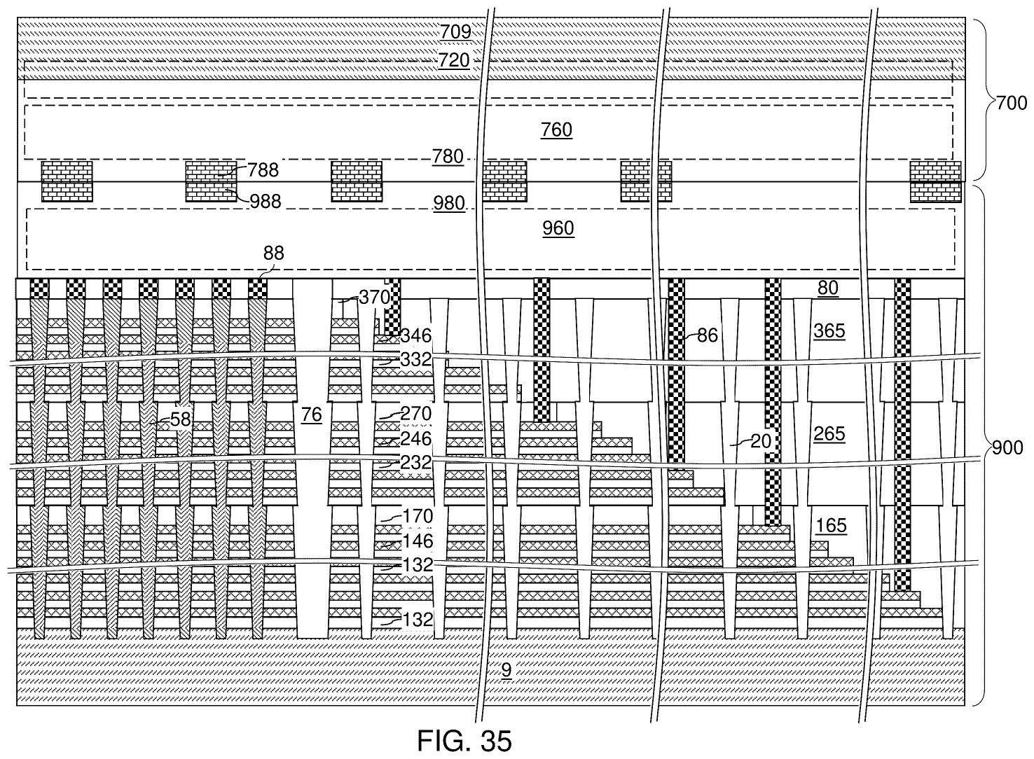

Referring to FIG. 35, a logic die 700 can be provided. For example, a peripheral circuit 720 can be formed on a logic-side substrate 709, which can be a semiconductor substrate. The peripheral circuit 720 can be configured to control operation of the memory array within the memory die 900. Logic-side metal interconnect structures 780 embedded within logic-side dielectric material layers 760 can be formed over the logic-side substrate 709 (which may comprise a semiconductor substrate) to form a logic die 700. The logic die 700 also comprises logic-side bonding pads 788 embedded within logic-side dielectric material layers 760.

A bonded assembly can be formed by bonding the logic die 700 with the memory die 900. The logic die 700 can be attached to the memory die 900, for example, by bonding the logic-side bonding pads 788 to the memory-side bonding pads 988. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within a respective memory die 900.

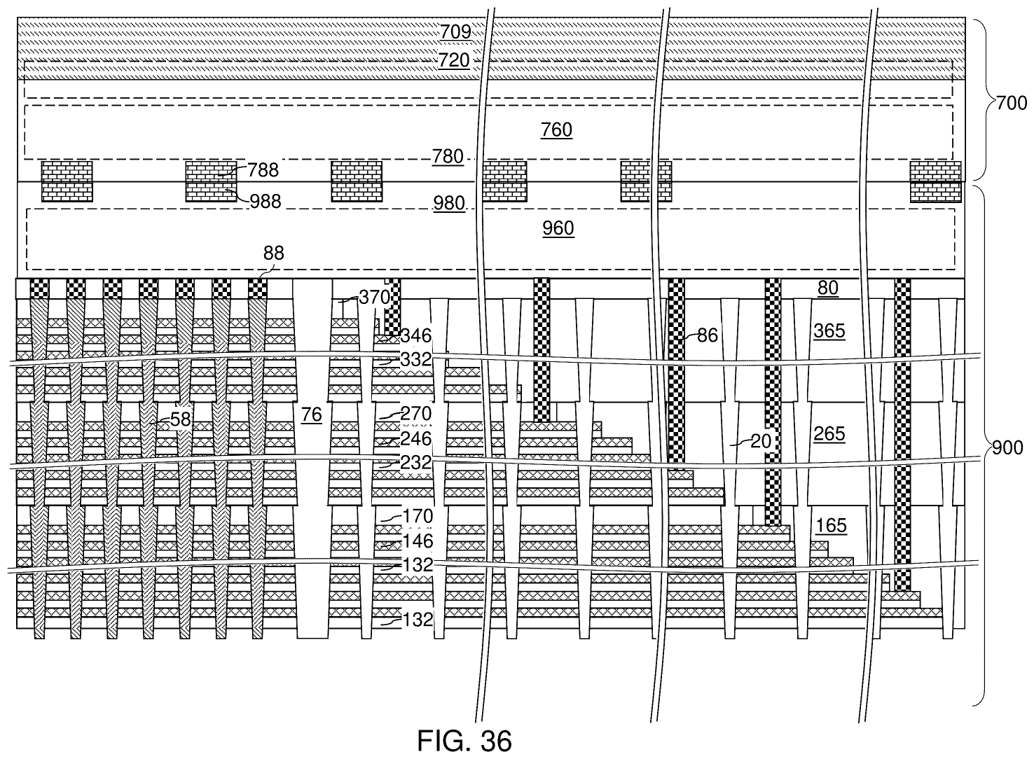

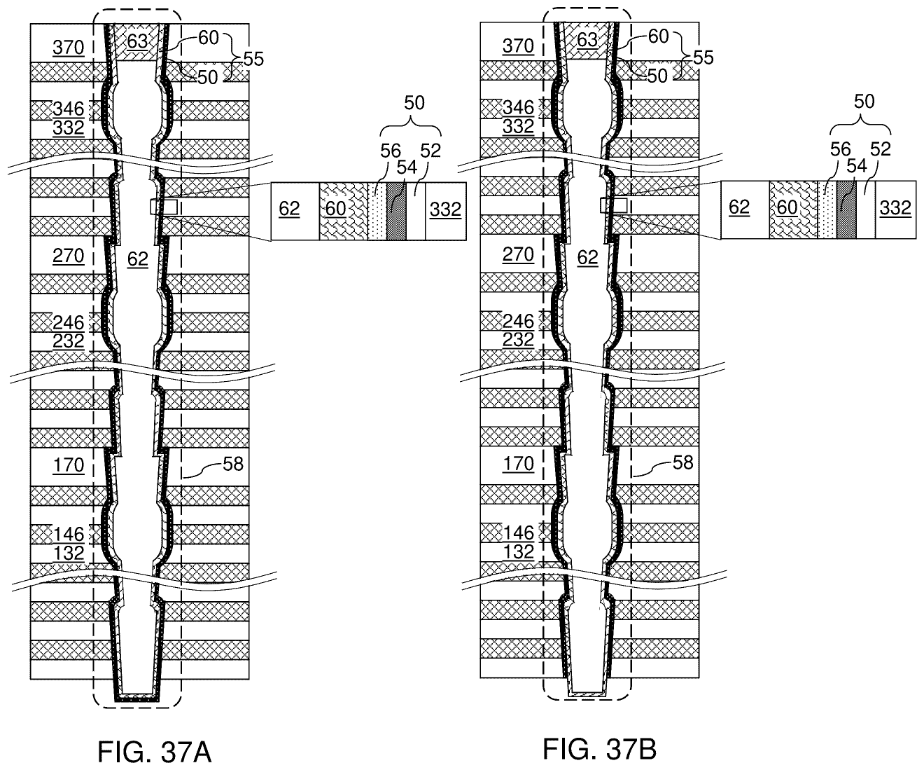

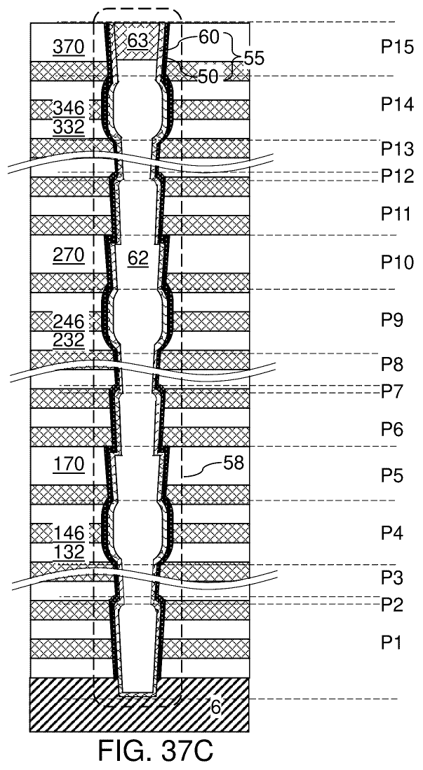

Referring to FIGS. 36 and 37A, the substrate 9 can optionally be removed, for example, by grinding, polishing, cleaving, an isotropic etch process, and/or an anisotropic etch process.

Referring to FIG. 37B, end portions of the memory film 50 can be removed selective to the vertical semiconductor channel 60 from each memory opening fill structure 58, for example, by performing an etch process that etches the materials of the memory film 50 selective to the material of the vertical semiconductor channel 60.

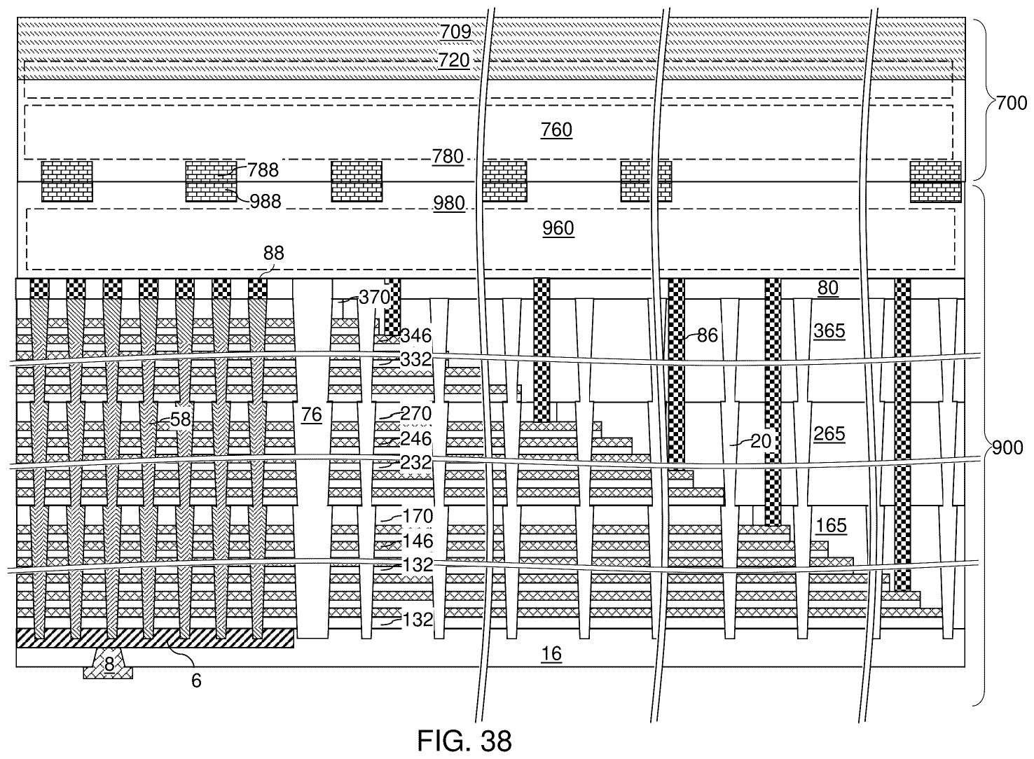

Referring to FIGS. 37C and 38, at least one conductive material can be deposited on physically exposed surfaces of the vertical semiconductor channels 60, and can be subsequently patterned to form a source layer 6. The source layer 6 may comprise a heavily doped semiconductor material layer (e.g., heavily doped polysilicon) and/or a metallic layer, such as a metal (e.g., W, Ti, Ta, Mo, Al, etc.) and/or a conductive metal nitride (TiN, MoN, TaN, WN, etc.) A backside dielectric layer 16 can be deposited over the source layer 6 and physically exposed surfaces of the first alternating stack (132, 146). A source contact pad 8 can be formed on the source layer 6. The source layer 6 and the backside dielectric layer 16 may function as a base material layer for the various openings through the alternating stacks {(132, 146), (232, 246), (332, 346)}.

Each memory opening 49 can be filled with a respective memory opening fill structure 58. The sidewall of the memory opening fill structure 58 has a contoured vertical cross-sectional profile. For example, the portion of the memory opening fill structure 58 that underlies the second alternating stack (232, 246) may comprise a first portion P1 having a first variable width that increases linearly with a vertical distance from the base material layer (such as a combination of a source layer 6 and a backside dielectric layer 16); a second portion P2 that overlies and is adjoined to the first portion P1 and having a second variable width that decreases non-linearly with the vertical distance from the base material layer (such as a combination of a source layer 6 and a backside dielectric layer 16) and laterally bounded by a tapered annular surface segment having a convex vertical profile and formed by the at least one isotropic etch process; and a third portion P3 that overlies and is adjoined to the second portion P2 and having a third variable width that increases linearly with the vertical distance from the base material layer (such as a combination of a source layer 6 and a backside dielectric layer 16). Further, the expanded opening may comprise a fourth portion P4 that overlies and is adjoined to the third portion P3 and has a fourth variable width of which a maximum is located between a horizontal plane including a bottom end of the fourth portion P4 and a horizonal plane including a top end of the fourth portion P4; and a fifth portion P5 that overlies and is adjoined to the fourth portion P4 and has a fifth variable width that increases with the vertical distance from the base material layer (such as a combination of a source layer 6 and a backside dielectric layer 16).

The portion of the memory opening fill structure 58 that extends through the second alternating stack (232, 246) may comprise: a sixth portion P6 having a sixth variable width that increases linearly with a vertical distance from the base material layer (such as a combination of a source layer 6 and a backside dielectric layer 16); a twelfth portion P7 that overlies and is adjoined to the sixth portion P6 and having a twelfth variable width that decreases non-linearly with the vertical distance from the base material layer (such as a combination of a source layer 6 and a backside dielectric layer 16) and laterally bounded by a tapered annular surface segment having a convex vertical profile and formed by the at least one isotropic etch process; and an eighth portion P8 that overlies and is adjoined to the twelfth portion P7 and having an eighth variable width that increases linearly with the vertical distance from the base material layer (such as a combination of a source layer 6 and a backside dielectric layer 16). Further, the expanded opening may comprise a ninth portion P9 that overlies and is adjoined to the eighth portion P8 and has a ninth variable width of which a maximum is located between a horizontal plane including a bottom end of the ninth portion P9 and a horizonal plane including a top end of the ninth portion P9; and a tenth portion P10 that overlies and is adjoined to the ninth portion P9 and has a tenth variable width that increases with the vertical distance from the base material layer (such as a combination of a source layer 6 and a backside dielectric layer 16).

The portion of the memory opening fill structure 58 that extends through the third alternating stack (332, 346) may comprise: an eleventh portion P11 having a eleventh variable width that increases linearly with a vertical distance from the base material layer (such as a combination of a source layer 6 and a backside dielectric layer 16); a twelfth portion P12 that overlies and is adjoined to the eleventh portion P11 and having a twelfth variable width that decreases non-linearly with the vertical distance from the base material layer (such as a combination of a source layer 6 and a backside dielectric layer 16) and laterally bounded by a tapered annular surface segment having a convex vertical profile and formed by the at least one isotropic etch process; and a thirteenth portion P13 that overlies and is adjoined to the twelfth portion P12 and having an thirteenth variable width that increases linearly with the vertical distance from the base material layer (such as a combination of a source layer 6 and a backside dielectric layer 16). Further, the expanded opening may comprise a fourteenth portion P14 that overlies and is adjoined to the thirteenth portion P13 and has a fourteenth variable width of which a maximum is located between a horizontal plane including a bottom end of the fourteenth portion P14 and a horizonal plane including a top end of the fourteenth portion P14; and a fifteenth portion P15 that overlies and is adjoined to the fourteenth portion P14 and has a fifteenth variable width that increases with the vertical distance from the base material layer (such as a combination of a source layer 6 and a backside dielectric layer 16).

Referring to all drawings and according to various embodiments of the present disclosure, a device structure is provided, which comprises: a layer stack (132, 146, 232, 246, 332, 346) that comprises a first alternating stack (132, 146) of first insulating layers 132 and first electrically conductive layers 146 which overlies a base material layer (such as a combination of a source layer 6 and a backside dielectric layer 16); and an opening fill structure (58, 20, 76) vertically extending through each layer within the layer stack (132, 146, 232, 246, 332, 346) and laterally enclosed by or contacted by the first alternating stack (132, 146). The opening fill structure (58, 20, 76) comprises: a contoured sidewall that continuously extends from a bottom surface of the opening fill structure (58, 20, 76) to a top surface of the opening fill structure (58, 20, 76); a first portion P1 having a first variable width that increases linearly with a vertical distance from the base material layer (such as a combination of a source layer 6 and a backside dielectric layer 16); a second portion P2 that overlies and is adjoined to the first portion P1 and having a second variable width that decreases non-linearly with the vertical distance from the base material layer (such as a combination of a source layer 6 and a backside dielectric layer 16) and laterally bounded by a tapered annular surface segment having a convex vertical profile; and a third portion P3 that overlies and is adjoined to the second portion P2 and having a third variable width that increases linearly with the vertical distance from the base material layer (such as a combination of a source layer 6 and a backside dielectric layer 16).

In one embodiment, the opening fill structure (58, 20, 76) comprises: a fourth portion P4 that overlies and is adjoined to the third portion P3 and has a fourth variable width of which a maximum is located between a horizontal plane including a bottom end of the fourth portion P4 and a horizonal plane including a top end of the fourth portion P4; and a fifth portion P5 that overlies and is adjoined to the fourth portion P4 and has a fifth variable width that increases with the vertical distance from the base material layer (such as a combination of a source layer 6 and a backside dielectric layer 16). In one embodiment, the layer stack (132, 146, 232, 246, 332, 346) comprises a first insulating cap layer 170 that overlies the first alternating stack (132, 146); and a top surface of the fifth portion P5 is coplanar with a top surface of the first insulating cap layer 170. In one embodiment, the fourth portion P4 has a bulging vertical cross-sectional profile such that the fourth variable width increases with the vertical distance from the base material layer (such as a combination of a source layer 6 and a backside dielectric layer 16) below a horizontal plane including the maximum of the fourth variable width, and decreases with the vertical distance from the base layer above the horizontal plane including the maximum of the fourth variable width.

In one embodiment, the layer stack (132, 146, 232, 246, 332, 346) comprises a second alternating stack of second insulating layers 232 and second electrically conductive layers 246 that overlies the first alternating stack (132, 146); and the opening fill structure (58, 20, 76) comprises: a sixth portion P6 that overlies the fifth portion P5, vertically extends through a portion of the second alternating stack, and has a sixth variable width that increases linearly with the vertical distance from the base material layer (such as a combination of a source layer 6 and a backside dielectric layer 16); and a seventh portion P7 that overlies and is adjoined to the sixth portion P6 and has a seventh variable width that increases with the vertical distance from the base material layer (such as a combination of a source layer 6 and a backside dielectric layer 16).

In one embodiment, the contoured sidewall comprises a horizontal annular surface segment having an outer periphery that adjoins a top periphery of the fifth portion P5 and having an inner periphery that adjoins a bottom periphery of the sixth portion P6. In one embodiment, the seventh portion P7 is laterally bounded by a second tapered annular surface segment having a second convex vertical profile. In one embodiment, the opening fill structure (58, 20, 76) comprises: an eighth portion P8 that overlies and is adjoined to the seventh portion P7 and having an eighth variable width that increases linearly with the vertical distance from the base material layer (such as a combination of a source layer 6 and a backside dielectric layer 16); a ninth portion P9 that overlies and is adjoined to the eighth portion P8 and has a ninth variable width of which a maximum is located between a horizontal plane including a bottom end of the ninth portion P9 and a horizonal plane including a top end of the ninth portion P9; and a tenth portion P10 that overlies and is adjoined to the ninth portion P9 and has a tenth variable width that increases with the vertical distance from the base material layer (such as a combination of a source layer 6 and a backside dielectric layer 16).

In one embodiment, the opening fill structure (58, 20, 76) is vertically extends through an opening in the first alternating stack (132, 146), and is laterally encircled by each of the first insulating layers 132 and each of the first electrically conductive layers 146. In one embodiment, the opening fill structure 58 comprises a memory opening fill structure 58, which comprises: a memory film 50 in contact with the first insulating layers 132; and a vertical semiconductor channel 60 that is laterally surrounded by the memory film 50.

In one embodiment, the opening fill structure (58, 20, 76) comprises a support pillar structure 20 consisting essentially of at least one dielectric material portion and having a planar top surface. In one embodiment, the support pillar structure 20 is laterally surrounded by a tubular dielectric liner (such as an etch stop liner 22/26/28) having a width undulation (as measured by a lateral distance between facing pairs of inner sidewall segments) and overlying the first portion P1 and the second portion P2 and contacting an outer surface of the third portion P3.

In one embodiment, the opening fill structure (58, 20, 76) comprises a trench fill structure (76 and optionally 22/26/28) and the contoured sidewall comprises a lengthwise sidewall that laterally extends straight along a first horizontal direction hd1 and having a contoured profile within a vertical plane that is perpendicular to the first horizontal direction hd1. In one embodiment, the trench fill structure (76 and optionally 22/26/28) comprises: a dielectric fill material that vertically extends continuously from a bottommost surface of the opening fill structure (58, 20, 76) that contacts the base material layer (such as a combination of a source layer 6 and a backside dielectric layer 16) to a planar top surface of the opening fill structure (58, 20, 76); and a tubular dielectric liner (such as an etch stop liner 22/26/28) having a width undulation and overlying the first portion P1 and the second portion P2 containing an outer segment of the third portion P3.

The various embodiments of the present disclosure may be employed to provide a more uniform width distribution for various openings that are formed through alternating stacks {(132, 142), (232, 242), (332, 342)}, and to provide enhanced uniformity in the characteristics of memory elements and structural elements in a three-dimensional memory device.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph of in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A device structure, comprising:
a layer stack that comprises a first alternating stack of first insulating layers and first electrically conductive layers which overlies a base material layer; and
an opening fill structure vertically extending through each layer within the layer stack and laterally enclosed by or contacted by the first alternating stack,
wherein the opening fill structure comprises:
a contoured sidewall that continuously extends from a bottom surface of the opening fill structure to a top surface of the opening fill structure;
a first portion having a first variable width that increases linearly with a vertical distance from the base material layer;
a second portion that overlies and is adjoined to the first portion and having a second variable width that decreases non-linearly with the vertical distance from the base material layer and laterally bounded by a tapered annular surface segment having a convex vertical profile; and
a third portion that overlies and is adjoined to the second portion and has a third variable width that increases linearly with the vertical distance from the base material layer.

2. The device structure of claim 1, wherein the opening fill structure further comprises:
a fourth portion that overlies and is adjoined to the third portion and has a fourth variable width of which a maximum is located between a horizontal plane including a bottom end of the fourth portion and a horizonal plane including a top end of the fourth portion; and
a fifth portion that overlies and is adjoined to the fourth portion and has a fifth variable width that increases with the vertical distance from the base material layer.

3. The device structure of claim 2, wherein:
the layer stack comprises a first insulating cap layer that overlies the first alternating stack; and
a top surface of the fifth portion is coplanar with a top surface of the first insulating cap layer.

4. The device structure of claim 2, wherein the fourth portion has a bulging vertical cross-sectional profile such that the fourth variable width increases with the vertical distance from the base material layer below a horizontal plane including the maximum of the fourth variable width, and decreases with the vertical distance from the base layer above the horizontal plane including the maximum of the fourth variable width.

5. The device structure of claim 2, wherein:
the layer stack further comprises a second alternating stack of second insulating layers and second electrically conductive layers that overlies the first alternating stack; and
the opening fill structure further comprises:
a sixth portion that overlies the fifth portion, vertically extends through a portion of the second alternating stack, and has a sixth variable width that increases linearly with the vertical distance from the base material layer; and
a seventh portion that overlies and is adjoined to the sixth portion and has a seventh variable width that increases with the vertical distance from the base material layer.

6. The device structure of claim 5, wherein the contoured sidewall further comprises a horizontal annular surface segment having an outer periphery that adjoins a top periphery of the fifth portion and having an inner periphery that adjoins a bottom periphery of the sixth portion.

7. The device structure of claim 5, wherein the seventh portion is laterally bounded by a second tapered annular surface segment having a second convex vertical profile.

8. The device structure of claim 5, wherein the opening fill structure further comprises:
an eighth portion that overlies and is adjoined to the seventh portion and having an eighth variable width that increases linearly with the vertical distance from the base material layer;
a ninth portion that overlies and is adjoined to the eighth portion and has a ninth variable width of which a maximum is located between a horizontal plane including a bottom end of the ninth portion and a horizonal plane including a top end of the ninth portion; and
a tenth portion that overlies and is adjoined to the ninth portion and has a tenth variable width that increases with the vertical distance from the base material layer.

9. The device structure of claim 1, wherein the opening fill structure vertically extends through an opening in the first alternating stack, and is laterally encircled by each of the first insulating layers and each of the first electrically conductive layers.

10. The device structure of claim 9, wherein the opening fill structure comprises:
a memory film in contact with the first insulating layers; and
a vertical semiconductor channel that is laterally surrounded by the memory film.

11. The device structure of claim 9, wherein the opening fill structure comprises a support pillar structure consisting essentially of at least one dielectric material portion and having a planar top surface.

12. The device structure of claim 11, wherein the support pillar structure is laterally surrounded by a tubular dielectric liner having a width undulation and overlying the first portion and the second portion and contacting an outer surface of the third portion.

13. The device structure of claim 1, wherein the opening fill structure comprises a trench fill structure and the contoured sidewall comprises a lengthwise sidewall that laterally extends straight along a first horizontal direction and having a contoured profile within a vertical plane that is perpendicular to the first horizontal direction.

14. The device structure of claim 13, wherein the trench fill structure comprises:
a dielectric fill material that vertically extends continuously from a bottommost surface of the opening fill structure that contacts the base material layer to a planar top surface of the opening fill structure; and
a tubular dielectric liner having a width undulation and overlying the first portion and the second portion containing an outer segment of the third portion.

15. A method of forming a device structure, comprising:
forming a first alternating stack of first insulating layers and first spacer material layer over a base material layer;
forming an opening through at least an upper portion of the first alternating stack;
forming an etch mask layer only on an upper portion of the sidewall of the opening;
performing an isotropic etch process that isotropically etches the first insulating layers and the first spacer material layers selective to the etch mask layer to laterally expand the opening at levels of a lower portion of the first alternating stack; and
forming an opening fill structure in a volume that includes an entire volume of the opening.

16. The method of claim 15, wherein:
the opening extends only through the upper portion of the first alternating stack; and
the method further comprises vertically extending the opening through the lower portion of the first alternating stack by performing an anisotropic etch process.

17. The method of claim 16, wherein the opening after the anisotropic etch process and the isotropic etch process comprises:
a first portion having a first variable width that increases linearly with a vertical distance from the base material layer;
a second portion that overlies and is adjoined to the first portion and having a second variable width that decreases non-linearly with the vertical distance from the base material layer and laterally bounded by a tapered annular surface segment having a convex vertical profile and formed by the at least one isotropic etch process;
a third portion that overlies and is adjoined to the second portion and having a third variable width that increases linearly with the vertical distance from the base material layer;
a fourth portion that overlies and is adjoined to the third portion and has a fourth variable width of which a maximum is located between a horizontal plane including a bottom end of the fourth portion and a horizonal plane including a top end of the fourth portion; and
a fifth portion that overlies and is adjoined to the fourth portion and has a fifth variable width that increases with the vertical distance from the base material layer.

18. The method of claim 15, wherein the opening fill structure comprises a memory opening fill structure that comprises:
a memory film that is formed directly on the first insulating layers; and
a vertical semiconductor channel that is formed on an inner sidewall of the memory film.

19. The method of claim 15, wherein the opening fill structure comprises a support pillar structure consisting essentially of at least one dielectric material portion and having a planar top surface.

20. The method of claim 15, wherein the opening fill structure comprises a trench fill structure and the contoured sidewall comprises a lengthwise sidewall that laterally extends straight along a first horizontal direction and having a contoured profile within a vertical plane that is perpendicular to the first horizontal direction, wherein the trench fill structure comprises a dielectric fill material that vertically extends continuously from a bottommost surface of the opening fill structure that contacts the base material layer to a planar top surface of the opening fill structure.
